(19) United States
(12) Patent Application Publication
(10) Pub. No.: US 2019/0296242 A1
(43) Pub. Date: Sep. 26, 2019

(54) POLYMERS WITH ASYMMETRIC REPEATING UNITS

(71) Applicant: Merck Patent GmbH, Darmstadt (DE)

(72) Inventors: Beate Burkhart, Darmstadt (DE); Katja Maria Scheible, Darmstadt (DE); Nils Koenen, Griesheim (DE); Holger Heil, Frankfurt am Main (DE)

(73) Assignee: Merck Patent GmbH, Darmstadt (DE)

(21) Appl. No.: 16/465,344

(22) PCT Filed: Nov. 27, 2017
(86) PCT No.: PCT/EP2017/080486

§ 371 Date: May 30, 2019

(30) Foreign Application Priority Data
Nov. 30, 2016 (EP) 16201317.1

(51) Int. Cl. H01L 51/00; C08G 61/12

(52) U.S. Cl. CPC H01L 51/0039; H01L 51/5056; H01L 51/0043; C08G 2261/124; C08G 2261/1412; C08G 2261/148; C08G 2261/18; C08G 2261/228; C08G 2261/3162; C08G 2261/312; C08G 2261/3142; C08G 2261/411; C08G 2261/412; C08G 2261/414; C08G 2261/91; C08G 2261/92; C08G 2261/95; C08G 61/121

(57) ABSTRACT

The invention relates to polymers having at least one asymmetrical structural unit of the following formula (I): wherein A, B, Ar¹, Ar², Ar³ and Ar⁴, n, m, o and p can have the meaning as defined in claim 1, to methods for the production thereof and to the use thereof in electronic or optoelectronic devices, in particular in organic electroluminescent devices, so-called OLEDs (OLED=Organic Light Emitting Diodes). The present invention also relates to organic electroluminescent devices which contain said polymers.

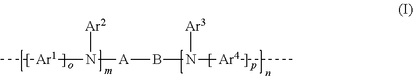

The present invention relates to polymers having asymmetric repeat units, to processes for preparation thereof and to the use thereof in electronic or optoelectronic devices, especially in organic electroluminescent devices, called OLEDs (OLED=organic light-emitting diodes). The present invention also further relates to organic electroluminescent devices comprising these polymers.

In electronic or optoelectronic devices, especially in organic electroluminescent devices (OLEDs), components of various functionality are required. In OLEDs, the different functionalities are normally present in different layers. Reference is made in this case to multilayer OLED systems. The layers in these multilayer OLED systems include charge-injecting layers, for example electron- and hole-injecting layers, charge-transporting layers, for example electron- and hole-conducting layers, and layers containing light-emitting components. These multilayer OLED systems are generally produced by successive layer by layer application.

If two or more layers are applied from solution, it has to be ensured that any layer already applied, after drying thereof, is not destroyed by the subsequent application of the solution for production of the next layer. This can be achieved, for example, by rendering a layer insoluble, for example by crosslinking. Methods of this kind are disclosed, for example, in EP 0 637 899 and WO 96/20253.

Furthermore, it is also necessary to match the functionalities of the individual layers to one another in terms of the material such that very good results, for example in terms of lifetime, efficiency, etc., are achieved. For instance, particularly the layers that directly adjoin an emitting layer, especially the hole-transporting layer (HTL=hole transport layer) have a significant influence on the properties of the adjoining emitting layer.

One of the problems addressed by the present invention was therefore that of providing compounds which can firstly be processed from solution and which secondly lead to an improvement in the properties of the device, i.e. especially of the OLED, when used in electronic or optoelectronic devices, preferably in OLEDs, and here especially in the hole transport layer thereof.

It has been found that, surprisingly, polymers having asymmetric repeat units, especially when used in the hole-transporting layer of OLEDs, lead to a distinct increase in the lifetime of these OLEDs.

The present application thus provides a polymer having at least one structural unit of the following formula (I):

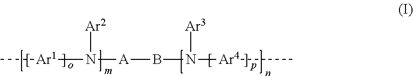

where

A is a polycyclic aromatic or heteroaromatic ring system which has 10 to 60, preferably 12 to 50 and more preferably 12 to 30 aromatic or heteroaromatic ring atoms and may be substituted by one or more R radicals,

B is a mono- or polycyclic, aromatic or heteroaromatic ring system which has 5 to 10 aromatic or heteroaromatic ring atoms and may be substituted by one or more R radicals,
where the number of aromatic or heteroaromatic ring atoms in A is greater than the number of aromatic or heteroaromatic ring atoms in B,

Ar¹, Ar², Ar³ and Ar⁴ are the same or different at each instance and are a mono- or polycyclic, aromatic or heteroaromatic ring system which has 5 to 60 aromatic ring atoms and may be substituted by one or more R radicals,

n, m, o and p are the same or different and are each 0 or 1,

R is the same or different at each instance and is H, D, F, Cl, Br, I, N(R¹)₂, CN, NO₂, Si(R¹)₃, B(OR¹)₂, C(═O)R¹, P(═O)(R¹)₂, S(═O)R¹, S(═O)₂R¹, OSO₂R¹, a straight-chain alkyl, alkoxy or thioalkoxy group having 1 to 40 carbon atoms or a branched or cyclic alkyl, alkoxy or thioalkoxy group having 3 to 40 carbon atoms, each of which may be substituted by one or more R¹ radicals, where one or more nonadjacent CH₂ groups may be replaced by R¹C═CR¹, C≡C, Si(R¹)₂, C═O, C═S, C═NR¹, P(═O)(R¹), SO, SO₂, NR¹, O, S or CONR¹ and where one or more hydrogen atoms may be replaced by D, F, Cl, Br, I or CN, or a mono- or polycyclic, aromatic or heteroaromatic ring system which has 5 to 60 aromatic ring atoms and may be substituted in each case by one or more R¹ radicals, or an aryloxy or heteroaryloxy group which has 5 to 60 aromatic ring atoms and may be substituted by one or more R¹ radicals, or an aralkyl or heteroaralkyl group which has 5 to 60 aromatic ring atoms and may be substituted by one or more R¹ radicals, or a diarylamino group, diheteroarylamino group or arylheteroarylamino group which has 10 to 40 aromatic ring atoms and may be substituted by one or more R¹ radicals, or a crosslinkable Q group; where two or more R radicals together may also form a mono- or polycyclic, aliphatic, aromatic and/or benzofused ring system;

R¹ is the same or different at each instance and is H, D, F or an aliphatic hydrocarbyl radical having 1 to 20 carbon atoms, an aromatic and/or a heteroaromatic hydrocarbyl radical having 5 to 20 carbon atoms, in which one or more hydrogen atoms may also be replaced by F; where two or more R¹ substituents together may also form a mono- or polycyclic, aliphatic, aromatic or heteroaromatic ring system; and

the dotted lines represent bonds to adjacent structural units in the polymer.

In the present application, the term “polymer” is understood to mean polymeric compounds, oligomeric compounds and dendrimers. The polymeric compounds of the invention have preferably 10 to 10 000, more preferably 10 to 5000 and most preferably 10 to 2000 structural units (i.e. repeat units). The oligomeric compounds of the invention preferably have 3 to 9 structural units. The branching factor of the polymers is between 0 (linear polymer, no branching sites) and 1 (fully branched dendrimer).

The polymers of the invention preferably have a molecular weight M_{w} in the range from 10 000 to 1 000 000 g/mol, more preferably a molecular weight M_{w} in the range from 20 000 to 500 000 g/mol and most preferably a molecular weight M_{w} in the range from 25 000 to 200 000 g/mol. The molecular weight M_{w} is determined by means of GPC (=gel permeation chromatography) against an internal polystyrene standard.

The polymers of the invention are either conjugated, semi-conjugated or non-conjugated polymers. Preference is given to conjugated or semi-conjugated polymers.

According to the invention, the structural units of the formula (I) may be incorporated into the main chain or side chain of the polymer. Preferably, however, the structural units of the formula (I) are incorporated into the main chain of the polymer. In the case of incorporation into the side chain of the polymer, the structural units of the formula (I) may either be mono- or bivalent, meaning that they have either one or two bonds to adjacent structural units in the polymer.

“Conjugated polymers” in the context of the present application are polymers containing mainly sp²-hybridized (or else optionally sp-hybridized) carbon atoms in the main chain, which may also be replaced by correspondingly hybridized heteroatoms. In the simplest case, this means the alternating presence of double and single bonds in the main chain, but polymers having units such as a meta-bonded phenylene, for example, should also be regarded as conjugated polymers in the context of this application. “Mainly” means that defects that occur naturally (involuntarily) and lead to interrupted conjugation do not make the term “conjugated polymer” inapplicable. Conjugated polymers are likewise considered to be polymers having a conjugated main chain and non-conjugated side chains. In addition, the present application likewise refers to conjugation when, for example, arylamine units, arylphosphine units, particular heterocycles (i.e. conjugation via nitrogen, oxygen or sulfur atoms) and/or organometallic complexes (i.e. conjugation via the metal atom) are present in the main chain. The same applies to conjugated dendrimers. In contrast, units such as simple alkyl bridges, (thio)ether, ester, amide or imide linkages, for example, are unambiguously defined as non-conjugated segments.

A semi-conjugated polymer shall be understood in the present application to mean a polymer containing conjugated regions separated from one another by non-conjugated sections, deliberate conjugation breakers (for example spacer groups) or branches, for example in which comparatively long conjugated sections in the main chain are interrupted by non-conjugated sections, or containing comparatively long conjugated sections in the side chains of a polymer non-conjugated in the main chain. Conjugated and semi-conjugated polymers may also contain conjugated, semi-conjugated or non-conjugated dendrimers.

The term “dendrimer” in the present application shall be understood to mean a highly branched compound formed from a multifunctional core to which monomers branched in a regular structure are bonded, such that a tree-like structure is obtained. In this case, both the core and the monomers may assume any desired branched structures consisting both of purely organic units and organometallic compounds or coordination compounds. “Dendrimer” shall generally be understood here as described, for example, by M. Fischer and F. Vogtle (Angew. Chem., Int. Ed. 1999, 38, 885).

The term “structural unit” in the present application is understood to mean a unit which, proceeding from a monomer unit having at least two, preferably two, reactive groups, by a bond-forming reaction, is incorporated into the polymer base skeleton as a portion thereof and is present thus bonded as a repeat unit within the polymer prepared.

The term “mono- or polycyclic aromatic ring system” is understood in the present application to mean an aromatic ring system which has 6 to 60, preferably 6 to 30 and more preferably 6 to 24 aromatic ring atoms and does not necessarily contain only aromatic groups, but in which it is also possible for two or more aromatic units to be interrupted by a short nonaromatic unit (<10% of the atoms other than H, preferably <5% of the atoms other than H), for example an spa-hybridized carbon atom or oxygen or nitrogen atom, a CO group, etc. For example, systems such as 9,9′-spirobifluorene, 9,9-diarylfluorene and 9,9-dialkylfluorene, for example, shall also be regarded as aromatic ring systems.

The aromatic ring systems may be mono- or polycyclic, meaning that they may have one ring (e.g. phenyl) or two or more rings which may also be fused (e.g. naphthyl) or covalently bonded (e.g. biphenyl), or contain a combination of fused and bonded rings.

Preferred aromatic ring systems are, for example, phenyl, biphenyl, terphenyl, [1,1′:3′,1″]terphenyl-2′-yl, quaterphenyl, naphthyl, anthracene, binaphthyl, phenanthrene, dihydrophenanthrene, pyrene, dihydropyrene, chrysene, perylene, tetracene, pentacene, benzopyrene, fluorene, indene, indenofluorene and spirobifluorene.

The term “mono- or polycyclic heteroaromatic ring system” is understood in the present application to mean an aromatic ring system having 5 to 60, preferably 5 to 30 and more preferably 5 to 24 aromatic ring atoms, where one or more of these atoms is/are a heteroatom. The “mono- or polycyclic heteroaromatic ring system” does not necessarily contain only aromatic groups, but may also be interrupted by a short nonaromatic unit (<10% of the atoms other than H, preferably <5% of the atoms other than H), for example an spa-hybridized carbon atom or oxygen or nitrogen atom, a CO group, etc.

The heteroaromatic ring systems may be mono- or polycyclic, meaning that they may have one ring or two or more rings which may also be fused or covalently bonded (e.g. pyridylphenyl), or contain a combination of fused and bonded rings. Preference is given to fully conjugated heteroaryl groups.

Preferred heteroaromatic ring systems are, for example, 5-membered rings such as pyrrole, pyrazole, imidazole, 1,2,3-triazole, 1,2,4-triazole, tetrazole, furan, thiophene, selenophene, oxazole, isoxazole, 1,2-thiazole, 1,3-thiazole, 1,2,3-oxadiazole, 1,2,4-oxadiazole, 1,2,5-oxadiazole, 1,3,4-oxadiazole, 1,2,3-thiadiazole, 1,2,4-thiadiazole, 1,2,5-thiadiazole, 1,3,4-thiadiazole, 6-membered rings such as pyridine, pyridazine, pyrimidine, pyrazine, 1,3,5-triazine, 1,2,4-triazine, 1,2,3-triazine, 1,2,4,5-tetrazine, 1,2,3,4-tetrazine, 1,2,3,5-tetrazine, or groups having several rings, such as carbazole, indenocarbazole, indole, isoindole, indolizine, indazole, benzimidazole, benzotriazole, purine, naphthimidazole, phenanthrimidazole, pyridimidazole, pyrazinimidazole, quinoxalinimidazole, benzoxazole, naphthoxazole, anthroxazole, phenanthroxazole, isoxazole, benzothiazole, benzofuran, isobenzofuran, dibenzofuran, quinoline, isoquinoline, pteridine, benzo-5,6-quinoline, benzo-6,7-quinoline, benzo-7,8-quinoline, benzoisoquinoline, acridine, phenothiazine, phenoxazine, benzopyridazine, benzopyrimidine, quinoxaline, phenazine, naphthyridine, azacarbazole, benzocarboline, phenanthridine, phenanthroline, thieno[2,3-b]thiophene, thieno[3,2-b]thiophene, dithienothiophene, isobenzothiophene, dibenzothiophene, benzothiadiazothiophene or combinations of these groups.

The mono- or polycyclic, aromatic or heteroaromatic ring system may be unsubstituted or substituted. “Substituted” in the present application means that the mono- or polycyclic, aromatic or heteroaromatic ring system has one or more R substituents.

R is the same or different at each instance and is preferably H, D, F, Cl, Br, I, N(R¹)₂, CN, NO₂, Si(R¹)₃, B(OR¹)₂, C(═O)R¹, P(═O)(R¹)₂, S(═O)R¹, S(═O)₂R¹, OSO₂R¹, a straight-chain alkyl, alkoxy or thioalkoxy group having 1 to 40 carbon atoms or an alkenyl or alkynyl group having 2 to 40 carbon atoms or a branched or cyclic alkyl, alkoxy or thioalkoxy group having 3 to 40 carbon atoms, each of which may be substituted by one or more R¹ radicals, where one or more nonadjacent CH₂ groups may be replaced by R¹C═CR¹, C≡C, Si(R¹)₂, C═O, C═S, C═NR¹, P(═O)(R¹), SO, SO₂, NR¹, O, S or CONR¹ and where one or more hydrogen atoms may be replaced by D, F, Cl, Br, I or CN, or an aromatic or heteroaromatic ring system which has 5 to 60 aromatic ring atoms and may be substituted in each case by one or more R¹ radicals, or an aryloxy or heteroaryloxy group which has 5 to 60 aromatic ring atoms and may be substituted by one or more R¹ radicals, or an aralkyl or heteroaralkyl group which has 5 to 60 aromatic ring atoms and may be substituted by one or more R¹ radicals, or a diarylamino group, diheteroarylamino group or arylheteroarylamino group which has 10 to 40 aromatic ring atoms and may be substituted by one or more R¹ radicals, or a crosslinkable Q group; at the same time, two or more R radicals together may also form a mono- or polycyclic, aliphatic, aromatic and/or benzofused ring system.

R is the same or different at each instance and is more preferably H, D, F, Cl, Br, I, N(R¹)₂, Si(R¹)₃, B(OR¹)₂, C(═O)R¹, P(═O)(R¹)₂, a straight-chain alkyl or alkoxy group having 1 to 20 carbon atoms or an alkenyl or alkynyl group having 2 to 20 carbon atoms or a branched or cyclic alkyl or alkoxy group having 3 to 20 carbon atoms, each of which may be substituted by one or more R¹ radicals, where one or more nonadjacent CH₂ groups may be replaced by R¹C═CR¹, C≡C, Si(R¹)₂, C═O, C═NR¹, P(═O)(R¹), NR¹, O or CONR¹ and where one or more hydrogen atoms may be replaced by F, Cl, Br or I, or an aromatic or heteroaromatic ring system which has 5 to 30 aromatic ring atoms and may be substituted in each case by one or more R¹ radicals, or an aryloxy or heteroaryloxy group which has 5 to 30 aromatic ring atoms and may be substituted by one or more R¹ radicals, or an aralkyl or heteroaralkyl group which has 5 to 30 aromatic ring atoms and may be substituted by one or more R¹ radicals, or a diarylamino group, diheteroarylamino group or arylheteroarylamino group which has 10 to 20 aromatic ring atoms and may be substituted by one or more R¹ radicals, or a crosslinkable Q group; at the same time, two or more R radicals together may also form a mono- or polycyclic, aliphatic, aromatic and/or benzofused ring system.

R is the same or different at each instance and is even more preferably H, a straight-chain alkyl or alkoxy group having 1 to 10 carbon atoms or an alkenyl or alkynyl group having 2 to 10 carbon atoms or a branched or cyclic alkyl or alkoxy group having 3 to 10 carbon atoms, each of which may be substituted by one or more R¹ radicals, where one or more nonadjacent CH₂ groups may be replaced by R¹C═CR¹, C≡C, C═O, C═NR¹, NR¹, O or CONR¹, or an aromatic or heteroaromatic ring system which has 5 to 20 aromatic ring atoms and may be substituted in each case by one or more R¹ radicals, or an aryloxy or heteroaryloxy group which has 5 to 20 aromatic ring atoms and may be substituted by one or more R¹ radicals, or an aralkyl or heteroaralkyl group which has 5 to 20 aromatic ring atoms and may be substituted by one or more R¹ radicals, or a diarylamino group, diheteroarylamino group or arylheteroarylamino group which has 10 to 20 aromatic ring atoms and may be substituted by one or more R¹ radicals, or a crosslinkable Q group; at the same time, two or more R radicals together may also form a mono- or polycyclic, aliphatic, aromatic and/or benzofused ring system.

Preferred alkyl groups having 1 to 10 carbon atoms are depicted in the following table:

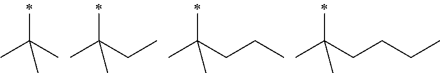

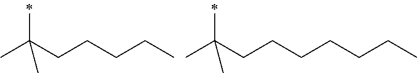

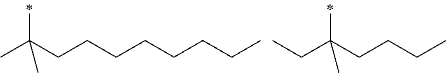

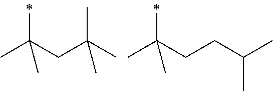

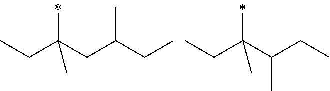

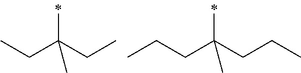

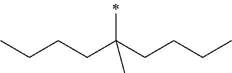

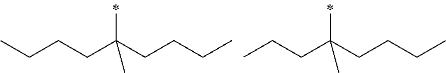

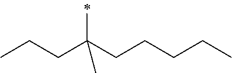

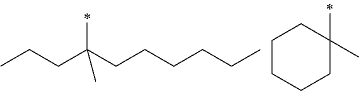

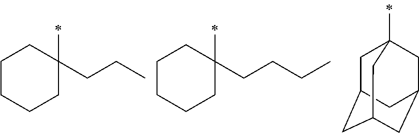

R¹ is the same or different at each instance and is preferably H, D, F or an aliphatic hydrocarbyl radical having 1 to 20 carbon atoms, an aromatic and/or a heteroaromatic hydrocarbyl radical having 5 to 20 carbon atoms, in which one or more hydrogen atoms may also be replaced by F; at the same time, two or more R¹ substituents together may also form a mono- or polycyclic, aliphatic, aromatic or heteroaromatic ring system.

R¹ is the same or different at each instance and is more preferably H, D or an aliphatic hydrocarbyl radical having 1 to 20 carbon atoms, an aromatic and/or a heteroaromatic hydrocarbyl radical having 5 to 20 carbon atoms; at the same time, two or more R¹ substituents together may also form a mono- or polycyclic, aliphatic, aromatic or heteroaromatic ring system.

R¹ is the same or different at each instance and is even more preferably H or an aliphatic hydrocarbyl radical having 1 to 10 carbon atoms, an aromatic and/or a heteroaromatic hydrocarbyl radical having 5 to 10 carbon atoms.

In a first preferred embodiment of the present invention, in the structural unit of the formula (I), m=n=1, meaning that the structural unit of the formula (I) preferably has the structure of the following formula (Ia):

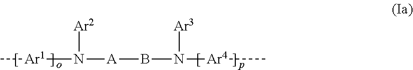

where A, B, Ar¹, Ar², Ar³, Ar⁴, o and p may assume the definitions given above in relation to formula (I).

In a first particularly preferred embodiment of the present invention, in the structural unit of the formula (I), (m=n=1 and o=p=1) or (m=n=1 and o=p=0), meaning that the structural unit of the formula (I) more preferably has the structure of the following formula (Ia1) or (Ia2):

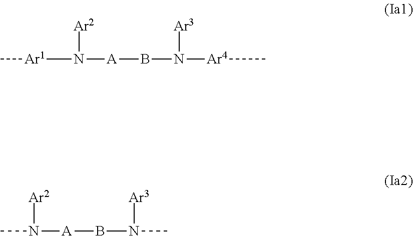

where A, B, Ar¹, Ar², Ar³ and Ar⁴ may assume the definitions given above in relation to formula (I).

In a second preferred embodiment of the present invention, in the structural unit of the formula (I), m=n=0, meaning that the structural unit of the formula (I) preferably has the structure of the following formula (Ib):

------A-B----- (Ib)

where A and B may assume the definitions given above in relation to formula (I).

In a third preferred embodiment of the present invention, in the structural unit of the formula (I), m=1 and n=0, meaning that the structural unit of the formula (I) preferably has the structure of the following formula (Ic):

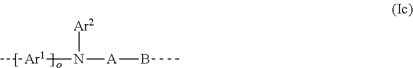

where A, B, Ar¹ and Ar² may assume the definitions given above in relation to formula (I) and o=0 or 1, preferably 1.

In a fourth preferred embodiment of the present invention, in the structural unit of the formula (I), m=0 and n=1, meaning that the structural unit of the formula (I) preferably has the structure of the following formula (Id):

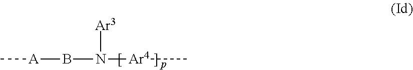

where A, B, Ar³ and Ar⁴ may assume the definitions given above in relation to formula (I) and p=0 or 1, preferably 1.

Of the four preferred embodiments mentioned above, particular preference is given to the two first embodiments.

In the structural units of the formulae (I), (Ia), (Ia1), (Ia2), (Ib), (Ic) and (Id), the polycyclic aromatic or heteroaromatic ring system A is preferably selected from the following units A1 to A8:

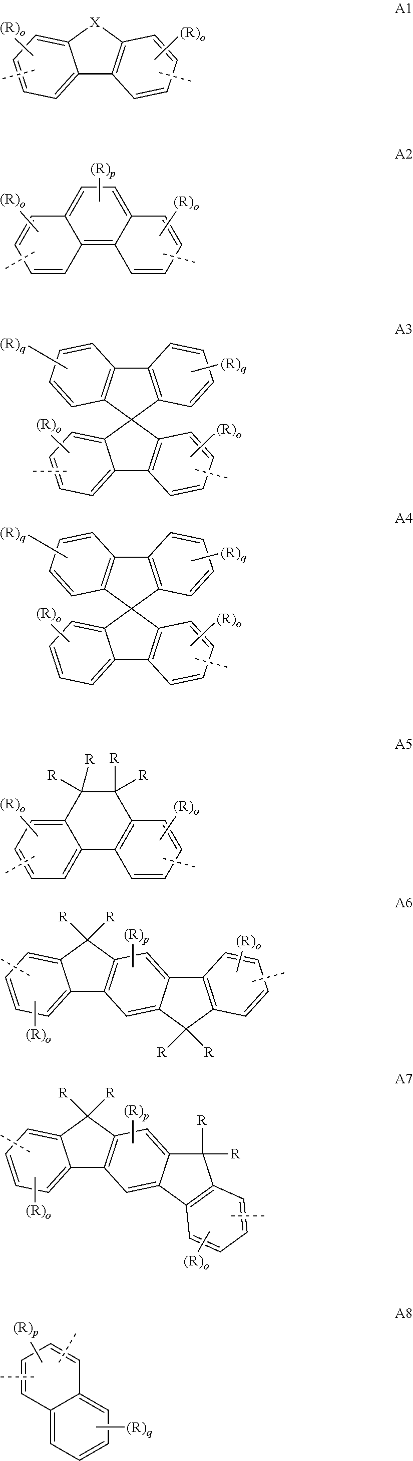

where R may assume the definitions given above,

X═CR², NR, SiR², O, S, C═O or P═O, preferably CR², NR, O or S,

o=0, 1, 2 or 3,

p=0, 1 or 2, and

q=0, 1, 2, 3 or 4.

In the structural units of the formulae (I), (Ia), (Ia1), (Ia2), (Ib), (Ic) and (Id), the polycyclic aromatic or heteroaromatic ring system A is more preferably selected from the following units A1 a to A8a:

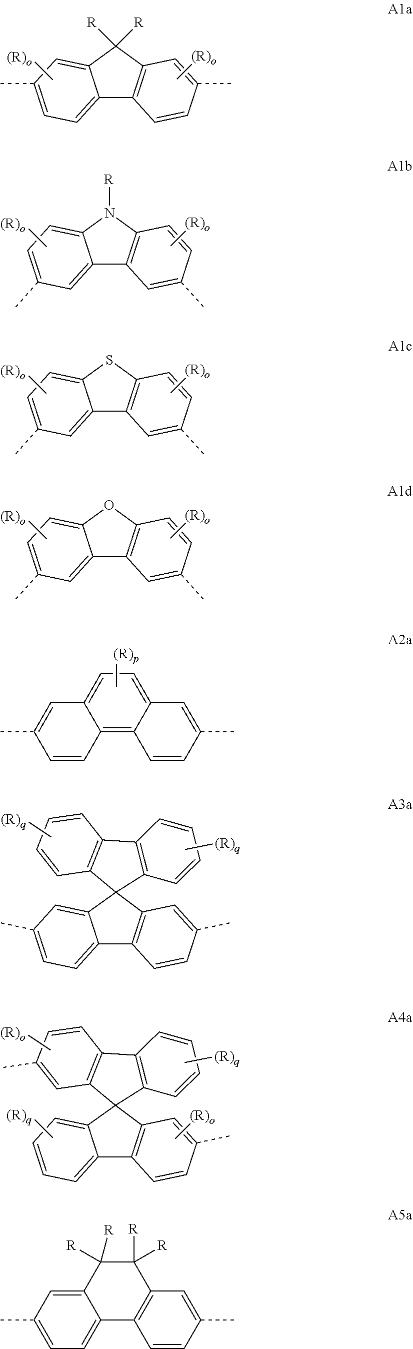

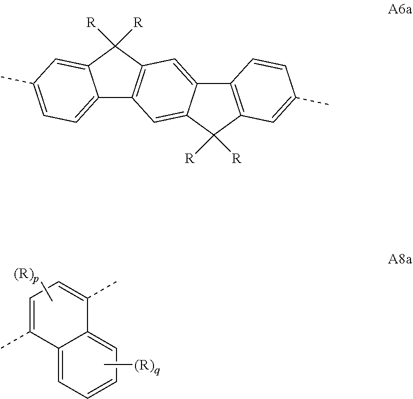

where R, o, p and q may assume the definitions given above.

In the structural units of the formulae (I), (Ia), (Ia1), (Ia2), (Ib), (Ic) and (Id), the polycyclic aromatic or heteroaromatic ring system A is even more preferably selected from the following units A1 aa to A8aa:

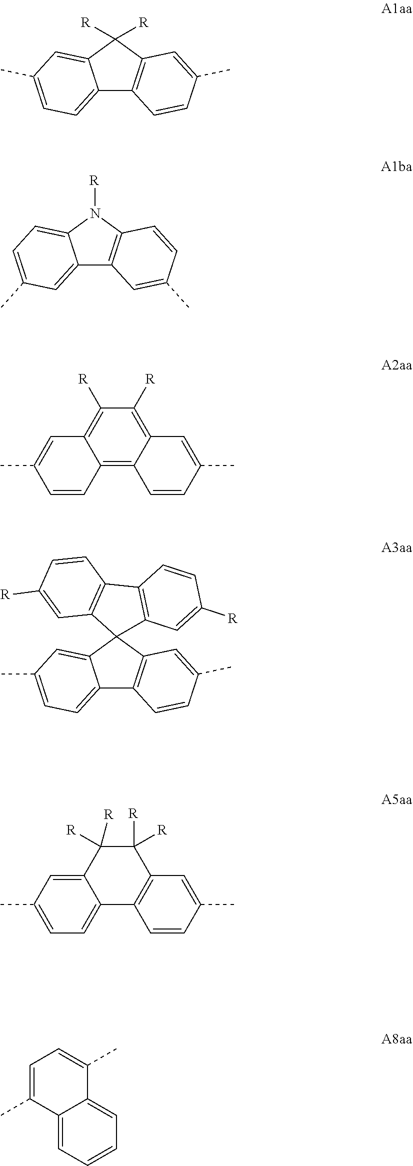

where R may assume the definitions given above.

In the structural units of the formulae (I), (Ia), (Ia1), (Ia2), (Ib), (Ic) and (Id), the mono- or polycyclic, aromatic or heteroaromatic ring system B is preferably selected from the following units B1 to B4:

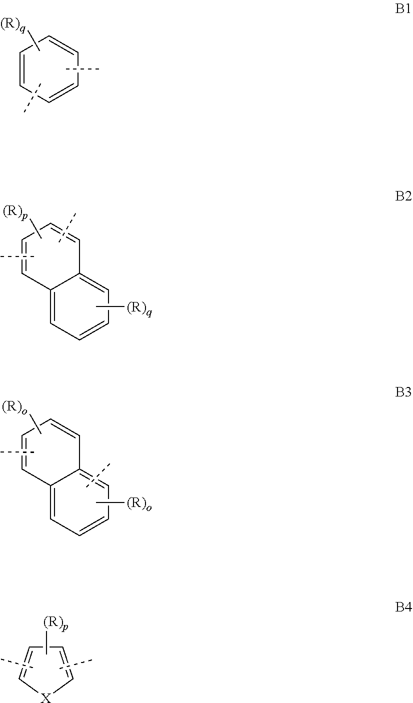

where R, o, p, q and X may assume the definitions given above in relation to the ring systems A.

In the structural units of the formulae (I), (Ia), (Ia1), (Ia2), (Ib), (Ic) and (Id), the mono- or polycyclic, aromatic or heteroaromatic ring system B is more preferably selected from the following units B1a to B4d:

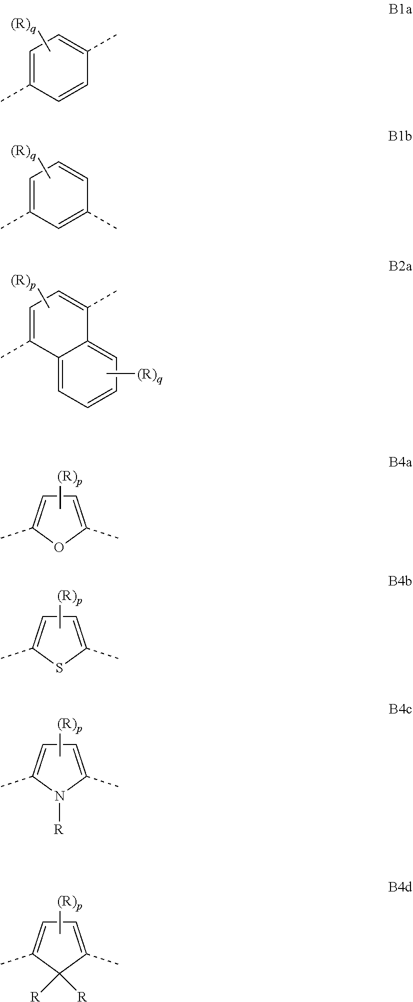

where R, p and q may assume the definitions given above in relation to the ring systems A.

In the structural units of the formulae (I), (Ia), (Ia1), (Ia2), (Ib), (Ic) and (Id), the mono- or polycyclic, aromatic or heteroaromatic ring system B is even more preferably selected from the following units B1 as to B4ca:

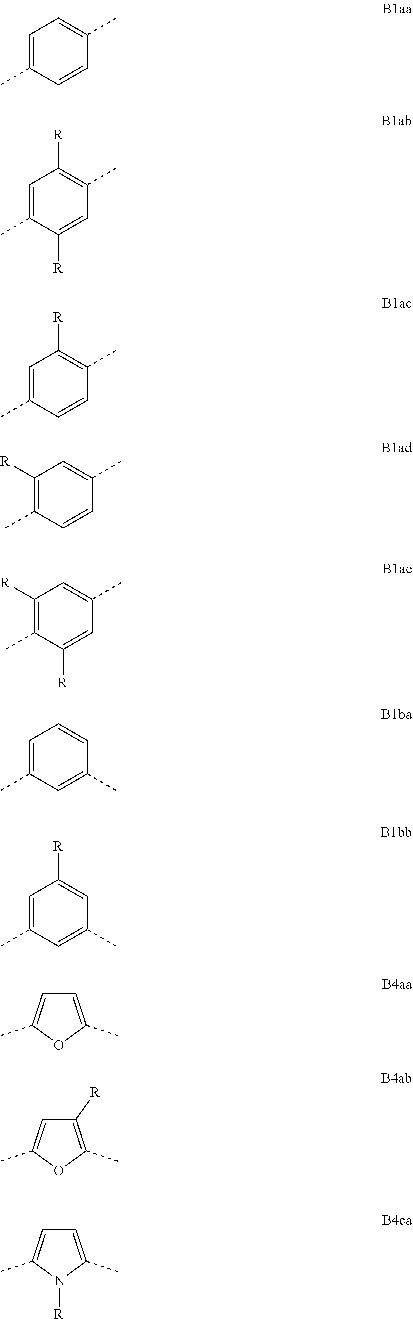

where R may assume the definitions given above in relation to the ring systems A.

In the structural units of the formulae (I), (Ia), (Ia1), (Ia2), (Ib), (Ic) and (Id), the mono- or polycyclic, aromatic or heteroaromatic ring systems Are and Ara are preferably selected from the following units Ar1 to Ar10:

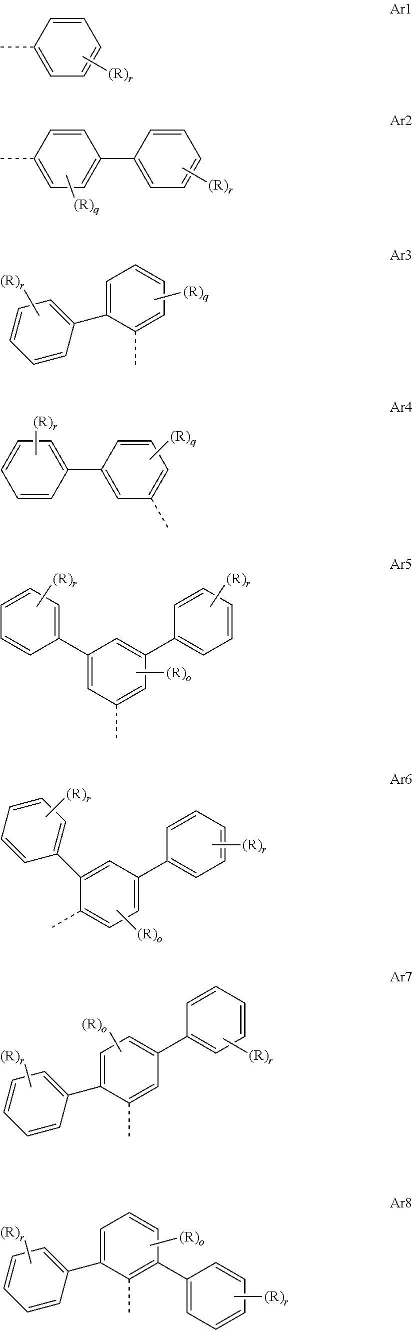

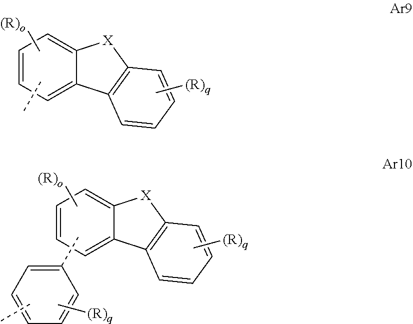

where R, o, q and X may assume the definitions given above in relation to the ring systems A, and

r=0, 1, 2, 3, 4 or 5.

In the structural units of the formulae (I), (Ia), (Ia1), (Ia2), (Ib), (Ic) and (Id), the mono- or polycyclic, aromatic or heteroaromatic ring systems Are and Ara are more preferably selected from the following units Ar1 to Ar10, where X in the units Ar9 and Ar10 is selected from CR₂, O, NR and S.

In the structural units of the formulae (I), (Ia), (Ia1), (Ia2), (Ib), (Ic) and (Id), the mono- or polycyclic, aromatic or heteroaromatic ring systems Are and Ara are even more preferably selected from the following units Ar1a to Ar10c:

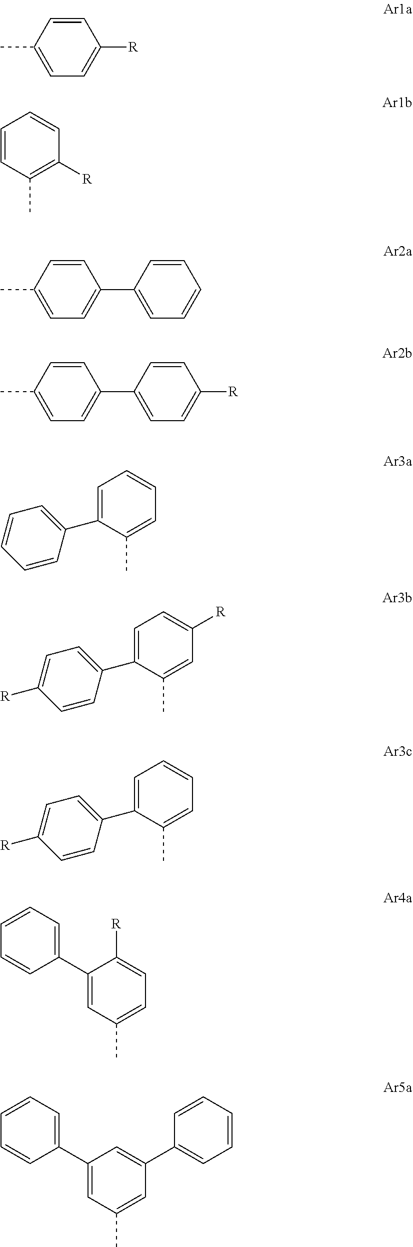

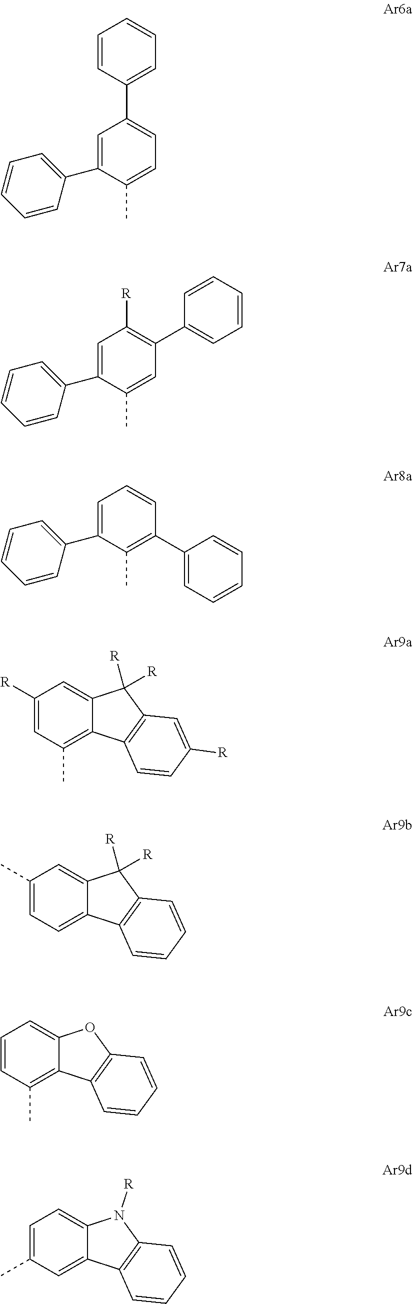

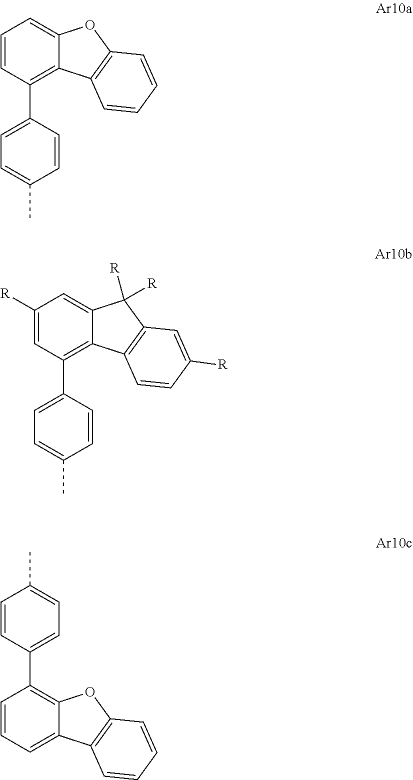

In the structural units of the formulae (I), (Ia), (Ia1), (Ia2), (Ib), (Ic) and (Id), the mono- or polycyclic, aromatic or heteroaromatic ring systems Ar¹ and Ar⁴ are preferably selected from the following units Ar11 to Ar18:

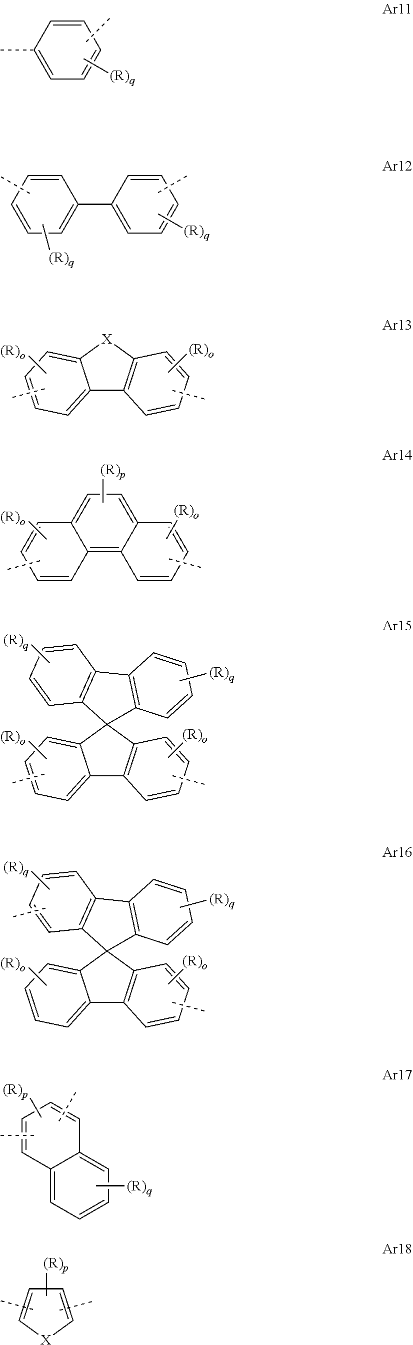

where R, o, q, p and X may assume the definitions given above in relation to the ring systems A.

In the structural units of the formulae (I), (Ia), (Ia1), (Ia2), (Ib), (Ic) and (Id), the mono- or polycyclic, aromatic or heteroaromatic ring systems Ar¹ and Ar⁴ are more preferably selected from the following units Ar11a to Ar18d:

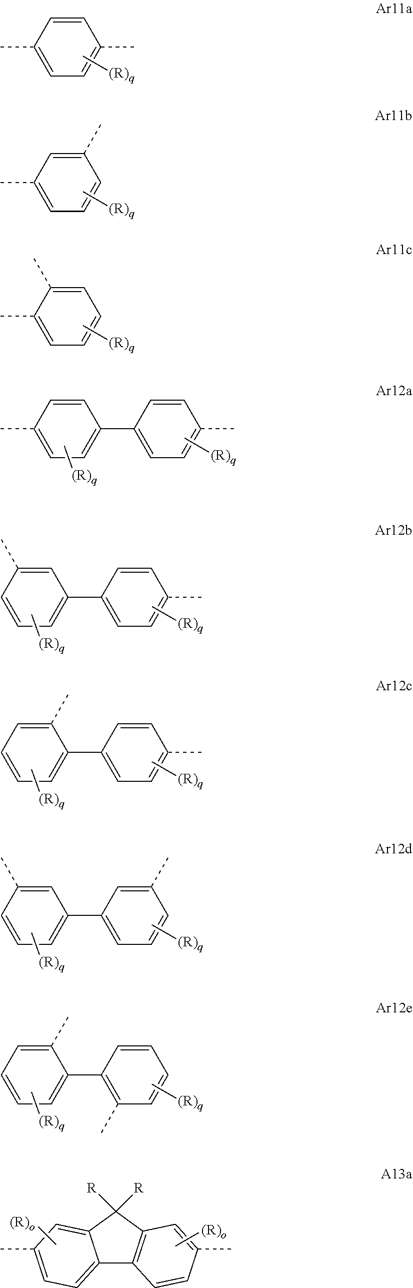

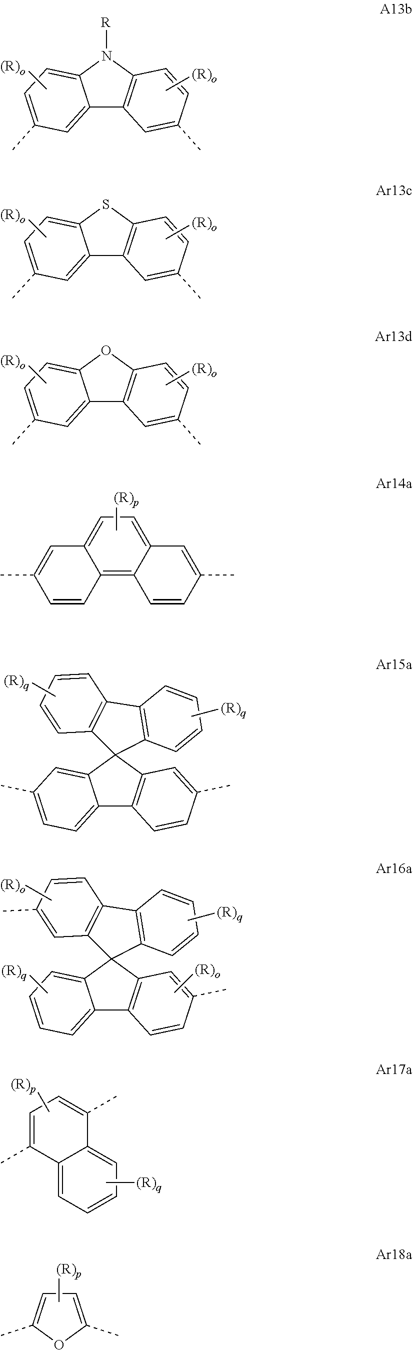

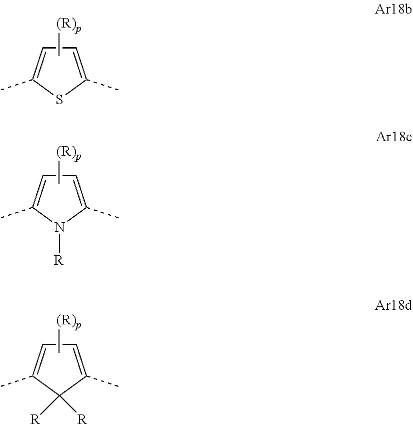

where R, o, q and p may assume the definitions given above in relation to the ring systems A.

In the structural units of the formulae (I), (Ia), (Ia1), (Ia2), (Ib), (Ic) and (Id), the mono- or polycyclic, aromatic or heteroaromatic ring systems Ar¹ and Ar⁴ are even more preferably selected from the following units Ar11aa to Ar17aa:

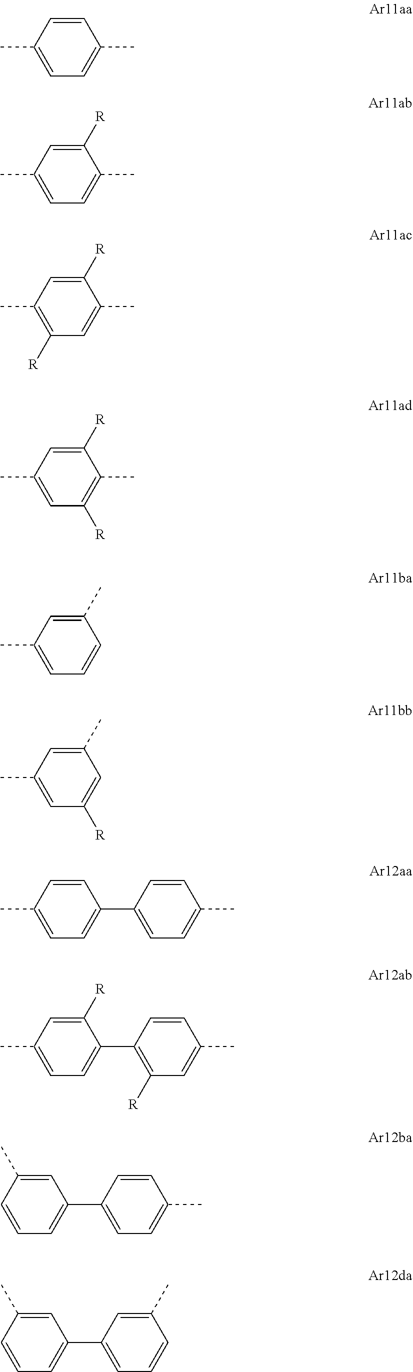

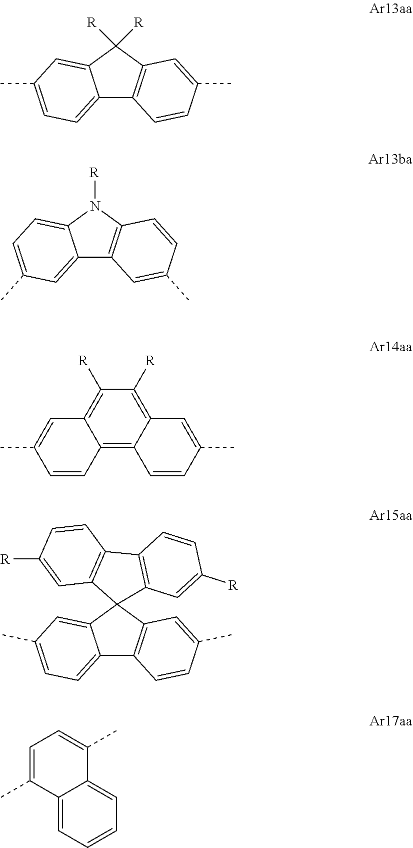

where R may assume the definitions given above in relation to the ring systems A.

Preferred structural units of the formula (I) are the structural units shown in the table below, composed of the respective units A, B, Ar¹, Ar², Ar³ and Ar⁴.

| Monomer | A | B | Ar1 | Ar2 | Ar3 | Ar4 |
|---|---|---|---|---|---|---|
| M1 | A1 | B1 | | | | |
| M2 | A2 | B1 | | | | |
| M3 | A3 | B1 | | | | |
| M4 | A4 | B1 | | | | |
| M5 | A5 | B1 | | | | |
| M6 | A6 | B1 | | | | |
| M7 | A7 | B1 | | | | |
| M8 | A8 | B1 | | | | |
| M9 | A1 | B2 | | | | |
| M10 | A2 | B2 | | | | |
| M11 | A3 | B2 | | | | |
| M12 | A4 | B2 | | | | |
| M13 | A5 | B2 | | | | |
| M14 | A6 | B2 | | | | |
| M15 | A7 | B2 | | | | |
| M16 | A8 | B2 | | | | |
| M17 | A1 | B3 | | | | |
| M18 | A2 | B3 | | | | |
| M19 | A3 | B3 | | | | |
| M20 | A4 | B3 | | | | |
| M21 | A5 | B3 | | | | |
| M22 | A6 | B3 | | | | |
| M23 | A7 | B3 | | | | |
| M24 | A8 | B3 | | | | |
| M25 | A1 | B4 | | | | |
| M26 | A2 | B4 | | | | |
| M27 | A3 | B4 | | | | |
| M28 | A4 | B4 | | | | |
| M29 | A5 | B4 | | | | |
| M30 | A6 | B4 | | | | |
| M31 | A7 | B4 | | | | |
| M32 | A8 | B4 | | | | |
| M33 | A1 | B1 | Ar11 | Ar1 | Ar1 | Ar11 |
| M34 | A1 | B1 | Ar11 | Ar2 | Ar2 | Ar11 |
| M35 | A1 | B1 | Ar11 | Ar3 | Ar3 | Ar11 |
| M36 | A1 | B1 | Ar11 | Ar4 | Ar4 | Ar11 |
| M37 | A1 | B1 | Ar11 | Ar5 | Ar5 | Ar11 |
| M38 | A1 | B1 | Ar11 | Ar6 | Ar6 | Ar11 |
| M39 | A1 | B1 | Ar11 | Ar7 | Ar7 | Ar11 |
| M40 | A1 | B1 | Ar11 | Ar8 | Ar8 | Ar11 |
| M41 | A1 | B1 | Ar11 | Ar9 | Ar9 | Ar11 |
| M42 | A1 | B1 | Ar11 | Ar10 | Ar10 | Ar11 |
| M43 | A1 | B1 | Ar12 | Ar1 | Ar1 | Ar12 |
| M44 | A1 | B1 | Ar12 | Ar2 | Ar2 | Ar12 |
| M45 | A1 | B1 | Ar12 | Ar3 | Ar3 | Ar12 |
| M46 | A1 | B1 | Ar12 | Ar4 | Ar4 | Ar12 |
| M47 | A1 | B1 | Ar12 | Ar5 | Ar5 | Ar12 |
| M48 | A1 | B1 | Ar12 | Ar6 | Ar6 | Ar12 |
| M49 | A1 | B1 | Ar12 | Ar7 | Ar7 | Ar12 |
| M50 | A1 | B1 | Ar12 | Ar8 | Ar8 | Ar12 |
| M51 | A1 | B1 | Ar12 | Ar9 | Ar9 | Ar12 |
| M52 | A1 | B1 | Ar12 | Ar10 | Ar10 | Ar12 |
| M53 | A1 | B1 | Ar13 | Ar1 | Ar1 | Ar13 |
| M54 | A1 | B1 | Ar13 | Ar2 | Ar2 | Ar13 |
| M55 | A1 | B1 | Ar13 | Ar3 | Ar3 | Ar13 |
| M56 | A1 | B1 | Ar13 | Ar4 | Ar4 | Ar13 |
| M57 | A1 | B1 | Ar13 | Ar5 | Ar5 | Ar13 |
| M58 | A1 | B1 | Ar13 | Ar6 | Ar6 | Ar13 |
| M59 | A1 | B1 | Ar13 | Ar7 | Ar7 | Ar13 |
| M60 | A1 | B1 | Ar13 | Ar8 | Ar8 | Ar13 |
| M61 | A1 | B1 | Ar13 | Ar9 | Ar9 | Ar13 |
| M62 | A1 | B1 | Ar13 | Ar10 | Ar10 | Ar13 |
| M63 | A1 | B1 | Ar14 | Ar1 | Ar1 | Ar14 |
| M64 | A1 | B1 | Ar14 | Ar2 | Ar2 | Ar14 |
| M65 | A1 | B1 | Ar14 | Ar3 | Ar3 | Ar14 |
| M66 | A1 | B1 | Ar14 | Ar4 | Ar4 | Ar14 |
| M67 | A1 | B1 | Ar14 | Ar5 | Ar5 | Ar14 |
| M68 | A1 | B1 | Ar14 | Ar6 | Ar6 | Ar14 |
| M69 | A1 | B1 | Ar14 | Ar7 | Ar7 | Ar14 |
| M70 | A1 | B1 | Ar14 | Ar8 | Ar8 | Ar14 |
| M71 | A1 | B1 | Ar14 | Ar9 | Ar9 | Ar14 |
| M72 | A1 | B1 | Ar14 | Ar10 | Ar10 | Ar14 |
| M73 | A1 | B1 | Ar15 | Ar1 | Ar1 | Ar15 |
| M74 | A1 | B1 | Ar15 | Ar2 | Ar2 | Ar15 |
| M75 | A1 | B1 | Ar15 | Ar3 | Ar3 | Ar15 |
| M76 | A1 | B1 | Ar15 | Ar4 | Ar4 | Ar15 |
| M77 | A1 | B1 | Ar15 | Ar5 | Ar5 | Ar15 |
| M78 | A1 | B1 | Ar15 | Ar6 | Ar6 | Ar15 |
| M79 | A1 | B1 | Ar15 | Ar7 | Ar7 | Ar15 |
| M80 | A1 | B1 | Ar15 | Ar8 | Ar8 | Ar15 |
| M81 | A1 | B1 | Ar15 | Ar9 | Ar9 | Ar15 |
| M82 | A1 | B1 | Ar15 | Ar10 | Ar10 | Ar15 |
| M83 | A1 | B1 | Ar16 | Ar1 | Ar1 | Ar16 |
| M84 | A1 | B1 | Ar16 | Ar2 | Ar2 | Ar16 |
| M85 | A1 | B1 | Ar16 | Ar3 | Ar3 | Ar16 |
| M86 | A1 | B1 | Ar16 | Ar4 | Ar4 | Ar16 |
| M87 | A1 | B1 | Ar16 | Ar5 | Ar5 | Ar16 |
| M88 | A1 | B1 | Ar16 | Ar6 | Ar6 | Ar16 |
| M89 | A1 | B1 | Ar16 | Ar7 | Ar7 | Ar16 |
| M90 | A1 | B1 | Ar16 | Ar8 | Ar8 | Ar16 |
| M91 | A1 | B1 | Ar16 | Ar9 | Ar9 | Ar16 |
| M92 | A1 | B1 | Ar16 | Ar10 | Ar10 | Ar16 |
| M93 | A1 | B1 | Ar17 | Ar1 | Ar1 | Ar17 |
| M94 | A1 | B1 | Ar17 | Ar2 | Ar2 | Ar17 |
| M95 | A1 | B1 | Ar17 | Ar3 | Ar3 | Ar17 |
| M96 | A1 | B1 | Ar17 | Ar4 | Ar4 | Ar17 |
| M97 | A1 | B1 | Ar17 | Ar5 | Ar5 | Ar17 |
| M98 | A1 | B1 | Ar17 | Ar6 | Ar6 | Ar17 |
| M99 | A1 | B1 | Ar17 | Ar7 | Ar7 | Ar17 |
| M100 | A1 | B1 | Ar17 | Ar8 | Ar8 | Ar17 |
| M101 | A1 | B1 | Ar17 | Ar9 | Ar9 | Ar17 |
| M102 | A1 | B1 | Ar17 | Ar10 | Ar10 | Ar17 |
| M103 | A1 | B1 | Ar18 | Ar1 | Ar1 | Ar18 |
| M104 | A1 | B1 | Ar18 | Ar2 | Ar2 | Ar18 |
| M105 | A1 | B1 | Ar18 | Ar3 | Ar3 | Ar18 |
| M106 | A1 | B1 | Ar18 | Ar4 | Ar4 | Ar18 |
| M107 | A1 | B1 | Ar18 | Ar5 | Ar5 | Ar18 |
| M108 | A1 | B1 | Ar18 | Ar6 | Ar6 | Ar18 |
| M109 | A1 | B1 | Ar18 | Ar7 | Ar7 | Ar18 |
| M110 | A1 | B1 | Ar18 | Ar8 | Ar8 | Ar18 |
| M111 | A1 | B1 | Ar18 | Ar9 | Ar9 | Ar18 |
| M112 | A1 | B1 | Ar18 | Ar10 | Ar10 | Ar18 |
| M113 | A1 | B2 | Ar11 | Ar1 | Ar1 | Ar11 |
| M114 | A1 | B3 | Ar12 | Ar3 | Ar3 | Ar12 |
| M115 | A1 | B4 | Ar11 | Ar9 | Ar9 | Ar11 |
| M116 | A2 | B1 | Ar11 | Ar3 | Ar3 | Ar11 |
| M117 | A3 | B1 | Ar12 | Ar7 | Ar7 | Ar12 |
| M118 | A4 | B1 | Ar11 | Ar3 | Ar3 | Ar11 |
| M119 | A5 | B1 | Ar11 | Ar3 | Ar3 | Ar11 |
| M120 | A6 | B1 | Ar11 | Ar3 | Ar3 | Ar11 |
| M121 | A7 | B1 | Ar11 | Ar3 | Ar3 | Ar11 |
| M122 | A8 | B1 | Ar11 | Ar3 | Ar3 | Ar11 |
| M123 | A1 | B1 | | Ar1 | Ar1 | |
| M124 | A1 | B1 | | Ar2 | Ar2 | |
| M125 | A1 | B1 | | Ar3 | Ar3 | |
| M126 | A1 | B1 | | Ar4 | Ar4 | |
| M127 | A1 | B1 | | Ar5 | Ar5 | |
| M128 | A1 | B1 | | Ar6 | Ar6 | |
| M129 | A1 | B1 | | Ar7 | Ar7 | |
| M130 | A1 | B1 | | Ar8 | Ar8 | |
| M131 | A1 | B1 | | Ar9 | Ar9 | |
| M132 | A1 | B1 | | Ar10 | Ar10 | |
| M133 | A1 | B1 | | Ar1 | Ar1 | |
| M134 | A1 | B1 | | Ar2 | Ar2 | |
| M135 | A1 | B1 | | Ar3 | Ar3 | |
| M136 | A1 | B1 | | Ar4 | Ar4 | |
| M137 | A1 | B1 | | Ar5 | Ar5 | |
| M138 | A1 | B1 | | Ar6 | Ar6 | |
| M139 | A1 | B1 | | Ar7 | Ar7 | |
| M140 | A1 | B1 | | Ar8 | Ar8 | |
| M141 | A1 | B1 | | Ar9 | Ar9 | |
| M142 | A1 | B1 | | Ar10 | Ar10 | |
| M143 | A1 | B1 | | Ar1 | Ar1 | |
| M144 | A1 | B1 | | Ar2 | Ar2 | |
| M145 | A1 | B1 | | Ar3 | Ar3 | |
| M146 | A1 | B1 | | Ar4 | Ar4 | |
| M147 | A1 | B1 | | Ar5 | Ar5 | |
| M148 | A1 | B1 | | Ar6 | Ar6 | |
| M149 | A1 | B1 | | Ar7 | Ar7 | |
| M150 | A1 | B1 | | Ar8 | Ar8 | |
| M151 | A1 | B1 | | Ar9 | Ar9 | |
| M152 | A1 | B1 | | Ar10 | Ar10 | |
| M153 | A1 | B1 | | Ar1 | Ar1 | |
| M154 | A1 | B1 | | Ar2 | Ar2 | |
| M155 | A1 | B1 | | Ar3 | Ar3 | |
| M156 | A1 | B1 | | Ar4 | Ar4 | |
| M157 | A1 | B1 | | Ar5 | Ar5 | |
| M158 | A1 | B1 | | Ar6 | Ar6 | |
| M159 | A1 | B1 | | Ar7 | Ar7 | |
| M160 | A1 | B1 | | Ar8 | Ar8 | |
| M161 | A1 | B1 | | Ar9 | Ar9 | |
| M162 | A1 | B1 | | Ar10 | Ar10 | |
| M163 | A1 | B1 | | Ar1 | Ar1 | |
| M164 | A1 | B1 | | Ar2 | Ar2 | |
| M165 | A1 | B1 | | Ar3 | Ar3 | |
| M166 | A1 | B1 | | Ar4 | Ar4 | |
| M167 | A1 | B1 | | Ar5 | Ar5 | |
| M168 | A1 | B1 | | Ar6 | Ar6 | |
| M169 | A1 | B1 | | Ar7 | Ar7 | |
| M170 | A1 | B1 | | Ar8 | Ar8 | |
| M171 | A1 | B1 | | Ar9 | Ar9 | |
| M172 | A1 | B1 | | Ar10 | Ar10 | |
| M173 | A1 | B1 | | Ar1 | Ar1 | |
| M174 | A1 | B1 | | Ar2 | Ar2 | |
| M175 | A1 | B1 | | Ar3 | Ar3 | |
| M176 | A1 | B1 | | Ar4 | Ar4 | |
| M177 | A1 | B1 | | Ar5 | Ar5 | |
| M178 | A1 | B1 | | Ar6 | Ar6 | |
| M179 | A1 | B1 | | Ar7 | Ar7 | |
| M180 | A1 | B1 | | Ar8 | Ar8 | |
| M181 | A1 | B1 | | Ar9 | Ar9 | |
| M182 | A1 | B1 | | Ar10 | Ar10 | |
| M183 | A1 | B1 | | Ar1 | Ar1 | |
| M184 | A1 | B1 | | Ar2 | Ar2 | |
| M185 | A1 | B1 | | Ar3 | Ar3 | |
| M186 | A1 | B1 | | Ar4 | Ar4 | |
| M187 | A1 | B1 | | Ar5 | Ar5 | |
| M188 | A1 | B1 | | Ar6 | Ar6 | |
| M189 | A1 | B1 | | Ar7 | Ar7 | |
| M190 | A1 | B1 | | Ar8 | Ar8 | |
| M191 | A1 | B1 | | Ar9 | Ar9 | |
| M192 | A1 | B1 | | Ar10 | Ar10 | |
| M193 | A1 | B1 | | Ar1 | Ar1 | |
| M194 | A1 | B1 | | Ar2 | Ar2 | |
| M195 | A1 | B1 | | Ar3 | Ar3 | |
| M196 | A1 | B1 | | Ar4 | Ar4 | |
| M197 | A1 | B1 | | Ar5 | Ar5 | |
| M198 | A1 | B1 | | Ar6 | Ar6 | |
| M199 | A1 | B1 | | Ar7 | Ar7 | |
| M200 | A1 | B1 | | Ar8 | Ar8 | |
| M201 | A1 | B1 | | Ar9 | Ar9 | |
| M202 | A1 | B1 | | Ar10 | Ar10 | |
| M203 | A1 | B2 | | Ar1 | Ar1 | |
| M204 | A1 | B3 | | Ar3 | Ar3 | |
| M205 | A1 | B4 | | Ar9 | Ar9 | |
| M206 | A2 | B1 | | Ar3 | Ar3 | |
| M207 | A3 | B1 | | Ar7 | Ar7 | |
| M208 | A4 | B1 | | Ar3 | Ar3 | |
| M209 | A5 | B1 | | Ar3 | Ar3 | |
| M210 | A6 | B1 | | Ar3 | Ar3 | |
| M211 | A7 | B1 | | Ar3 | Ar3 | |
| M212 | A8 | B1 | | Ar3 | Ar3 | |
| M213 | A1 | B1 | | | Ar1 | Ar11 |
| M214 | A1 | B1 | | | Ar2 | Ar11 |
| M215 | A1 | B1 | | | Ar3 | Ar11 |
| M216 | A1 | B1 | | | Ar4 | Ar11 |
| M217 | A1 | B1 | | | Ar5 | Ar11 |
| M218 | A1 | B1 | | | Ar6 | Ar11 |
| M219 | A1 | B1 | | | Ar7 | Ar11 |
| M220 | A1 | B1 | | | Ar8 | Ar11 |
| M221 | A1 | B1 | | | Ar9 | Ar11 |
| M222 | A1 | B1 | | | Ar10 | Ar11 |
| M223 | A1 | B1 | | | Ar1 | Ar12 |
| M224 | A1 | B1 | | | Ar2 | Ar12 |
| M225 | A1 | B1 | | | Ar3 | Ar12 |
| M226 | A1 | B1 | | | Ar4 | Ar12 |
| M227 | A1 | B1 | | | Ar5 | Ar12 |
| M228 | A1 | B1 | | | Ar6 | Ar12 |
| M229 | A1 | B1 | | | Ar7 | Ar12 |
| M230 | A1 | B1 | | | Ar8 | Ar12 |
| M231 | A1 | B1 | | | Ar9 | Ar12 |
| M232 | A1 | B1 | | | Ar10 | Ar12 |
| M233 | A1 | B1 | | | Ar1 | Ar13 |
| M234 | A1 | B1 | | | Ar2 | Ar13 |
| M235 | A1 | B1 | | | Ar3 | Ar13 |
| M236 | A1 | B1 | | | Ar4 | Ar13 |
| M237 | A1 | B1 | | | Ar5 | Ar13 |
| M238 | A1 | B1 | | | Ar6 | Ar13 |
| M239 | A1 | B1 | | | Ar7 | Ar13 |
| M240 | A1 | B1 | | | Ar8 | Ar13 |
| M241 | A1 | B1 | | | Ar9 | Ar13 |
| M242 | A1 | B1 | | | Ar10 | Ar13 |
| M243 | A1 | B1 | | | Ar1 | Ar14 |
| M244 | A1 | B1 | | | Ar2 | Ar14 |
| M245 | A1 | B1 | | | Ar3 | Ar14 |
| M246 | A1 | B1 | | | Ar4 | Ar14 |
| M247 | A1 | B1 | | | Ar5 | Ar14 |
| M248 | A1 | B1 | | | Ar6 | Ar14 |
| M249 | A1 | B1 | | | Ar7 | Ar14 |
| M250 | A1 | B1 | | | Ar8 | Ar14 |
| M251 | A1 | B1 | | | Ar9 | Ar14 |
| M252 | A1 | B1 | | | Ar10 | Ar14 |
| M253 | A1 | B1 | | | Ar1 | Ar15 |
| M254 | A1 | B1 | | | Ar2 | Ar15 |
| M255 | A1 | B1 | | | Ar3 | Ar15 |
| M256 | A1 | B1 | | | Ar4 | Ar15 |
| M257 | A1 | B1 | | | Ar5 | Ar15 |
| M258 | A1 | B1 | | | Ar6 | Ar15 |
| M259 | A1 | B1 | | | Ar7 | Ar15 |
| M260 | A1 | B1 | | | Ar8 | Ar15 |
| M261 | A1 | B1 | | | Ar9 | Ar15 |
| M262 | A1 | B1 | | | Ar10 | Ar15 |
| M263 | A1 | B1 | | | Ar1 | Ar16 |
| M264 | A1 | B1 | | | Ar2 | Ar16 |
| M265 | A1 | B1 | | | Ar3 | Ar16 |
| M266 | A1 | B1 | | | Ar4 | Ar16 |
| M267 | A1 | B1 | | | Ar5 | Ar16 |
| M268 | A1 | B1 | | | Ar6 | Ar16 |
| M269 | A1 | B1 | | | Ar7 | Ar16 |
| M270 | A1 | B1 | | | Ar8 | Ar16 |
| M271 | A1 | B1 | | | Ar9 | Ar16 |
| M272 | A1 | B1 | | | Ar10 | Ar16 |
| M273 | A1 | B1 | | | Ar1 | Ar17 |
| M274 | A1 | B1 | | | Ar2 | Ar17 |
| M275 | A1 | B1 | | | Ar3 | Ar17 |
| M276 | A1 | B1 | | | Ar4 | Ar17 |
| M277 | A1 | B1 | | | Ar5 | Ar17 |
| M278 | A1 | B1 | | | Ar6 | Ar17 |
| M279 | A1 | B1 | | | Ar7 | Ar17 |
| M280 | A1 | B1 | | | Ar8 | Ar17 |
| M281 | A1 | B1 | | | Ar9 | Ar17 |
| M282 | A1 | B1 | | | Ar10 | Ar17 |
| M283 | A1 | B1 | | | Ar1 | Ar18 |
| M284 | A1 | B1 | | | Ar2 | Ar18 |
| M285 | A1 | B1 | | | Ar3 | Ar18 |
| M286 | A1 | B1 | | | Ar4 | Ar18 |
| M287 | A1 | B1 | | | Ar5 | Ar18 |
| M288 | A1 | B1 | | | Ar6 | Ar18 |
| M289 | A1 | B1 | | | Ar7 | Ar18 |
| M290 | A1 | B1 | | | Ar8 | Ar18 |
| M291 | A1 | B1 | | | Ar9 | Ar18 |
| M292 | A1 | B1 | | | Ar10 | Ar18 |
| M293 | A1 | B2 | | | Ar1 | Ar11 |
| M294 | A1 | B3 | | | Ar3 | Ar12 |
| M295 | A1 | B4 | | | Ar9 | Ar11 |
| M296 | A2 | B1 | | | Ar3 | Ar11 |
| M297 | A3 | B1 | | | Ar7 | Ar12 |
| M298 | A4 | B1 | | | Ar3 | Ar11 |
| M299 | A5 | B1 | | | Ar3 | Ar11 |
| M300 | A6 | B1 | | | Ar3 | Ar11 |
| M301 | A7 | B1 | | | Ar3 | Ar11 |
| M302 | A8 | B1 | | | Ar3 | Ar11 |
| M303 | A1 | B1 | Ar11 | Ar1 | | |
| M304 | A1 | B1 | Ar11 | Ar2 | | |
| M305 | A1 | B1 | Ar11 | Ar3 | | |
| M306 | A1 | B1 | Ar11 | Ar4 | | |
| M307 | A1 | B1 | Ar11 | Ar5 | | |
| M308 | A1 | B1 | Ar11 | Ar6 | | |
| M309 | A1 | B1 | Ar11 | Ar7 | | |
| M310 | A1 | B1 | Ar11 | Ar8 | | |
| M311 | A1 | B1 | Ar11 | Ar9 | | |
| M312 | A1 | B1 | Ar11 | Ar10 | | |
| M313 | A1 | B1 | Ar12 | Ar1 | | |
| M314 | A1 | B1 | Ar12 | Ar2 | | |
| M315 | A1 | B1 | Ar12 | Ar3 | | |
| M316 | A1 | B1 | Ar12 | Ar4 | | |
| M317 | A1 | B1 | Ar12 | Ar5 | | |
| M318 | A1 | B1 | Ar12 | Ar6 | | |
| M319 | A1 | B1 | Ar12 | Ar7 | | |
| M320 | A1 | B1 | Ar12 | Ar8 | | |
| M321 | A1 | B1 | Ar12 | Ar9 | | |
| M322 | A1 | B1 | Ar12 | Ar10 | | |
| M323 | A1 | B1 | Ar13 | Ar1 | | |
| M324 | A1 | B1 | Ar13 | Ar2 | | |
| M325 | A1 | B1 | Ar13 | Ar3 | | |
| M326 | A1 | B1 | Ar13 | Ar4 | | |
| M327 | A1 | B1 | Ar13 | Ar5 | | |
| M328 | A1 | B1 | Ar13 | Ar6 | | |
| M329 | A1 | B1 | Ar13 | Ar7 | | |
| M330 | A1 | B1 | Ar13 | Ar8 | | |
| M331 | A1 | B1 | Ar13 | Ar9 | | |
| M332 | A1 | B1 | Ar13 | Ar10 | | |
| M333 | A1 | B1 | Ar14 | Ar1 | | |
| M334 | A1 | B1 | Ar14 | Ar2 | | |
| M335 | A1 | B1 | Ar14 | Ar3 | | |
| M336 | A1 | B1 | Ar14 | Ar4 | | |
| M337 | A1 | B1 | Ar14 | Ar5 | | |
| M338 | A1 | B1 | Ar14 | Ar6 | | |
| M339 | A1 | B1 | Ar14 | Ar7 | | |
| M340 | A1 | B1 | Ar14 | Ar8 | | |
| M341 | A1 | B1 | Ar14 | Ar9 | | |
| M342 | A1 | B1 | Ar14 | Ar10 | | |
| M343 | A1 | B1 | Ar15 | Ar1 | | |
| M344 | A1 | B1 | Ar15 | Ar2 | | |
| M345 | A1 | B1 | Ar15 | Ar3 | | |
| M346 | A1 | B1 | Ar15 | Ar4 | | |
| M347 | A1 | B1 | Ar15 | Ar5 | | |
| M348 | A1 | B1 | Ar15 | Ar6 | | |
| M349 | A1 | B1 | Ar15 | Ar7 | | |
| M350 | A1 | B1 | Ar15 | Ar8 | | |
| M351 | A1 | B1 | Ar15 | Ar9 | | |
| M352 | A1 | B1 | Ar15 | Ar10 | | |
| M353 | A1 | B1 | Ar16 | Ar1 | | |
| M354 | A1 | B1 | Ar16 | Ar2 | | |
| M355 | A1 | B1 | Ar16 | Ar3 | | |
| M356 | A1 | B1 | Ar16 | Ar4 | | |
| M357 | A1 | B1 | Ar16 | Ar5 | | |
| M358 | A1 | B1 | Ar16 | Ar6 | | |
| M359 | A1 | B1 | Ar16 | Ar7 | | |
| M360 | A1 | B1 | Ar16 | Ar8 | | |
| M361 | A1 | B1 | Ar16 | Ar9 | | |
| M362 | A1 | B1 | Ar16 | Ar10 | | |
| M363 | A1 | B1 | Ar17 | Ar1 | | |
| M364 | A1 | B1 | Ar17 | Ar2 | | |
| M365 | A1 | B1 | Ar17 | Ar3 | | |
| M366 | A1 | B1 | Ar17 | Ar4 | | |
| M367 | A1 | B1 | Ar17 | Ar5 | | |
| M368 | A1 | B1 | Ar17 | Ar6 | | |
| M369 | A1 | B1 | Ar17 | Ar7 | | |
| M370 | A1 | B1 | Ar17 | Ar8 | | |
| M371 | A1 | B1 | Ar17 | Ar9 | | |
| M372 | A1 | B1 | Ar17 | Ar10 | | |
| M373 | A1 | B1 | Ar18 | Ar1 | | |
| M374 | A1 | B1 | Ar18 | Ar2 | | |
| M375 | A1 | B1 | Ar18 | Ar3 | | |
| M376 | A1 | B1 | Ar18 | Ar4 | | |
| M377 | A1 | B1 | Ar18 | Ar5 | | |
| M378 | A1 | B1 | Ar18 | Ar6 | | |
| M379 | A1 | B1 | Ar18 | Ar7 | | |
| M380 | A1 | B1 | Ar18 | Ar8 | | |
| M381 | A1 | B1 | Ar18 | Ar9 | | |
| M382 | A1 | B1 | Ar18 | Ar10 | | |
| M383 | A1 | B2 | Ar11 | Ar1 | | |
| M384 | A1 | B3 | Ar12 | Ar3 | | |
| M385 | A1 | B4 | Ar11 | Ar9 | | |
| M386 | A2 | B1 | Ar11 | Ar3 | | |
| M387 | A3 | B1 | Ar12 | Ar7 | | |
| M388 | A4 | B1 | Ar11 | Ar3 | | |
| M389 | A5 | B1 | Ar11 | Ar3 | | |
| M390 | A6 | B1 | Ar11 | Ar3 | | |
| M391 | A7 | B1 | Ar11 | Ar3 | | |
| M392 | A8 | B1 | Ar11 | Ar3 | | |
| M393 | A1 | B1 | Ar11 | Ar1 | Ar2 | Ar11 |
| M394 | A1 | B1 | Ar11 | Ar3 | Ar9 | Ar11 |
| M395 | A1 | B1 | Ar11 | Ar3 | Ar4 | Ar11 |
| M396 | A1 | B1 | Ar11 | Ar2 | Ar3 | Ar11 |
| M397 | A1 | B1 | Ar11 | Ar5 | Ar8 | Ar11 |
| M398 | A1 | B1 | Ar12 | Ar3 | Ar6 | Ar12 |
| M399 | A1 | B1 | Ar12 | Ar3 | Ar7 | Ar12 |
| M400 | A1 | B1 | Ar12 | Ar3 | Ar3 | Ar11 |
| M401 | A1 | B1 | Ar11 | Ar3 | Ar3 | Ar13 |

Particularly preferred structural units of the formula (I) are the structural units shown in the table below, composed of the respective units A, B, Ar¹, Ar², Ar³ and Ar⁴.

| Monomer | A | B | Ar1 | Ar2 | Ar3 | Ar4 |
|---|---|---|---|---|---|---|
| Mo1 | A1a | B1a | | | | |
| Mo2 | A1a | B1b | | | | |
| Mo3 | A1a | B2a | | | | |
| Mo4 | A1a | B4a | | | | |
| Mo5 | A1a | B4b | | | | |
| Mo6 | A1a | B4c | | | | |
| Mo7 | A1a | B4d | | | | |
| Mo8 | A1b | B1a | | | | |
| Mo9 | A1b | B1b | | | | |
| Mo10 | A1b | B2a | | | | |
| Mo11 | A1c | B1a | | | | |
| Mo12 | A1c | B4d | | | | |
| Mo13 | A1d | B1a | | | | |
| Mo14 | A1d | B4c | | | | |
| Mo15 | A2a | B1a | | | | |
| Mo16 | A2a | B1b | | | | |
| Mo17 | A2a | B2a | | | | |
| Mo18 | A2a | B4a | | | | |
| Mo19 | A2a | B4b | | | | |
| Mo20 | A2a | B4c | | | | |
| Mo21 | A2a | B4d | | | | |
| Mo22 | A3a | B1a | | | | |
| Mo23 | A3a | B1b | | | | |
| Mo24 | A3a | B2a | | | | |
| Mo25 | A3a | B4a | | | | |
| Mo26 | A3a | B4b | | | | |
| Mo27 | A3a | B4c | | | | |
| Mo28 | A3a | B4d | | | | |
| Mo29 | A4a | B1b | | | | |
| Mo30 | A4a | B2a | | | | |
| Mo31 | A4a | B4a | | | | |
| Mo32 | A4a | B4b | | | | |
| Mo33 | A4a | B4c | | | | |
| Mo34 | A4a | B4d | | | | |
| Mo35 | A5a | B1b | | | | |
| Mo36 | A5a | B2a | | | | |
| Mo37 | A5a | B4a | | | | |
| Mo38 | A5a | B4b | | | | |
| Mo39 | A5a | B4c | | | | |
| Mo40 | A5a | B4d | | | | |
| Mo41 | A6a | B1a | | | | |
| Mo42 | A6a | B1b | | | | |
| Mo43 | A8a | B1a | | | | |
| Mo44 | A8a | B1b | | | | |
| Mo45 | A1a | B1a | Ar11a | Ar1a | Ar1a | Ar11a |
| Mo46 | A1a | B1a | Ar11b | Ar1a | Ar1a | Ar11b |
| Mo47 | A1a | B1a | Ar11c | Ar1a | Ar1a | Ar11c |
| Mo48 | A1a | B1a | Ar11a | Ar1b | Ar1b | Ar11a |
| Mo49 | A1a | B1a | Ar12a | Ar1b | Ar1b | Ar12a |
| Mo50 | A1a | B1a | Ar12d | Ar2a | Ar2a | Ar12d |
| Mo51 | A1a | B1a | Ar11a | Ar3a | Ar3a | Ar11a |
| Mo52 | A1a | B1a | Ar12a | Ar3a | Ar3a | Ar12a |
| Mo53 | A1a | B1a | Ar13a | Ar3a | Ar3a | Ar13a |
| Mo54 | A1a | B1a | Ar15a | Ar3a | Ar3a | Ar15a |
| Mo55 | A1a | B1a | Ar11a | Ar3b | Ar3b | Ar11a |
| Mo56 | A1a | B1a | Ar11a | Ar3c | Ar3c | Ar11a |
| Mo57 | A1a | B1a | Ar12d | Ar3c | Ar3c | Ar12d |
| Mo58 | A1a | B1a | Ar12d | Ar4a | Ar4a | Ar12d |
| Mo59 | A1a | B1a | Ar16a | Ar5a | Ar5a | Ar16a |
| Mo60 | A1a | B1a | Ar11b | Ar6a | Ar6a | Ar11b |
| Mo61 | A1a | B1a | Ar11a | Ar7a | Ar7a | Ar11a |
| Mo62 | A1a | B1a | Ar13c | Ar8a | Ar8a | Ari13c |
| Mo63 | A1a | B1a | Ar11a | Ar9a | Ar9a | Ar11a |
| Mo64 | A1a | B1a | Ar17a | Ar9b | Ar9b | Ar17a |
| Mo65 | A1a | B1a | Ar13d | Ar9c | Ar9c | Ar13d |
| Mo66 | A1a | B1a | Ar12e | Ar9d | Ar9d | Ar12e |
| Mo67 | A1a | B1a | Ar11a | Ar10a | Ar10a | Ar11a |
| Mo68 | A1a | B1a | Ar18a | Ar10b | Ar10b | Ar18a |
| Mo69 | A1a | B1a | Ar18c | Ar10c | Ar10c | Ar18c |
| Mo70 | A1a | B1b | Ar11a | Ar3a | Ar3a | Ar11a |
| Mo71 | A1a | B1b | Ar11a | Ar9a | Ar9a | Ar11a |
| Mo72 | A1a | B1b | Ar12d | Ar9a | Ar9a | Ar12d |
| Mo73 | A1b | B2a | Ar13a | Ar5a | Ar5a | Ar13a |
| Mo74 | A1d | B1a | Ar12c | Ar8a | Ar8a | Ar12c |
| Mo75 | A2a | B1a | Ar11a | Ar3a | Ar3a | Ar11a |
| Mo76 | A3a | B1b | Ar12a | Ar9a | Ar9a | Ar12a |
| Mo77 | A3a | B1a | Ar11a | Ar9c | Ar9c | Ar11a |
| Mo78 | A3a | B1a | Ar12d | Ar3c | Ar3c | Ar12d |
| Mo79 | A4a | B1b | Ar18c | Ar7a | Ar7a | Ar18c |
| Mo80 | A5a | B4c | Ar13d | Ar9d | Ar9d | Ar13d |
| Mo81 | A6a | B4a | Ar18a | Ar8a | Ar8a | Ar18a |
| Mo82 | A1a | B1a | | Ar1a | Ar1a | |
| Mo83 | A1a | B1a | | Ar1a | Ar1a | |
| Mo84 | A1a | B1a | | Ar1a | Ar1a | |
| Mo85 | A1a | B1a | | Ar1b | Ar1b | |
| Mo86 | A1a | B1a | | Ar1b | Ar1b | |
| Mo87 | A1a | B1a | | Ar2a | Ar2a | |
| Mo88 | A1a | B1a | | Ar3a | Ar3a | |
| Mo89 | A1a | B1a | | Ar3a | Ar3a | |
| Mo90 | A1a | B1a | | Ar3a | Ar3a | |
| Mo91 | A1a | B1a | | Ar3a | Ar3a | |
| Mo92 | A1a | B1a | | Ar3b | Ar3b | |
| Mo93 | A1a | B1a | | Ar3c | Ar3c | |
| Mo94 | A1a | B1a | | Ar3c | Ar3c | |
| Mo95 | A1a | B1a | | Ar4a | Ar4a | |
| Mo96 | A1a | B1a | | Ar5a | Ar5a | |
| Mo97 | A1a | B1a | | Ar6a | Ar6a | |
| Mo98 | A1a | B1a | | Ar7a | Ar7a | |
| Mo99 | A1a | B1a | | Ar8a | Ar8a | |
| Mo100 | A1a | B1a | | Ar9a | Ar9a | |
| Mo101 | A1a | B1a | | Ar9b | Ar9b | |
| Mo102 | A1a | B1a | | Ar9c | Ar9c | |
| Mo103 | A1a | B1a | | Ar9d | Ar9d | |
| Mo104 | A1a | B1a | | Ar10a | Ar10a | |
| Mo105 | A1a | B1a | | Ar10b | Ar10b | |
| Mo106 | A1a | B1a | | Ar10c | Ar10c | |
| Mo107 | A1a | B1b | | Ar3a | Ar3a | |
| Mo108 | A1a | B1b | | Ar9a | Ar9a | |
| Mo109 | A1a | B1b | | Ar9a | Ar9a | |
| Mo110 | A1b | B2a | | Ar5a | Ar5a | |
| Mo111 | A1d | B1a | | Ar8a | Ar8a | |
| Mo112 | A2a | B1a | | Ar3a | Ar3a | |
| Mo113 | A3a | B1b | | Ar9a | Ar9a | |
| Mo114 | A3a | B1a | | Ar9c | Ar9c | |
| Mo115 | A3a | B1a | | Ar3c | Ar3c | |
| Mo116 | A4a | B1b | | Ar7a | Ar7a | |
| Mo117 | A5a | B4c | | Ar9d | Ar9d | |
| Mo118 | A6a | B4a | | Ar8a | Ar8a | |
| Mo119 | A1a | B1a | | | Ar1a | Ar11a |
| Mo120 | A1a | B1a | | | Ar1a | Ar11b |
| Mo121 | A1a | B1a | | | Ar1a | Ar11c |
| Mo122 | A1a | B1a | | | Ar1b | Ar11a |
| Mo123 | A1a | B1a | | | Ar1b | Ar12a |
| Mo124 | A1a | B1a | | | Ar2a | Ar12d |
| Mo125 | A1a | B1a | | | Ar3 a | Ar11a |
| Mo126 | A1a | B1a | | | Ar3a | Ar12a |
| Mo127 | A1a | B1a | | | Ar3a | Ar13a |
| Mo128 | A1a | B1a | | | Ar3a | Ar15a |
| Mo129 | A1a | B1a | | | Ar3b | Ar11a |
| Mo130 | A1a | B1a | | | Ar3c | Ar11a |
| Mo131 | A1a | B1a | | | Ar3c | Ar12d |
| Mo132 | A1a | B1a | | | Ar4a | Ar12d |
| Mo133 | A1a | B1a | | | Ar5a | Ar16a |
| Mo134 | A1a | B1a | | | Ar6a | Ar11b |
| Mo135 | A1a | B1a | | | Ar7a | Ar11a |
| Mo136 | A1a | B1a | | | Ar8a | Ar13c |
| Mo137 | A1a | B1a | | | Ar9a | Ar11a |
| Mo138 | A1a | B1a | | | Ar9b | Ar17a |
| Mo139 | A1a | B1a | | | Ar9c | Ar13d |
| Mo140 | A1a | B1a | | | Ar9d | Ar12e |
| Mo141 | A1a | B1a | | | Ar10a | Ar11a |
| Mo142 | A1a | B1a | | | Ar10b | Ar18a |
| Mo143 | A1a | B1a | | | Ar10c | Ar18c |
| Mo144 | A1a | B1b | | | Ar3a | Ar11a |
| Mo145 | A1a | B1b | | | Ar9a | Ar11a |
| Mo146 | A1a | B1b | | | Ar9a | Ar12d |
| Mo147 | A1b | B2a | | | Ar5a | Ar13a |
| Mo148 | A1d | B1a | | | Ar8a | Ar12c |
| Mo149 | A2a | B1a | | | Ar3a | Ar11a |
| Mo150 | A3a | B1b | | | Ar9a | Ar12a |
| Mo151 | A3a | B1a | | | Ar9c | Ar11a |
| Mo152 | A3a | B1a | | | Ar3c | Ar12d |
| Mo153 | A4a | B1b | | | Ar7a | Ar18c |
| Mo154 | A5a | B4c | | | Ar9d | Ar13d |
| Mo155 | A6a | B4a | | | Ar8a | Ar18a |
| Mo156 | A1a | B1a | Ar11a | Ar1a | | |
| Mo157 | A1a | B1a | Ar11b | Ar1a | | |
| Mo158 | A1a | B1a | Ar11c | Ar1a | | |
| Mo159 | A1a | B1a | Ar11a | Ar1b | | |
| Mo160 | A1a | B1a | Ar12a | Ar1b | | |
| Mo161 | A1a | B1a | Ar12d | Ar2a | | |
| Mo162 | A1a | B1a | Ar11a | Ar3a | | |
| Mo163 | A1a | B1a | Ar12a | Ar3a | | |
| Mo164 | A1a | B1a | Ar13a | Ar3a | | |
| Mo165 | A1a | B1a | Ar15a | Ar3a | | |
| Mo166 | A1a | B1a | Ar11a | Ar3b | | |
| Mo167 | A1a | B1a | Ar11a | Ar3c | | |
| Mo168 | A1a | B1a | Ar12d | Ar3c | | |
| Mo169 | A1a | B1a | Ar12d | Ar4a | | |
| Mo170 | A1a | B1a | Ar16a | Ar5a | | |
| Mo171 | A1a | B1a | Ar11b | Ar6a | | |
| Mo172 | A1a | B1a | Ar11a | Ar7a | | |
| Mo173 | A1a | B1a | Ar13c | Ar8a | | |
| Mo174 | A1a | B1a | Ar11a | Ar9a | | |
| Mo175 | A1a | B1a | Ar17a | Ar9b | | |
| Mo176 | A1a | B1a | Ar13d | Ar9c | | |
| Mo177 | A1a | B1a | Ar12e | Ar9d | | |
| Mo178 | A1a | B1a | Ar11a | Ar10a | | |
| Mo179 | A1a | B1a | Ar18a | Ar10b | | |
| Mo180 | A1a | B1a | Ar18c | Ar10c | | |
| Mo181 | A1a | B1b | Ar11a | Ar3a | | |
| Mo182 | A1a | B1b | Ar11a | Ar9a | | |
| Mo183 | A1a | B1b | Ar12d | Ar9a | | |
| Mo184 | A1b | B2a | Ar13a | Ar5a | | |
| Mo185 | A1d | B1a | Ar12c | Ar8a | | |
| Mo186 | A2a | B1a | Ar11a | Ar3a | | |
| Mo187 | A3a | B1b | Ar12a | Ar9a | | |
| Mo188 | A3a | B1a | Ar11a | Ar9c | | |
| Mo189 | A3a | B1a | Ar12d | Ar3c | | |
| Mo190 | A4a | B1b | Ar18c | Ar7a | | |
| Mo191 | A5a | B4c | Ar13d | Ar9d | | |
| Mo192 | A6a | B4a | Ar18a | Ar8a | | |
| Mo193 | A1a | B1a | Ar11a | Ar3a | Ar3b | Ar11a |
| Mo194 | A1a | B1a | Ar11a | Ar3a | Ar9a | Ar11a |
| Mo195 | A1a | B1a | Ar12a | Ar2a | Ar2b | Ar12a |
| Mo196 | A1a | B1a | Ar11a | Ar3a | Ar3a | Ar11b |
| Mo197 | A1a | B1b | Ar12a | Ar3c | Ar3a | Ar12d |
| Mo198 | A1a | B1b | Ar11a | Ar9a | Ar9a | Ar12a |

Very particularly preferred structural units of the formula (I) are the structural units shown in the table below, composed of the respective units A, B, Ar¹, Ar², Ar³ and Ar⁴.

| Monomer | A | B | Ar1 | Ar2 | Ar3 | Ar4 |
|---|---|---|---|---|---|---|
| Mon1 | A1aa | B1aa | | | | |
| Mon2 | A1aa | B1ab | | | | |
| Mon3 | A1aa | B1ac | | | | |
| Mon4 | A1aa | B1ad | | | | |
| Mon5 | A1aa | B1ae | | | | |
| Mon6 | A1aa | B1ba | | | | |
| Mon7 | A1ba | B1aa | | | | |
| Mon8 | A1ba | B1bb | | | | |
| Mon9 | A1ba | B4aa | | | | |
| Mon10 | A2aa | B1ab | | | | |
| Mon11 | A2aa | B1ae | | | | |
| Mon12 | A2aa | B4ca | | | | |
| Mon13 | A3aa | B1ac | | | | |
| Mon14 | A3aa | B1bb | | | | |
| Mon15 | A5aa | B1aa | | | | |
| Mon16 | A5aa | B4ab | | | | |
| Mon17 | A8aa | B1ab | | | | |
| Mon18 | A8aa | B1ad | | | | |
| Mon19 | A1aa | B1aa | Ar11aa | Ar3a | Ar3a | Ar11aa |
| Mon20 | A1aa | B1aa | Ar11aa | Ar3b | Ar3b | Ar11aa |
| Mon21 | A1aa | B1aa | Ar11aa | Ar3c | Ar3c | Ar11aa |
| Mon22 | A1aa | B1aa | Ar11aa | Ar9a | Ar9a | Ar11aa |
| Mon23 | A1aa | B1aa | Ar11aa | Ar2a | Ar2a | Ar11aa |
| Mon24 | A1aa | B1aa | Ar12aa | Ar3a | Ar3a | Ar12aa |
| Mon25 | A1aa | B1aa | Ar12ab | Ar3c | Ar3c | Ar12ab |
| Mon26 | A1aa | B1aa | Ar12da | Ar1a | Ar1a | Ar12da |
| Mon27 | A1aa | B1aa | Ar13aa | Ar2a | Ar2a | Ar13aa |
| Mon28 | A1aa | B1ab | Ar11aa | Ar3a | Ar3a | Ar11aa |
| Mon29 | A1aa | B1ab | Ar11aa | Ar3b | Ar3b | Ar11aa |
| Mon30 | A1aa | B1ab | Ar11aa | Ar3c | Ar3c | Ar11aa |
| Mon31 | A1aa | B1ab | Ar11aa | Ar9a | Ar9a | Ar11aa |
| Mon32 | A1aa | B1ab | Ar11aa | Ar2a | Ar2a | Ar11aa |
| Mon33 | A1aa | B1ab | Ar12aa | Ar9a | Ar9a | Ar12aa |
| Mon34 | A1aa | B1ac | Ar11aa | Ar3a | Ar3a | Ar11aa |
| Mon35 | A1aa | B1ac | Ar11aa | Ar3b | Ar3b | Ar11aa |
| Mon36 | A1aa | B1ac | Ar11aa | Ar3c | Ar3c | Ar11aa |
| Mon37 | A1aa | B1ac | Ar11aa | Ar9a | Ar9a | Ar11aa |
| Mon38 | A1aa | B1ac | Ar11aa | Ar2b | Ar2b | Ar11aa |
| Mon39 | A1aa | B1ad | Ar11aa | Ar3a | Ar3a | Ar11aa |
| Mon40 | A1aa | B1ae | Ar12aa | Ar8a | Ar8a | Ar12aa |
| Mon41 | A1aa | B1ba | Ar11aa | Ar3c | Ar3c | Ar11aa |
| Mon42 | A1ba | B1bb | Ar11bb | Ar10b | Ar10b | Ar11bb |
| Mon43 | A2aa | B4aa | Ar17aa | Ar5a | Ar5a | A17aa |
| Mon44 | A3aa | B1aa | A11aa | Ar3a | Ar3a | A11aa |
| Mon45 | A3aa | B1ab | A12aa | Ar9a | Ar9a | A12aa |
| Mon46 | A5aa | B4ca | A13ba | Ar10c | Ar10c | A13ba |
| Mon47 | A1aa | B1aa | | Ar3a | Ar3a | |
| Mon48 | A1aa | B1aa | | Ar3b | Ar3b | |
| Mon49 | A1aa | B1aa | | Ar3c | Ar3c | |
| Mon50 | A1aa | B1aa | | Ar9a | Ar9a | |
| Mon51 | A1aa | B1aa | | Ar2a | Ar2a | |
| Mon52 | A1aa | B1aa | | Ar3a | Ar3a | |
| Mon53 | A1aa | B1aa | | Ar3c | Ar3c | |
| Mon54 | A1aa | B1aa | | Ar1a | Ar1a | |
| Mon55 | A1aa | B1aa | | Ar2a | Ar2a | |
| Mon56 | A1aa | B1ab | | Ar3a | Ar3a | |
| Mon57 | A1aa | B1ab | | Ar3b | Ar3b | |
| Mon58 | A1aa | B1ab | | Ar3c | Ar3c | |
| Mon59 | A1aa | B1ab | | Ar9a | Ar9a | |
| Mon60 | A1aa | B1ab | | Ar2a | Ar2a | |
| Mon61 | A1aa | B1ab | | Ar9a | Ar9a | |
| Mon62 | A1aa | B1ac | | Ar3a | Ar3a | |
| Mon63 | A1aa | B1ac | | Ar3b | Ar3b | |
| Mon64 | A1aa | B1ac | | Ar3c | Ar3c | |
| Mon65 | A1aa | B1ac | | Ar9a | Ar9a | |
| Mon66 | A1aa | B1ac | | Ar2b | Ar2b | |
| Mon67 | A1aa | B1ad | | Ar3a | Ar3a | |
| Mon68 | A1aa | B1ae | | Ar8a | Ar8a | |
| Mon69 | A1aa | B1ba | | Ar3c | Ar3c | |
| Mon70 | A1ba | B1bb | | Ar10b | Ar10b | |
| Mon71 | A2aa | B4aa | | Ar5a | Ar5a | |
| Mon72 | A3aa | B1aa | | Ar3a | Ar3a | |
| Mon73 | A3aa | B1ab | | Ar9a | Ar9a | |
| Mon74 | A5aa | B4ca | | Ar10c | Ar10c | |
| Mon75 | A1aa | B1aa | | | Ar3a | Ar11aa |
| Mon76 | A1aa | B1aa | | | Ar3b | Ar11aa |
| Mon77 | A1aa | B1aa | | | Ar3c | Ar11aa |
| Mon78 | A1aa | B1aa | | | Ar9a | Ar11aa |
| Mon79 | A1aa | B1aa | | | Ar2a | Ar11aa |
| Mon80 | A1aa | B1aa | | | Ar3a | Ar12aa |
| Mon81 | A1aa | B1aa | | | Ar3c | Ar12ab |
| Mon82 | A1aa | B1aa | | | Ar1a | Ar12da |
| Mon83 | A1aa | B1aa | | | Ar2a | Ar13aa |
| Mon84 | A1aa | B1ab | | | Ar3a | Ar11aa |
| Mon85 | A1aa | B1ab | | | Ar3b | Ar11aa |
| Mon86 | A1aa | B1ab | | | Ar3c | Ar11aa |
| Mon87 | A1aa | B1ab | | | Ar9a | Ar11aa |
| Mon88 | A1aa | B1ab | | | Ar2a | Ar11aa |
| Mon89 | A1aa | B1ab | | | Ar9a | Ar12aa |
| Mon90 | A1aa | B1ac | | | Ar3a | Ar11aa |
| Mon91 | A1aa | B1ac | | | Ar3b | Ar11aa |
| Mon123 | A1aa | B1ad | Ar11aa | Ar3a | | |
| Mon124 | A1aa | B1ae | Ar12aa | Ar8a | | |
| Mon125 | A1aa | B1ba | Ar11aa | Ar3c | | |
| Mon126 | A1ba | B1bb | Ar11bb | Ar10b | | |
| Mon127 | A2aa | B4aa | Ar17aa | Ar5a | | |
| Mon128 | A3aa | B1aa | A11aa | Ar3a | | |
| Mon129 | A3aa | B1ab | A12aa | Ar9a | | |
| Mon130 | A5aa | B4ca | A13ba | Ar10c | | |
| Mon131 | A1aa | B1aa | Ar11aa | Ar3a | Ar3b | Ar11aa |
| Mon132 | A1aa | B1aa | Ar11aa | Ar9a | Ar9a | Ar12aa |

The proportion of structural units of the formula (I), (Ia), (Ia1), (Ia2), (Ib), (Ic) or (Id) (X) in the polymer is in the range from 1 to 100 mol %.

In a first preferred embodiment, the inventive polymer contains only one structural unit of the formula (I), (Ia), (Ia1), (Ia2), (Ib), (Ic) or (Id), i.e. the proportion thereof in the polymer is 100 mol %. In this case, the polymer of the invention is a homopolymer.

In a second preferred embodiment, the proportion of structural units of the formula (I), (Ia), (Ia1), (Ia2), (Ib), (Ic) or (Id) in the polymer is in the range from 50 to 95 mol %, more preferably in the range from 60 to 95 mol %, based on 100 mol % of all copolymerizable monomers present as structural units in the polymer, meaning that the polymer of the invention, as well as one or more structural units of the formula (I), (Ia), (Ia1), (Ia2), (Ib), (Ic) and/or (Id), also has further structural units different than the structural units of the formulae (I), (Ia), (Ia1), (Ia2), (Ib), (Ic) and (Id).

In a third preferred embodiment, the proportion of structural units of the formula (I), (Ia), (Ia1), (Ia2), (Ib), (Ic) or (Id) in the polymer is in the range from 5 to 50 mol %, more preferably in the range from 25 to 50 mol %, based on 100 mol % of all copolymerizable monomers present as structural units in the polymer, meaning that the polymer of the invention, as well as one or more structural units of the formula (I), (Ia), (Ia1), (Ia2), (Ib), (Ic) and/or (Id), also has further structural units different than the structural units of the formulae (I), (Ia), (Ia1), (Ia2), (Ib), (Ic) and (Id).

These structural units different than the structural units of the formulae (I), (Ia), (Ia1), (Ia2), (Ib), (Ic) and (Id) include those as disclosed and extensively listed in WO 02/077060 A1, in WO 2005/014689 A2 and in WO 2013/156130. These are considered to form part of the present invention by reference. The further structural units may come, for example, from the following classes:
Group 1: units which influence the hole injection and/or hole transport properties of the polymers;
Group 2: units which influence the electron injection and/or electron transport properties of the polymers;
Group 3: units having combinations of individual units of group 1 and group 2;
Group 4: units which alter the emission characteristics in such a way that electrophosphorescence rather than electrofluorescence is obtainable;
Group 5: units which improve the transition from the singlet to the triplet state;
Group 6: units which affect the emission color of the resulting polymers;
Group 7: units which are typically used as polymer backbone;
Group 8: units which interrupt the delocalization of the π electrons in the polymer and hence shorten the conjugation length in the polymer.

Preferred polymers of the invention are those in which at least one structural unit has charge transport properties, i.e. those which contain the units from group 1 and/or 2.

Structural units from group 1 having hole injection and/or hole transport properties are, for example, triarylamine, benzidine, tetraaryl-para-phenylenediamine, triarylphosphine, phenothiazine, phenoxazine, dihydrophenazine, thianthrene, dibenzo-para-dioxin, phenoxathiine, carbazole, azulene, thiophene, pyrrole and furan derivatives and further O-, S- or N-containing heterocycles.

Structural units from group 2 having electron injection and/or electron transport properties are, for example, pyridine, pyrimidine, pyridazine, pyrazine, oxadiazole, quinoline, quinoxaline, anthracene, benzanthracene, pyrene, perylene, benzimidazole, triazine, ketone, phosphine oxide and phenazine derivatives, but also triarylboranes and further O-, S- or N-containing heterocycles.

It may be preferable when the polymers of the invention contain units from group 3 in which structures which increase hole mobility and which increase electron mobility (i.e. units from group 1 and 2) are bonded directly to one another or structures which increase both hole mobility and electron mobility are present. Some of these units may serve as emitters and shift the emission color into the green, yellow or red. The use thereof is thus suitable, for example, for the creation of other emission colors from originally blue-emitting polymers.

Structural units of group 4 are those which can emit light with high efficiency from the triplet state even at room temperature, i.e. exhibit electrophosphorescence rather than electrofluorescence, which frequently brings about an increase in energy efficiency. Suitable for this purpose, first of all, are compounds containing heavy atoms having an atomic number of more than 36. Preferred compounds are those which contain d or f transition metals, which fulfill the abovementioned condition. Particular preference is given here to corresponding structural units containing elements of groups 8 to 10 (Ru, Os, Rh, Ir, Pd, Pt). Useful structural units here for the polymers of the invention include, for example, various complexes as described, for example, in WO 02/068435 A1, WO 02/081488 A1, EP 1239526 A2 and WO 2004/026886 A2. Corresponding monomers are described in WO 02/068435 A1 and in WO 2005/042548 A1.

Structural units of group 5 are those which improve the transition from the singlet to the triplet state and which, used in association with the structural elements of group 4, improve the phosphorescence properties of these structural elements. Useful units for this purpose are especially carbazole and bridged carbazole dimer units, as described, for example, in WO 2004/070772 A2 and WO 2004/113468 A1. Additionally useful for this purpose are ketones, phosphine oxides, sulfoxides, sulfones, silane derivatives and similar compounds, as described, for example, in WO 2005/040302 A1.

Structural units of group 6 are, as well as those mentioned above, those which include at least one further aromatic structure or another conjugated structure which are not among the abovementioned groups, i.e. which have only little effect on the charge carrier mobilities, which are not organometallic complexes or which have no effect on the singlet-triplet transition. Structural elements of this kind can affect the emission color of the resulting polymers. According to the unit, they can therefore also be used as emitters. Preference is given to aromatic structures having 6 to 40 carbon atoms or else tolane, stilbene or bisstyrylarylene derivatives which may each be substituted by one or more R radicals. Particular preference is given to the incorporation of 1,4- or 9,10-anthrylene, 1,6-, 2,7- or 4,9-pyrenylene, 3,9- or 3,10-perylenylene, 4,4′-tolanylene, 4,4′-stilbenylene, benzothiadiazole and corresponding oxygen derivatives, quinoxaline, phenothiazine, phenoxazine, dihydrophenazine, bis(thiophenyl)arylene, oligo(thiophenylene), phenazine, rubrene, pentacene or perylene derivatives which are preferably substituted, or preferably conjugated push-pull systems (systems substituted by donor and acceptor substituents) or systems such as squarines or quinacridones which are preferably substituted.

Structural units of group 7 are units including aromatic structures having 6 to 40 carbon atoms, which are typically used as the polymer backbone. These are, for example, 4,5-dihydropyrene derivatives, 4,5,9,10-tetrahydropyrene derivatives, fluorene derivatives, 9,9′-spirobifluorene derivatives, phenanthrene derivatives, 9,10-dihydrophenanthrene derivatives, 5,7-dihydrodibenzooxepine derivatives and cis- and trans-indenofluorene derivatives, but also 1,2-, 1,3- or 1,4-phenylene, 1,2-, 1,3- or 1,4-naphthylene, 2,2′-, 3,3′- or 4,4′-biphenylylene, 2,2″-, 3,3″- or 4,4″-terphenylylene, 2,2′-, 3,3′- or 4,4′-bi-1,1′-naphthylylene or 2,2′″-, 3,3′″- or 4,4′″-quaterphenylylene derivatives.

Structural units of group 8 are those that have conjugation-interrupting properties, for example via meta bonding, steric hindrance or use of saturated carbon or silicon atoms. Compounds of this kind are disclosed, for example, in WO2006/063852, WO 2012/048778 and WO 2013/093490. The conjugation-interrupting properties of the structural units of group 8 are manifested inter alia by a blue shift in the absorption edge of the polymer.

Preference is given to polymers of the invention which simultaneously contain, as well as structural units of the formula (I), (Ia), (Ia1), (Ia2), (Ib), (Ic) and (Id), additionally one or more units selected from groups 1 to 8. It may likewise be preferable when more than one further structural unit from one group is simultaneously present.

Preference is given here to polymers of the invention that contain, as well as at least one structural unit of the formula (I), (Ia), (Ia1), (Ia2), (Ib), (Ic) and (Id), also units from group 7.

It is likewise preferable when the polymers of the invention contain units which improve charge transport or charge injection, i.e. units from group 1 and/or 2.

It is additionally particularly preferable when the polymers of the invention contain structural units from group 7 and units from group 1 and/or 2.

If the polymer of the invention contains one or more units selected from groups 1 to 8, one or more of these units, preferably a unit from group 1, may have one or more crosslinkable groups, preferably one crosslinkable group.

The polymers of the invention are either homopolymers composed of structural units of the formula (I), (Ia), (Ia1), (Ia2), (Ib), (Ic) and (Id) or copolymers. The polymers of the invention may be linear or branched, preferably linear. Copolymers of the invention may, as well as one or more structural units of the formula (I), (Ia), (Ia1), (Ia2), (Ib), (Ic) and (Id), potentially have one or more further structures from the above-detailed groups 1 to 8.

The copolymers of the invention may have random, alternating or block structures, or else have two or more of these structures in alternation. More preferably, the copolymers of the invention have random or alternating structures. More preferably, the copolymers are random or alternating copolymers. The way in which copolymers having block structures are obtainable and which further structural elements are particularly preferred for the purpose is described in detail, for example, in WO 2005/014688 A2. This is incorporated into the present application by reference. It should likewise be emphasized once again at this point that the polymer may also have dendritic structures.

In a further embodiment of the present invention, the polymers of the invention contain, as well as one or more structural units of the formula (I), (Ia), (Ia1), (Ia2), (Ib), (Ic) and/or (Id) and optionally further structural units selected from the abovementioned groups 1 to 8, also at least one, preferably one, structural unit having a crosslinkable Q group.

“Crosslinkable Q group” in the context of the present invention means a functional group capable of entering into a reaction and thus forming an insoluble compound. The reaction may be with a further identical Q group, a further different Q group or any other portion of the same or another polymer chain. The crosslinkable group is thus a reactive group. This affords, as a result of the reaction of the crosslinkable group, a correspondingly crosslinked compound. The chemical reaction can also be conducted in the layer, giving rise to an insoluble layer. The crosslinking can usually be promoted by means of heat or by means of UV radiation, microwave radiation, x-radiation or electron beams, optionally in the presence of an initiator. “Insoluble” in the context of the present invention preferably means that the inventive polymer, after the crosslinking reaction, i.e. after the reaction of the crosslinkable groups, has a lower solubility at room temperature in an organic solvent by at least a factor of 3, preferably at least a factor of 10, than that of the corresponding non-crosslinked inventive polymer in the same organic solvent.

The structural unit that bears the crosslinkable Q group may, in a first embodiment, be selected from the structural units of the formulae (I), (Ia), (Ia1), (Ia2), (Ib), (Ic) and (Id).

In a first embodiment, the structural units that bear the crosslinkable Q group are the following structural units, derived from the structural unit of the formula (I), of the formulae (IIa) to (IIf):

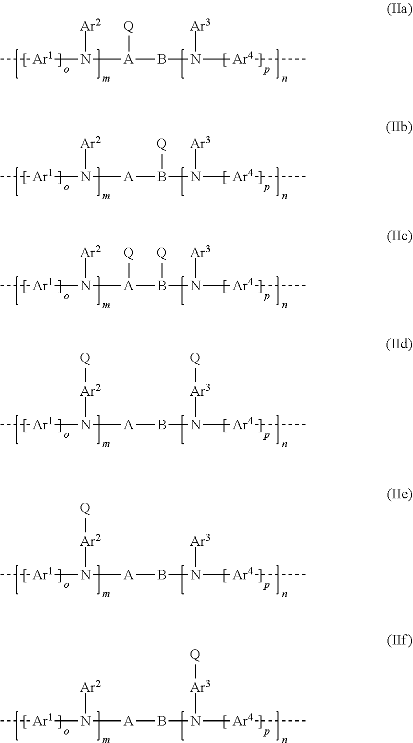

where A, B, Ar¹, Ar², Ar³, Ar⁴, m, n, o and p may assume the definitions given above in relation to formula (I) and Q is a crosslinkable group.

In a first preferred embodiment, the structural units that bear the crosslinkable Q group are the following structural units, derived from the structural unit of the formula (Ia), of the formulae (IIIa) to (IIIf):

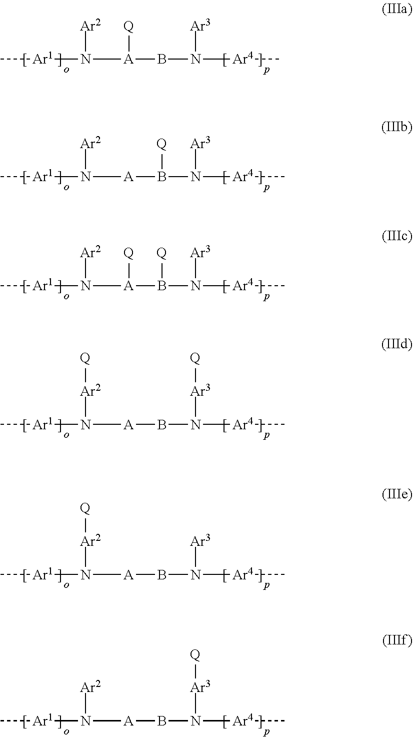

where A, B, Ar¹, Ar², Ar³, Ar⁴, o and p may assume the definitions given above in relation to formula (I) and Q is a crosslinkable group.

In a first particularly preferred embodiment, the structural units that bear the crosslinkable Q group are the following structural units, derived from the structural unit of the formula (Ia1), of the formulae (IIIa) to (IIIf):

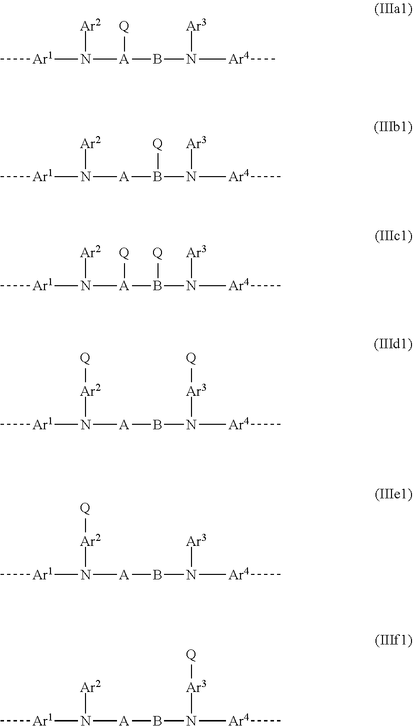

where A, B, Ar¹, Ar², Ar³ and Ar⁴ may assume the definitions given above in relation to formula (I) and Q is a crosslinkable group.

In a second particularly preferred embodiment, the structural units that bear the crosslinkable Q group are the following structural units, derived from the structural unit of the formula (Ia1), of the formulae (IVa) to (IVf):

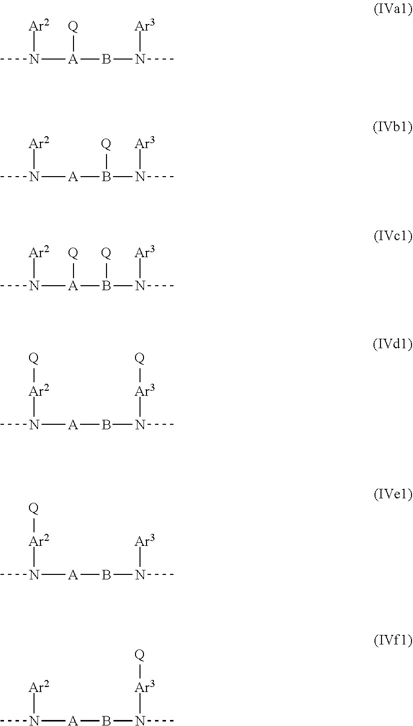

where A, B, Ar¹, Ar², Ar³ and Ar⁴ may assume the definitions given above in relation to formula (I) and Q is a crosslinkable group.

In a second preferred embodiment, the structural units that bear the crosslinkable Q group are the following structural units, derived from the structural unit of the formula (Ib), of the formulae (Va) to (Vc):

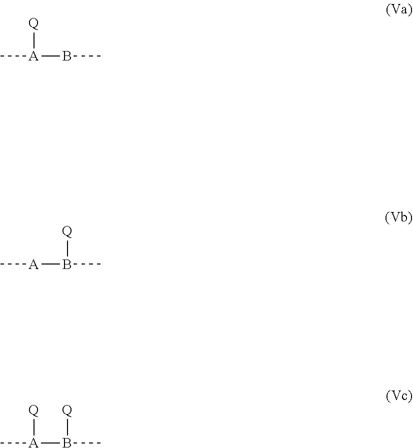

where A and B may assume the definitions given above in relation to formula (I) and Q is a crosslinkable group.

In a third preferred embodiment, the structural units that bear the crosslinkable Q group are structural units derived from the structural unit of the formula (Ic) in which A, B and/or Ar² bear the crosslinkable Q group.

In a fourth preferred embodiment, the structural units that bear the crosslinkable Q group are structural units derived from the structural unit of the formula (Id) in which A, B and/or Ar³ bear the crosslinkable Q group.

Crosslinkable Q groups preferred in accordance with the invention are the following groups:

a) Terminal or Cyclic Alkenyl or Terminal Dienyl and Alkynyl Groups:

Suitable units are those which contain a terminal or cyclic double bond, a terminal dienyl group or a terminal triple bond, especially terminal or cyclic alkenyl, terminal dienyl or terminal alkynyl groups having 2 to 40 carbon atoms, preferably having 2 to 10 carbon atoms, where individual CH₂ groups and/or individual hydrogen atoms may also be replaced by the abovementioned R groups. Additionally suitable are also groups which are to be regarded as precursors and which are capable of in situ formation of a double or triple bond.

b) Alkenyloxy, Dienyloxy or Alkynyloxy Groups:

Additionally suitable are alkenyloxy, dienyloxy or alkynyloxy groups, preferably alkenyloxy groups.

c) Acrylic Acid Groups:

Additionally suitable are acrylic acid units in the broadest sense, preferably acrylic esters, acrylamides, methacrylic esters and methacrylamides. Particular preference is given to C₁₋₁₀-alkyl acrylate and C₁₋₁₀-alkyl methacrylate.

The crosslinking reaction of the groups mentioned above under a) to c) can be effected via a free-radical, cationic or anionic mechanism, or else via cycloaddition.

It may be advisable to add an appropriate initiator for the crosslinking reaction. Suitable initiators for the free-radical crosslinking are, for example, dibenzoyl peroxide, AIBN or TEMPO. Suitable initiators for the cationic crosslinking are, for example, AlCl₃, BF₃, triphenylmethyl perchlorate or tropylium hexachloroantimonate. Suitable initiators for the anionic crosslinking are bases, especially butyllithium.

In a preferred embodiment of the present invention, the crosslinking, however, is conducted without the addition of an initiator and is initiated exclusively by thermal means. The reason for this preference is that the absence of the initiator prevents contamination of the layer which could lead to worsening of the device properties.

d) Oxetanes and Oxiranes:

A further suitable class of crosslinkable Q groups is that of oxetanes and oxiranes which crosslink cationically via ring opening.

It may be advisable to add an appropriate initiator for the crosslinking reaction. Suitable initiators are, for example, AlCl₃, BF₃, triphenylmethyl perchlorate or tropylium hexachloroantimonate. It is likewise possible to add photoacids as initiators.

e) Silanes:

Additionally suitable as a class of crosslinkable groups are silane groups SiR₃ where at least two R groups, preferably all three R groups, are Cl or an alkoxy group having 1 to 20 carbon atoms.

This group reacts in the presence of water to give an oligo- or polysiloxane.

f) Cyclobutane Groups

The crosslinkable Q groups mentioned above under a) to f) are generally known to those skilled in the art, as are the suitable reaction conditions which are used for reaction of these groups.

Preferred crosslinkable Q groups include alkenyl groups of the following formula Q1, dienyl groups of the following formula Q2, alkynyl groups of the following formula Q3, alkenyloxy groups of the following formula Q4, dienyloxy groups of the following formula Q5, alkynyloxy groups of the following formula Q6, acrylic acid groups of the following formulae Q7 and Q8, oxetane groups of the following formulae Q9 and Q10, oxirane groups of the following formula Q11, cyclobutane groups of the following formulae Q12, Q13 and Q14:

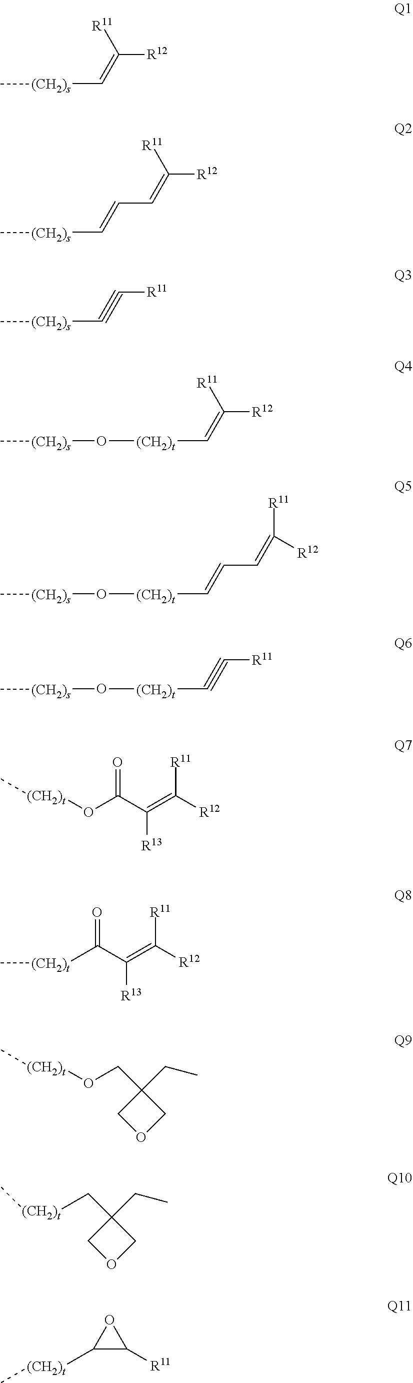

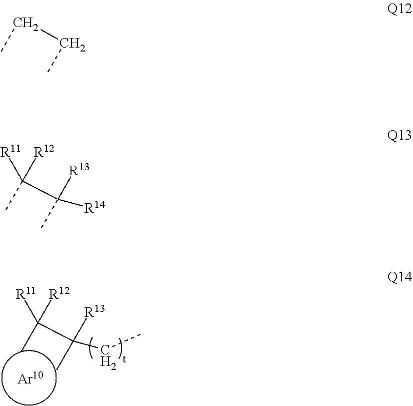

The R¹¹, R¹², R¹³ and R¹⁴ radicals in the formulae Q1 to Q8, Q11, Q13 and Q14 are the same or different at each instance and are H or a straight-chain or branched alkyl group having 1 to 6 carbon atoms, preferably 1 to 4 carbon atoms. More preferably, R¹¹, R¹², R¹³ and R¹⁴ are H, methyl, ethyl, n-propyl, isopropyl, n-butyl, sec-butyl or tert-butyl and most preferably H or methyl. The indices used have the following meaning: s=0 to 8; and t=1 to 8.

Ar¹⁰ in the formula Q14 may assume the same definitions as Ar¹ in formula (I).

The dotted bond in the formulae Q1 to Q11 and Q14 and the dotted bonds in the formulae Q12 and Q13 represent the linkage of the crosslinkable group to the structural units.

The crosslinkable groups of the formulae Q1 to Q14 may be joined directly to the structural unit, or else indirectly, via a further mono- or polycyclic, aromatic or heteroaromatic ring system Ar¹⁰, as shown in the following formulae Q15 to Q28:

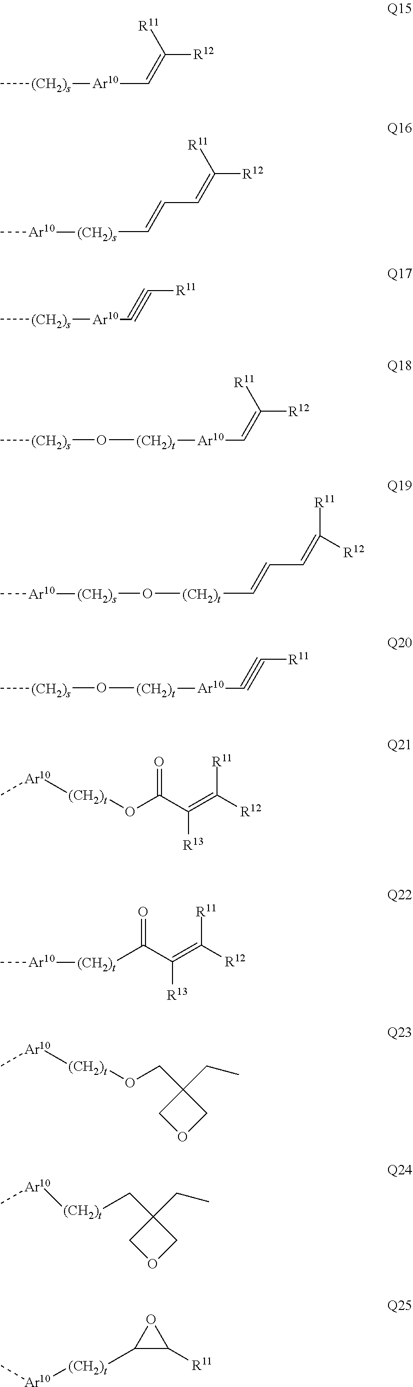

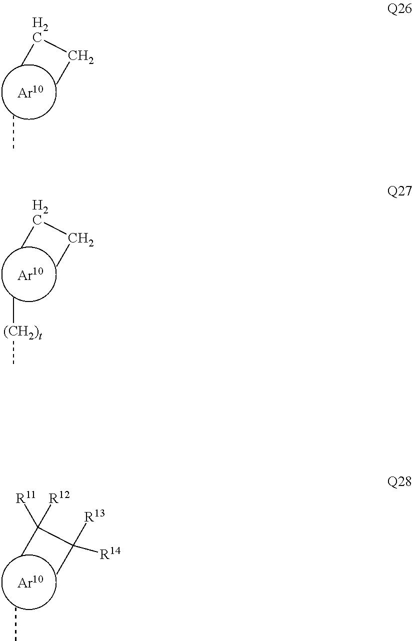

where Ar¹⁰ in the formulae Q15 to Q28 may assume the same definitions as Ar¹ in formula (I).

Particularly preferred crosslinkable Q groups are as follows:

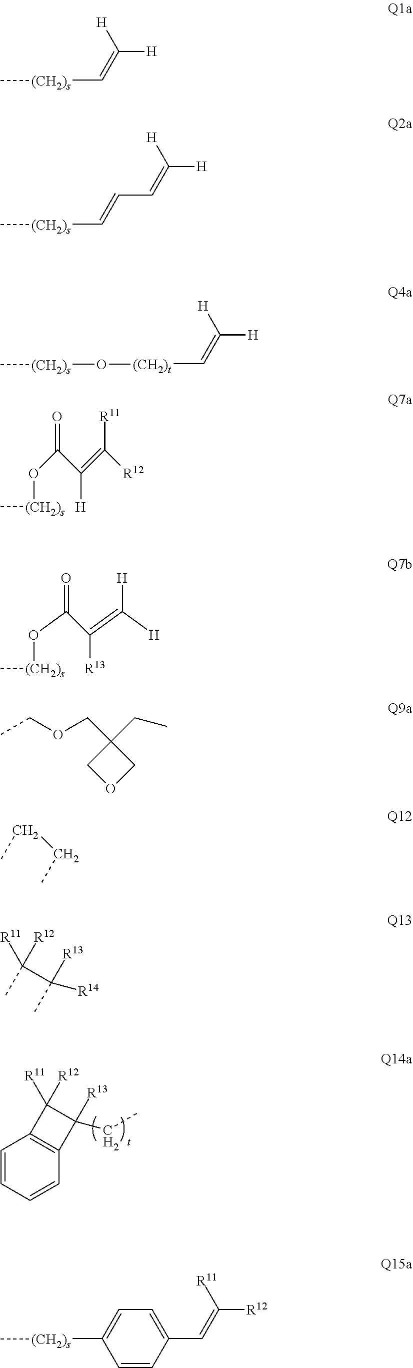

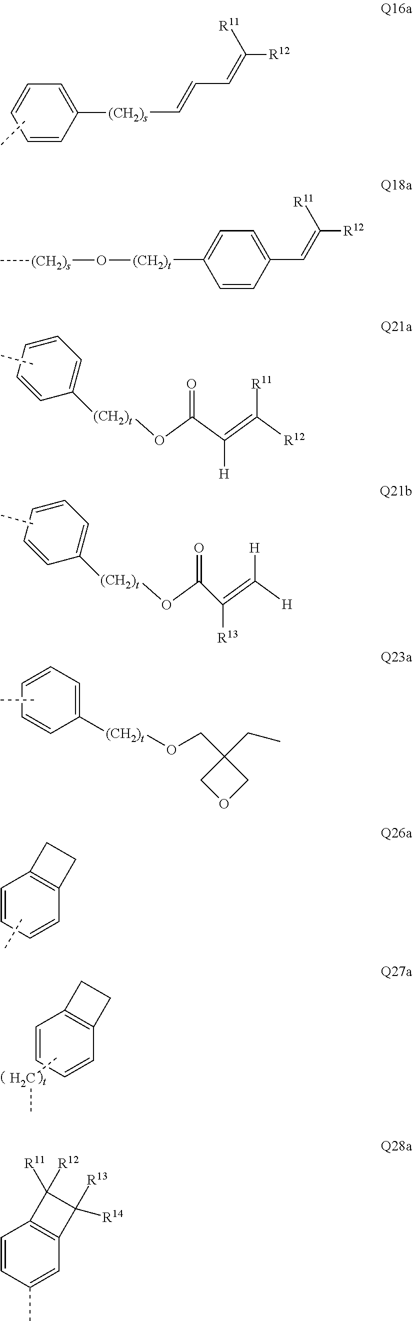

The R¹¹, R¹², R¹³ and R¹⁴ radicals are the same or different at each instance and are H or a straight-chain or branched alkyl group having 1 to 6 carbon atoms, preferably 1 to 4 carbon atoms. More preferably, the R¹¹, R¹², R¹³ and R¹⁴ radicals are methyl, ethyl, n-propyl, isopropyl, n-butyl, sec-butyl or tert-butyl and most preferably methyl.

The indices used have the following meaning: s=0 to 8 and t=1 to 8.

Very particularly preferred crosslinkable Q groups are as follows:

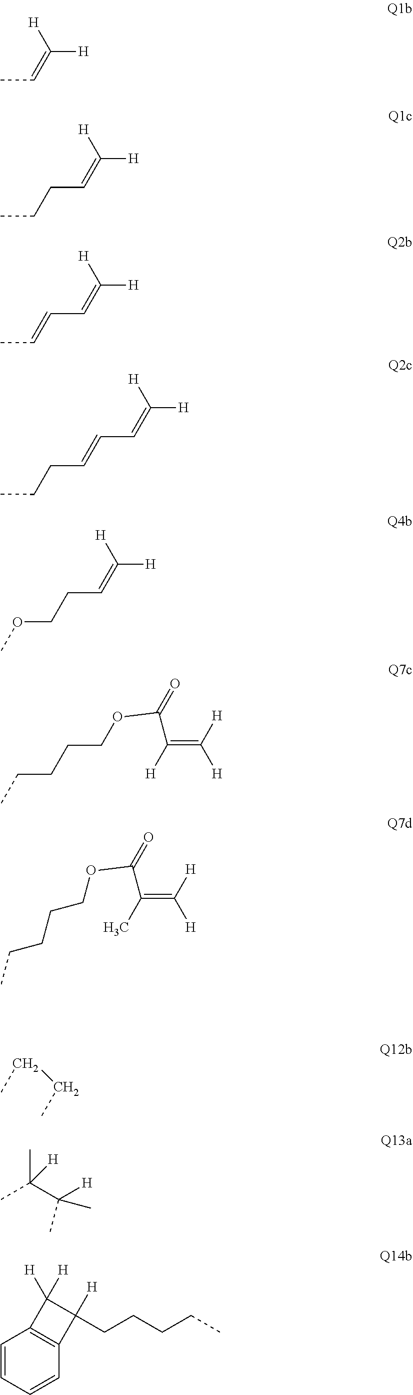

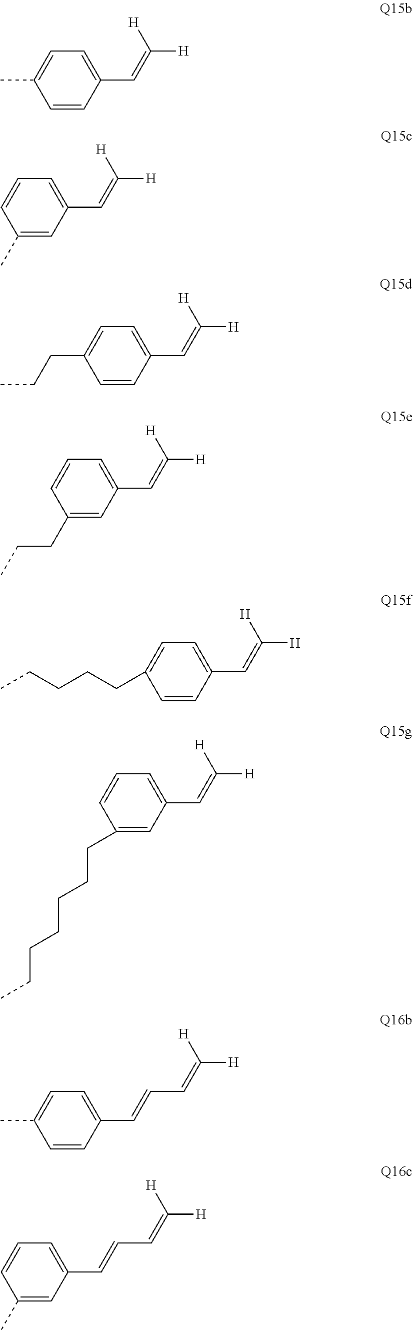

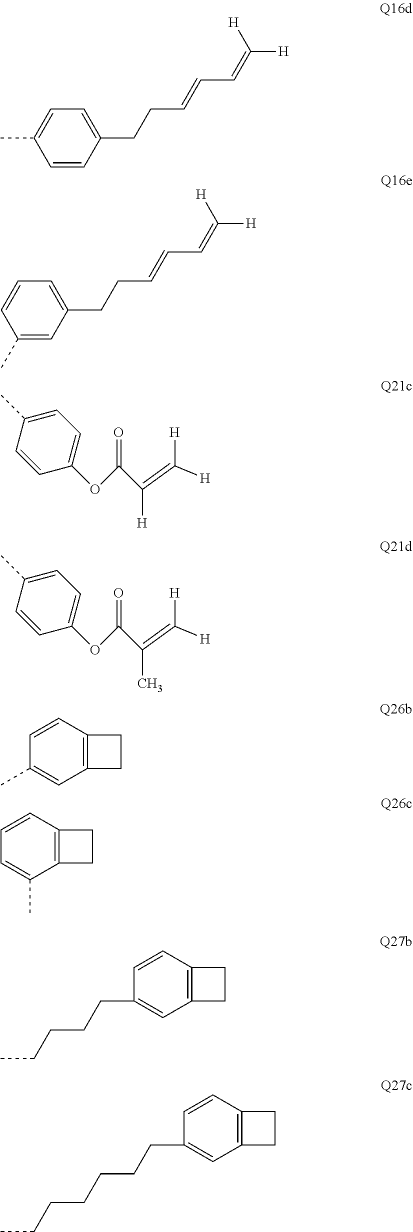

In the structural units of the formulae (IIa), (IIc), (IIIa), (IIIc), (Va) and (Vc), in which the polycyclic aromatic or heteroaromatic ring system A has at least one crosslinkable Q group, A is preferably selected from the following units A11a to A16b:

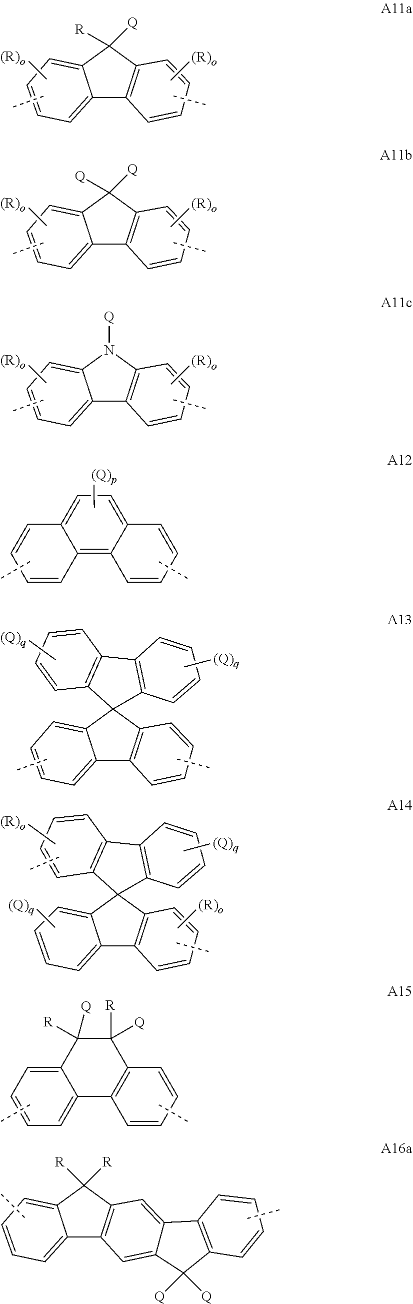

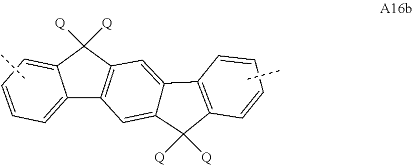

where R may assume the definitions given above, Q is a crosslinkable group,

o=0, 1, 2 or 3,

p=0, 1 or 2 and

q=0, 1, 2, 3 or 4.

In the structural units of the formulae (IIa), (IIc), (IIIa), (IIIc), (IVa) and (IVc), in which the polycyclic aromatic or heteroaromatic ring system A has at least one crosslinkable Q group, A is more preferably selected from the following units A11a1 to A13a1:

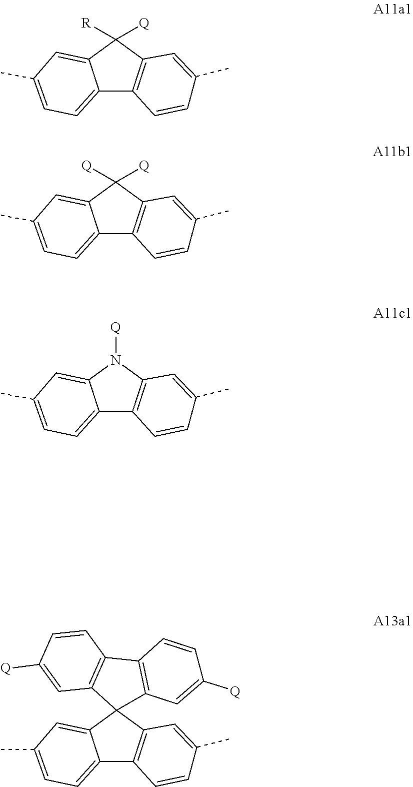

where R may assume the definitions given above and Q is a crosslinkable group.

In the structural units of the formulae (IIb), (IIc), (IIIb), (IIIc), (Vb) and (Vc), in which the mono- or polycyclic, aromatic or heteroaromatic ring system B has at least one crosslinkable Q group, B is preferably selected from the following units B11a to B14f:

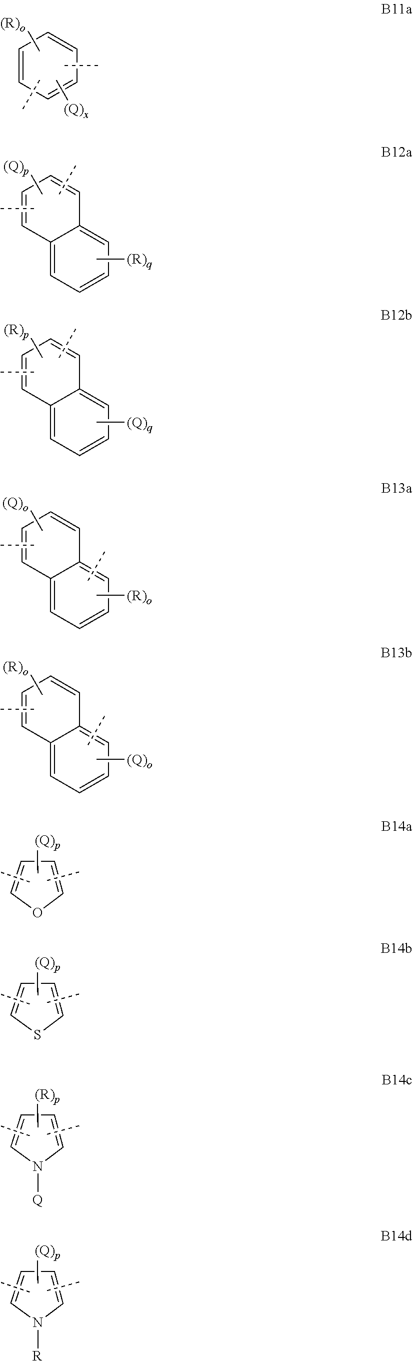

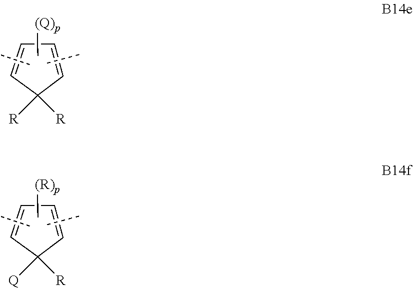

where R may assume the definitions given above, Q is a crosslinkable group,

o=0, 1, 2 or 3,

p=0, 1 or 2,

q=0, 1, 2, 3 or 4, and

x=1, 2, 3 or 4, where x+o≤4.

In the structural units of the formulae (IIb), (IIc), (IIIb), (IIIc), (Vb) and (Vc), in which the mono- or polycyclic, aromatic or heteroaromatic ring system B has at least one crosslinkable Q group, B is more preferably selected from the following units B11a1 to B14c1:

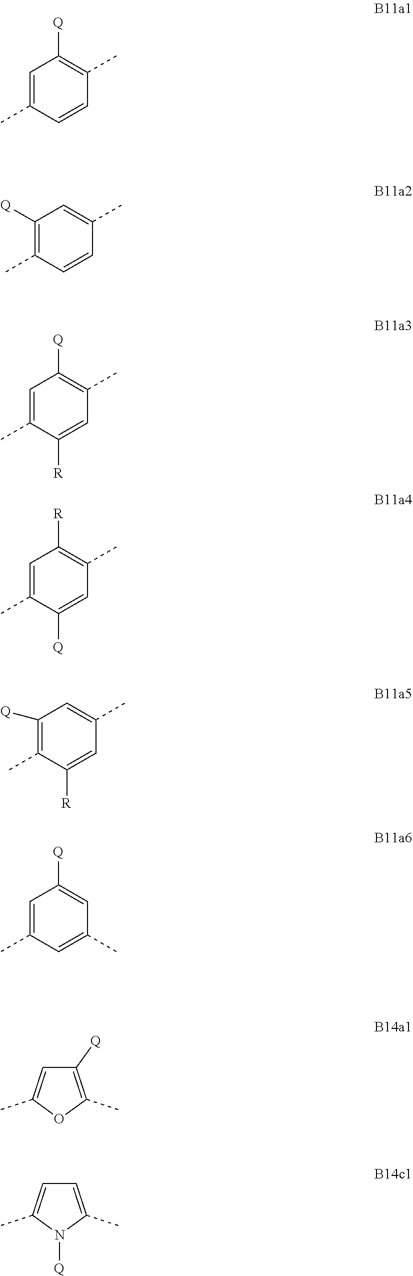

where R may assume the definitions given above and Q is a crosslinkable group.

In the structural units of the formulae (IId), (IIe), (IIf), (IIId), (IIIe) and (IIIf), in which the mono- or polycyclic, aromatic or heteroaromatic ring systems Ar² and/or Ar³ have at least one crosslinkable Q group, Ar² and Ar³ are preferably selected from the following units Ar11a to Ar20c:

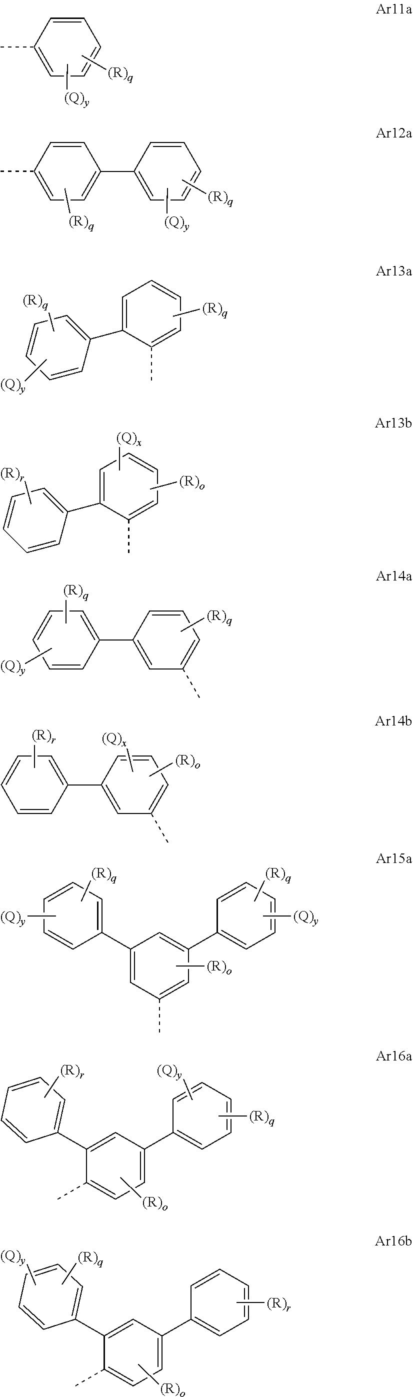

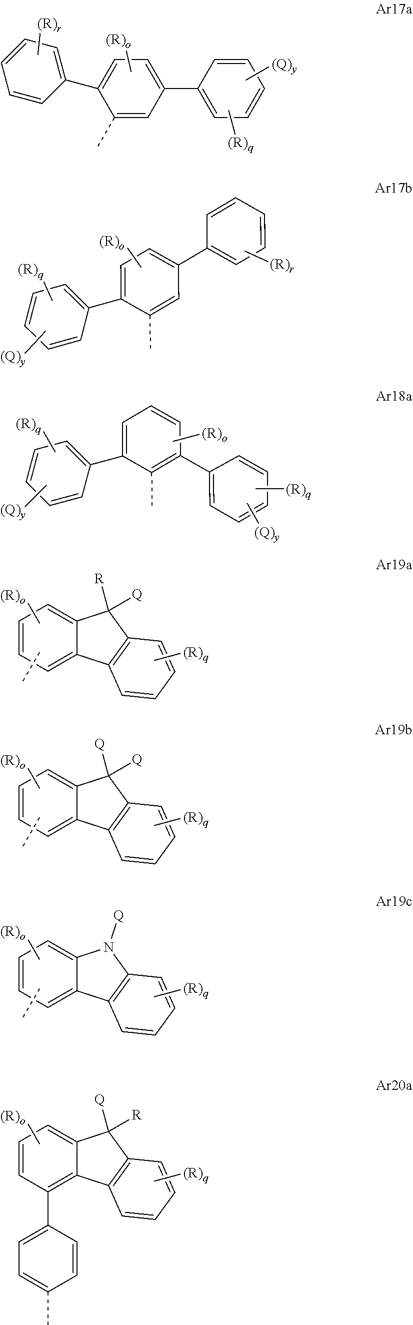

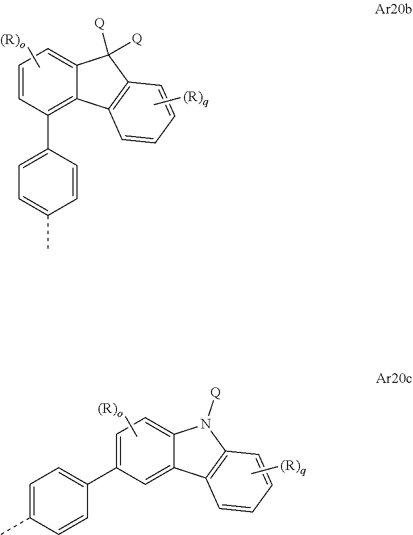

where R may assume the definitions given above, Q is a crosslinkable group,

o=0, 1, 2 or 3,

p=0, 1 or 2,

q=0, 1, 2, 3 or 4,

r=0, 1, 2, 3, 4 or 5,

x=1, 2, 3 or 4, where x+o 4 and

y=1, 2, 3, 4 or 5, where y+q 5.

In the structural units of the formulae (IId), (IIe), (IIf), (IIId), (IIIe) and (IIIf), in which the mono- or polycyclic, aromatic or heteroaromatic ring systems Ar² and/or Ar³ have at least one crosslinkable Q group, Ar² and Ar³ are more preferably selected from the following units Ar11a1 to Ar20c1:

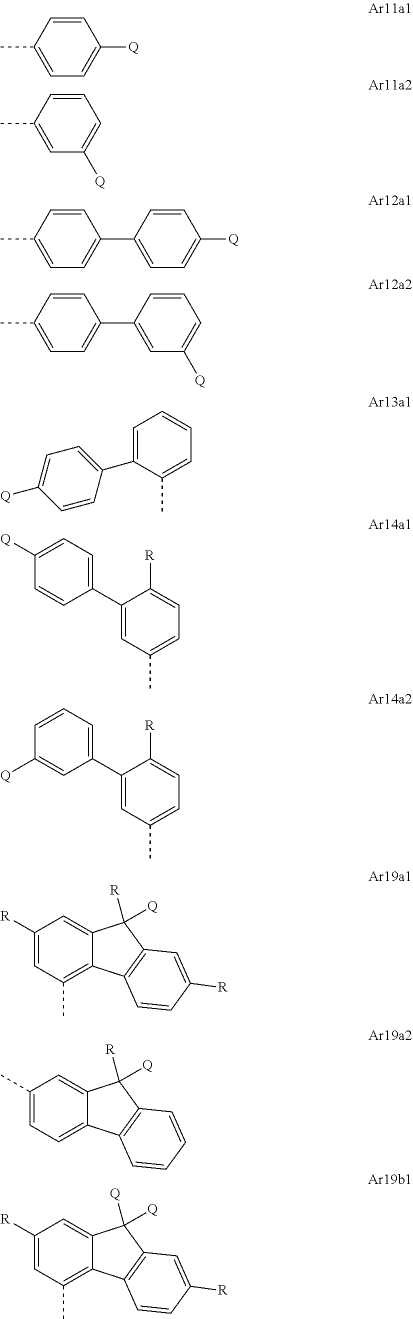

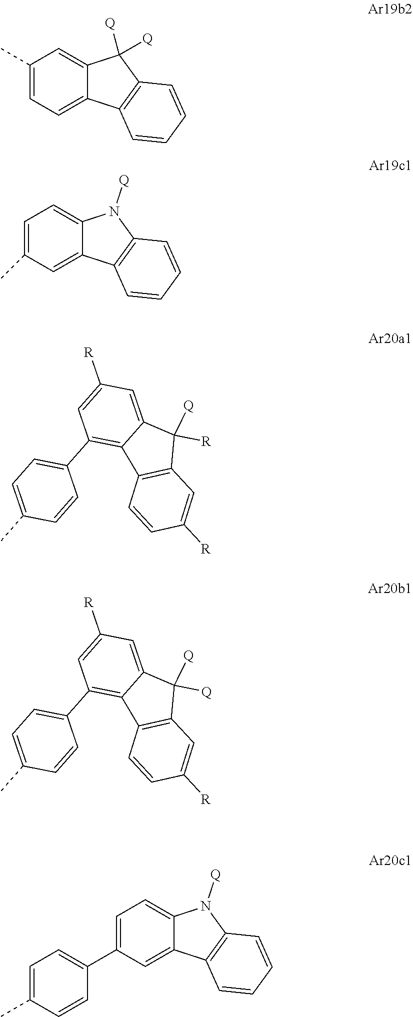

where R may assume the definitions given above and Q is a crosslinkable group.

In the structural units of the formulae (IIa) to (IIf) and (IIIa) to (IIIf), the mono- or polycyclic, aromatic or heteroaromatic ring systems Ar¹ and/or Ar⁴ are preferably selected from the units Ar11 to Ar18 and more preferably from the units Ar11a to Ar18d.

Preferred structural units of the formulae (IIa) to (IIf) or (Va) to (Vc) are the structural units shown in the table below, composed of the respective units A, B, Ar¹, Ar², Ar³ and Ar⁴.

| Monomer | A | B | Ar1 | Ar2 | Ar3 | Ar4 | Q |
|---|---|---|---|---|---|---|---|
| MX1 | A11a1 | B1aa | | | | | Q15b |
| MX2 | A11a1 | B1aa | | | | | Q15c |
| MX3 | A11a1 | B1aa | | | | | Q15f |
| MX4 | A11a1 | B1aa | | | | | Q26b |
| MX5 | A11a1 | B1aa | | | | | Q27c |
| MX6 | A11a1 | B1ab | | | | | Q2c |
| MX7 | A11a1 | B1ab | | | | | Q21c |
| MX8 | A11a1 | B1ba | | | | | Q15g |
| MX9 | A11a1 | B1ba | | | | | Q15b |
| MX10 | A11b1 | B1aa | | | | | Q15b |
| MX11 | A11b1 | B1aa | | | | | Q15c |
| MX12 | A11b1 | B1aa | | | | | Q26b |
| MX13 | A11b1 | B1aa | | | | | Q15f |
| MX14 | A11b1 | B1aa | | | | | Q7c |
| MX15 | A11b1 | B1ab | | | | | Q27c |
| MX16 | A11b1 | B1ac | | | | | Q15b |
| MX17 | A11b1 | B1ba | | | | | Q14b |
| MX18 | A11b1 | B1bb | | | | | Q2c |
| MX19 | A11c1 | B1aa | | | | | Q15d |
| MX20 | A13a1 | B1aa | | | | | Q27c |
| MX21 | A1aa | B11a1 | | | | | Q15f |
| MX22 | A1aa | B11a2 | | | | | Q27b |
| MX23 | A1ba | B11a6 | | | | | Q15b |
| MX24 | A3aa | B11a1 | | | | | Q26b |
| MX25 | A1aa | B11a1 | | | | | Q15c |
| MX26 | A1aa | B11a1 | | | | | Q16d |
| MX27 | A1aa | B11a1 | | | | | Q1b |
| MX28 | A11a1 | B11a1 | | | | | Q15b |
| MX29 | A13a1 | B11a6 | | | | | Q26b |
| MX30 | A11a1 | B1aa | Ar11aa | Ar3a | Ar3a | Ar11aa | Q15b |
| MX31 | A11a1 | B1aa | Ar11aa | Ar3b | Ar3b | Ar11aa | Q15d |
| MX32 | A11a1 | B1aa | Ar11aa | Ar3c | Ar3c | Ar11aa | Q26b |
| MX33 | A11a1 | B1aa | Ar11aa | Ar9a | Ar9a | Ar11aa | Q27c |
| MX34 | A11b1 | B1aa | Ar12d | Ar2a | Ar2a | Ar12d | Q16d |
| MX35 | A11b1 | B1aa | Ar11a | Ar3a | Ar3a | Ar11a | Q14b |
| MX36 | A1aa | B11a1 | Ar12aa | Ar9a | Ar9a | Ar12aa | Q15e |
| MX37 | A1aa | B11a1 | Ar11aa | Ar3a | Ar3a | Ar11aa | Q14b |
| MX38 | A2aa | B14a1 | Ar11aa | Ar3b | Ar3b | Ar11aa | Q1b |
| MX39 | A3aa | B11a6 | Ar11aa | Ar10b | Ar10b | Ar11aa | Q2b |
| MX40 | A11a1 | B11a1 | Ar11aa | Ar3a | Ar3a | Ar11aa | Q15b |
| MX41 | A11a1 | B11a1 | Ar11aa | Ar3b | Ar3b | Ar11aa | Q15d |
| MX42 | A11a1 | B11a1 | Ar11aa | Ar3c | Ar3c | Ar11aa | Q26b |
| MX43 | A13a1 | B11a6 | Ar12aa | Ar9a | Ar9a | Ar12aa | Q15g |
| MX44 | A1aa | B1aa | Ar11aa | Ar13a1 | Ar13a1 | Ar11aa | Q1b |
| MX45 | A1aa | B1aa | Ar11aa | Ar12a1 | Ar12a1 | Ar11aa | Q1b |
| MX46 | A1aa | B1aa | Ar11aa | Ar11a1 | Ar11a1 | Ar11aa | Q12b |
| MX47 | A1aa | B1aa | Ar11aa | Ar19a1 | Ar19a1 | Ar11aa | Q15f |
| MX48 | A1aa | B1aa | Ar11aa | Ar12a2 | Ar12a2 | Ar11aa | Q1b |
| MX49 | A1aa | B1aa | Ar12aa | Ar13a1 | Ar13a1 | Ar12aa | Q13a |
| MX50 | A1aa | B1aa | Ar12ab | Ar14a2 | Ar14a2 | Ar12ab | Q15c |
| MX51 | A1aa | B1aa | Ar12da | Ar11a1 | Ar11a1 | Ar12da | Q1b |
| MX52 | A1aa | B1aa | Ar13aa | Ar12a2 | Ar12a2 | Ar13aa | Q12b |
| MX53 | A1aa | B1ab | Ar11aa | Ar13a1 | Ar13a1 | Ar11aa | Q1c |
| MX54 | A1aa | B1ab | Ar11aa | Ar19a1 | Ar19a1 | Ar11aa | Q27c |
| MX55 | A1aa | B1ab | Ar11aa | Ar19b1 | Ar19b1 | Ar11aa | Q15g |
| MX56 | A1aa | B1ab | Ar11aa | Ar20a1 | Ar20a1 | Ar11aa | Q26b |
| MX57 | A1aa | B1ab | Ar11aa | Ar20b1 | Ar20b1 | Ar11aa | Q15b |
| MX58 | A1aa | B1ab | Ar12aa | Ar19a2 | Ar19a2 | Ar12aa | Q15e |
| MX59 | A1aa | B1ac | Ar11aa | Ar13a1 | Ar13a1 | Ar11aa | Q1b |
| MX60 | A1aa | B1ac | Ar11aa | Ar11a1 | Ar11a1 | Ar11aa | Q12b |
| MX61 | A1aa | B1ac | Ar11aa | Ar11a2 | Ar11a2 | Ar11aa | Q1b |
| MX62 | A1aa | B1ac | Ar11aa | Ar12a1 | Ar12a1 | Ar11aa | Q4b |
| MX63 | A1aa | B1ac | Ar11aa | Ar12a2 | Ar12a2 | Ar11aa | Q13a |
| MX64 | A1aa | B1ad | Ar11aa | Ar19b1 | Ar19b1 | Ar11aa | Q26b |
| MX65 | A1aa | B1ae | Ar12aa | Ar20b1 | Ar20b1 | Ar12aa | Q15b |
| MX66 | A1aa | B1ba | Ar11aa | Ar20c1 | Ar20c1 | Ar11aa | Q27c |
| MX67 | A1ba | B1bb | Ar11bb | Ar20a1 | Ar20a1 | Ar11bb | Q15g |
| MX68 | A2aa | B4aa | Ar17aa | Ar11a1 | Ar11a1 | A17aa | Q1b |
| MX69 | A3aa | B1aa | A11aa | Ar12a1 | Ar12a1 | A11aa | Q12b |
| MX70 | A3aa | B1b | A12aa | Ar19a1 | Ar19a1 | A12aa | Q27c |
| MX71 | A5aa | B4ca | A13ba | Ar12a2 | Ar12a2 | A13ba | Q4b |
| MX72 | A1aa | B1aa | Ar11aa | Ar3a | Ar13a1 | Ar11aa | Q1b |
| MX73 | A1aa | B1aa | Ar11aa | Ar2a | Ar12a1 | Ar11aa | Q1b |
| MX74 | A1aa | B1aa | Ar11aa | Ar1a | Ar11a1 | Ar11aa | Q12b |
| MX75 | A1aa | B1aa | Ar11aa | Ar9a | Ar19a1 | Ar11aa | Q15f |
| MX76 | A1aa | B1aa | Ar11aa | Ar2a | Ar12a2 | Ar11aa | Q1b |
| MX77 | A1aa | B1aa | Ar12aa | Ar3a | Ar13a1 | Ar12aa | Q13a |
| MX78 | A1aa | B1aa | Ar12ab | Ar4a | Ar14a2 | Ar12ab | Q15c |
| MX79 | A2aa | B4aa | Ar17aa | Ar1a | Ar11a1 | A17aa | Q1b |
| MX80 | A3aa | B1aa | A11aa | Ar2a | Ar12a1 | A11aa | Q12b |
| MX81 | A3aa | B1ab | A12aa | Ar9a | Ar19a1 | A12aa | Q27c |
| MX82 | A5aa | B4ca | A13ba | Ar2a | Ar12a2 | A13ba | Q4b |
| MX83 | A1aa | B1aa | Ar11aa | Ar13a1 | Ar3a | Ar11aa | Q1b |
| MX84 | A1aa | B1aa | Ar11aa | Ar12a1 | Ar2a | Ar11aa | Q1b |
| MX85 | A1aa | B1aa | Ar11aa | Ar11a1 | Ar1a | Ar11aa | Q12b |
| MX86 | A1aa | B1aa | Ar11aa | Ar19a1 | Ar9a | Ar11aa | Q15f |
| MX87 | A1aa | B1aa | Ar11aa | Ar12a2 | Ar2a | Ar11aa | Q1b |
| MX88 | A1aa | B1aa | Ar12aa | Ar13a1 | Ar3a | Ar12aa | Q13a |
| MX89 | A1aa | B1ac | Ar11aa | Ar11a2 | Ar1a | Ar11aa | Q1b |
| MX90 | A2aa | B4aa | Ar17aa | Ar11a1 | Ar11 | A17aa | Q1b |
| MX91 | A3aa | B1aa | A11aa | Ar12a1 | Ar2a | A11aa | Q12b |
| MX92 | A3aa | B1ab | A12aa | Ar19a1 | Ar9a | A12aa | Q27c |
| MX93 | A5aa | B4ca | A13ba | Ar12a2 | Ar2a | A13ba | Q4b |

The polymers of the invention containing structural units of the formula (I), (Ia), (Ia1), (Ia2), (Ib), (Ic) and/or (Id) are generally prepared by polymerization of one or more monomer types, of which at least one monomer leads to structural units of the formula (I), (Ia), (Ia1), (Ia2), (Ib), (Ic) and/or (Id) in the polymer. Suitable polymerization reactions are known to those skilled in the art and are described in the literature. Particularly suitable and preferred polymerization reactions which lead to C—C and C—N couplings are as follows:

(A) SUZUKI polymerization;

(B) YAMAMOTO polymerization;

(C) STILLE polymerization;

(D) HECK polymerization;

(E) NEGISHI polymerization;

(F) SONOGASHIRA polymerization;

(G) HIYAMA polymerization; and

(H) HARTWIG-BUCHWALD polymerization.

How the polymerization can be conducted by these methods and how the polymers can then be separated from the reaction medium and purified is known to those skilled in the art and is described in detail in the literature, for example in WO 03/048225 A2, WO 2004/037887 A2 and WO 2004/037887 A2.

The C—C couplings are preferably selected from the groups of SUZUKI coupling, YAMAMOTO coupling and STILLE coupling; the C—N coupling is preferably a coupling according to HARTWIG-BUCHWALD.

The present invention thus also provides a process for preparing the polymers of the invention, which is characterized in that they are prepared by SUZUKI polymerization, YAMAMOTO polymerization, STILLE polymerization or HARTWIG-BUCHWALD polymerization.

The synthesis of the polymers of the invention requires the corresponding monomers of the formula (MI)

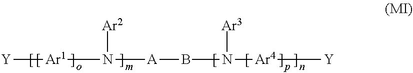

where A, B, Ar¹, Ar², Ar³ and Ar⁴ and also m, n, o and p may assume the definitions given in relation to the structural unit of the formula (I).

The monomers of the formula (MI) which lead to structural units of the formula (I) in the inventive polymers are compounds which have corresponding substitution and have suitable functionalities at two positions that allow incorporation of this monomer unit into the polymer. These monomers of the formula (MI) thus likewise form part of the subject-matter of the present invention. The Y group is the same or different and is a leaving group suitable for a polymerization reaction, such that the incorporation of the monomer units into polymeric compounds is enabled.

Preferably, Y is a chemical functionality which is the same or different and is selected from the class of the halogens, O-tosylates, O-triflates, O-sulfonates, boric esters, partly fluorinated silyl groups, diazonium groups and organotin compounds.

The basic structure of the monomer compounds can be functionalized by standard methods, for example by Friedel-Crafts alkylation or acylation. In addition, the basic structure can be halogenated by standard organic chemistry methods. The halogenated compounds can optionally be converted further in additional functionalization steps. For example, the halogenated compounds can be used either directly or after conversion to a boronic acid derivative or an organotin derivative as starting materials for the conversion to polymers, oligomers or dendrimers.

Said methods are merely a selection from the reactions known to those skilled in the art, who are able to use these, without exercising inventive skill, to synthesize the inventive compounds.

The polymers of the invention can be used as a neat substance, or else as a mixture together with any further polymeric, oligomeric, dendritic or low molecular weight substances. A low molecular weight substance is understood in the present invention to mean compounds having a molecular weight in the range from 100 to 3000 g/mol, preferably 200 to 2000 g/mol. These further substances can, for example, improve the electronic properties or emit themselves. A mixture refers above and below to a mixture comprising at least one polymeric component. In this way, it is possible to produce one or more polymer layers consisting of a mixture (blend) of one or more polymers of the invention having a structural unit of the formula (I), (Ia), (Ia1), (Ia2), (Ib), (Ic) and/or (Id) and optionally one or more further polymers with one or more low molecular weight substances.

The present invention thus further provides a polymer blend comprising one or more polymers of the invention, and one or more further polymeric, oligomeric, dendritic and/or low molecular weight substances.

The invention further provides solutions and formulations composed of one or more polymers of the invention or a polymer blend in one or more solvents. The way in which such solutions can be prepared is known to those skilled in the art and is described, for example, in WO 02/072714 A1, WO 03/019694 A2 and the literature cited therein.

These solutions can be used in order to produce thin polymer layers, for example by surface coating methods (e.g. spin-coating) or by printing methods (e.g. inkjet printing).

Polymers containing structural units having a crosslinkable Q group are particularly suitable for producing films or coatings, especially for producing structured coatings, for example by thermal or light-induced in situ polymerization and in situ crosslinking, for example in situ UV photopolymerization or photopatterning. It is possible here to use either corresponding polymers in pure form or else formulations or mixtures of these polymers as described above. These can be used with or without addition of solvents and/or binders. Suitable materials, processes and apparatuses for the above-described methods are described, for example, in WO 2005/083812 A2. Possible binders are, for example, polystyrene, polycarbonate, poly(meth)acrylates, polyacrylates, polyvinyl butyral and similar optoelectronically neutral polymers.

Suitable and preferred solvents are, for example, toluene, anisole, o-, m- or p-xylene, methyl benzoate, mesitylene, tetralin, veratrole, THF, methyl-THF, THP, chlorobenzene, dioxane, phenoxytoluene, especially 3-phenoxytoluene, (−)-fenchone, 1,2,3,5-tetramethylbenzene, 1,2,4,5-tetramethylbenzene, 1-methylnaphthalene, 2-methylbenzothiazole, 2-phenoxyethanol, 2-pyrrolidinone, 3-methylanisole, 4-methylanisole, 3,4-dimethylanisole, 3,5-dimethylanisole, acetophenone, α-terpineol, benzothiazole, butyl benzoate, cumene, cyclohexanol, cyclohexanone, cyclohexylbenzene, decalin, dodecylbenzene, ethyl benzoate, indane, methyl benzoate, NMP, p-cymene, phenetole, 1,4-diisopropylbenzene, dibenzyl ether, diethylene glycol butyl methyl ether, triethylene glycol butyl methyl ether, diethylene glycol dibutyl ether, triethylene glycol dimethyl ether, diethylene glycol monobutyl ether, tripropylene glycol dimethyl ether, tetraethylene glycol dimethyl ether, 2-isopropylnaphthalene, pentylbenzene, hexylbenzene, heptylbenzene, octylbenzene, 1,1-bis(3,4-dimethylphenyl)ethane or mixtures of these solvents.

The present invention thus further provides for the use of a polymer containing structural units having a crosslinkable Q group for preparation of a crosslinked polymer. The crosslinkable group, which is more preferably a vinyl group or alkenyl group, is preferably incorporated into the polymer by the WITTIG reaction or a WITTIG-like reaction. If the crosslinkable group is a vinyl group or alkenyl group, the crosslinking can take place via free-radical or ionic polymerization, which can be induced thermally or by radiation. Preference is given to free-radical polymerization which is induced thermally, preferably at temperatures of less than 250° C., more preferably at temperatures of less than 230° C.

Optionally, during the crosslinking process, an additional styrene monomer is added in order to achieve a higher degree of crosslinking. Preferably, the proportion of the added styrene monomer is in the range from 0.01 to 50 mol %, more preferably 0.1 to 30 mol %, based on 100 mol % of all the copolymerized monomers present as structural units in the polymer.

The present invention thus also provides a process for preparing a crosslinked polymer, comprising the following steps:

(a) providing polymers containing structural units having one or more crosslinkable Q groups; and

(b) free-radical or ionic crosslinking, preferably free-radical crosslinking, which can be induced either thermally or by radiation, preferably thermally.

The crosslinked polymers prepared by the process of the invention are insoluble in all standard solvents. In this way, it is possible to produce defined layer thicknesses which are not dissolved or partly dissolved again even by the application of subsequent layers.

The present invention thus also relates to a crosslinked polymer obtainable by the aforementioned process. The crosslinked polymer is—as described above—preferably produced in the form of a crosslinked polymer layer. Because of the insolubility of the crosslinked polymer in all solvents, a further layer can be applied from a solvent to the surface of such a crosslinked polymer layer by the above-described techniques.

The present invention also encompasses what are called hybrid devices in which one or more layers which are processed from solution and layers which are produced by vapor deposition of low molecular weight substances may occur.

The polymers of the invention can be used in electronic or optoelectronic devices or for production thereof.

The present invention thus further provides for the use of the polymers of the invention in electronic or optoelectronic devices, preferably in organic electroluminescent devices (OLEDs), organic field-effect transistors (OFETs), organic integrated circuits (O-ICs), organic thin-film transistors (TFTs), organic solar cells (O-SCs), organic laser diodes (O-laser), organic photovoltaic (OPV) elements or devices or organic photoreceptors (OPCs), more preferably in organic electroluminescent devices (OLEDs).

In the case of the aforementioned hybrid device, in conjunction with organic electroluminescent devices, reference is made to combined PLED/SMOLED (polymeric light-emitting diode/small molecule organic light-emitting diode) systems.

The way in which OLEDs can be produced is known to those skilled in the art and is described in detail, for example, as a general process in WO 2004/070772 A2, which has to be adapted appropriately to the individual case.

As described above, the polymers of the invention are very particularly suitable as electroluminescent materials in OLEDs or displays produced in this way.

Electroluminescent materials in the context of the present invention are considered to mean materials which can find use as the active layer. “Active layer” means that the layer is capable of emitting light on application of an electrical field (light-emitting layer) and/or that it improves the injection and/or transport of the positive and/or negative charges (charge injection or charge transport layer).

The present invention therefore preferably also provides for the use of the polymers of the invention in OLEDs, especially as electroluminescent material.

The present invention further provides electronic or optoelectronic components, preferably organic electroluminescent devices (OLEDs), organic field-effect transistors (OFETs), organic integrated circuits (O-ICs), organic thin-film transistors (TFTs), organic solar cells (O-SCs), organic laser diodes (O-laser), organic photovoltaic (OPV) elements or devices and organic photoreceptors (OPCs), more preferably organic electroluminescent devices, having one or more active layers, wherein at least one of these active layers comprises one or more polymers of the invention. The active layer may, for example, be a light-emitting layer, a charge transport layer and/or a charge injection layer.

In the present application text and also in the examples that follow hereinafter, the main aim is the use of the polymers of the invention in relation to OLEDs and corresponding displays. In spite of this restriction of the description, it is possible for the person skilled in the art, without exercising further inventive skill, to utilize the polymers of the invention as semiconductors for the further above-described uses in other electronic devices as well.

The examples which follow are intended to illustrate the invention without restricting it. More particularly, the features, properties and advantages that are described therein for the defined compounds that form the basis of the example in question are also applicable to other compounds that are not referred to in detail but are covered by the scope of protection of the claims, unless the opposite is stated elsewhere.

### WORKING EXAMPLES

### Part A: Synthesis of the Monomers

All syntheses are conducted in an argon atmosphere and in dry solvents, unless stated otherwise.

### Example 1

Synthesis of Monomer Mon-1

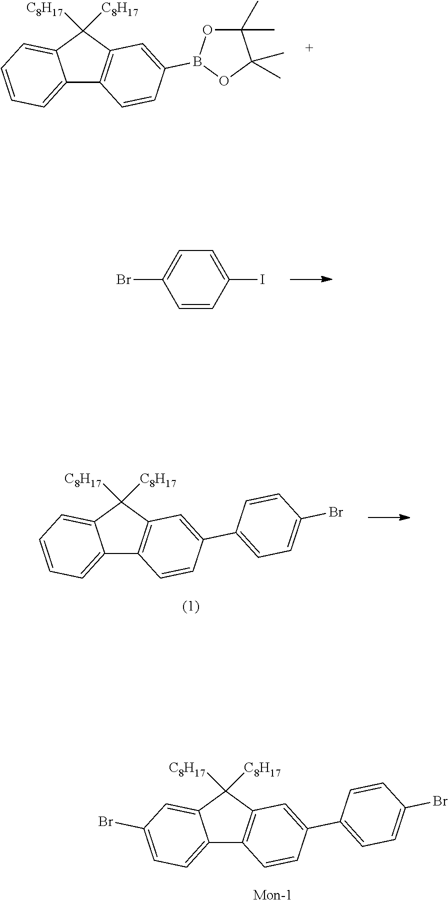

To an initial charge of 135 g (293 mmol) of 2-(9,9-dioctyl-9H-fluoren-2-yl)-[1,3,2]dioxaborolane and 87 g (299 mmol, 1.02 eq) of 1-bromo-4-iodobenzene in 2200 ml of ethylene glycol dimethyl ether are added 68 g (655 mmol) of Na₂CO₃ dissolved in 250 ml of H₂O. The mixture is saturated with argon, 10.2 g (8.8 mmol) of tetrakis(triphenylphosphine)palladium(0) are added and the mixture is stirred under reflux for 48 hours. After cooling to room temperature, water and toluene are added to the mixture, and the organic phase is removed. The organic phase is washed three times with 500 ml each time of water, dried over sodium sulfate and freed of the solvent on a rotary evaporator. The crude product is then taken up in heptane and filtered through silica gel. Removing the solvent leaves 130 g (240 mmol, 82% of theory) of a beige solid (1).

130 g (240 mmol) of the solid (1) and 42.6 g (240 mmol) of N-bromosuccinimide are dissolved in 3300 ml of DCM, and the mixture is heated to 40° C. Subsequently, 1 ml of 33% HBr solution in acetic acid is added and the mixture is stirred at 40° C. for 12 hours. After cooling to room temperature, the mixture is freed of the solvent on a rotary evaporator, dissolved in hot toluene and filtered. The orange solution is concentrated again on a rotary evaporator and the remaining solids are repeatedly dissolved in hot heptane and precipitated with ethanol. 82 g (130 mmol, 55% of theory) of Mon-1 were obtained.

### Examples 2 to 6

Synthesis of Monomers Mon-2 to Mon-5 and Mon-16

Analogously to example 1, the reactants shown in table 1 below are used to obtain the monomers Mon-2 to Mon-5 and Mon-16 in the corresponding yields.

TABLE 1

| | Product | | | Yield |
|---|---|---|---|---|
| Example | name | Reactant | Product | [%] |
| 1 | Mon-1 | 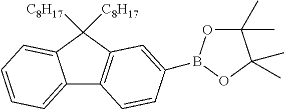 | 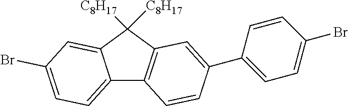 | 55 |
| 2 | Mon-2 | 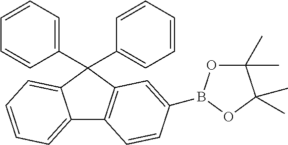 [SMILES: CC1(C)OB(c2ccc3c(c2)C(c2ccccc2)(c2ccccc2)c2ccccc2-3)OC1(C)C] | 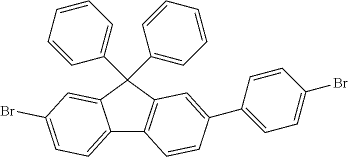 [SMILES: Brc1ccc(-c2ccc3c(c2)C(c2ccccc2)(c2ccccc2)c2cc(Br)ccc2-3)cc1] | 73 |
| 3 | Mon-3 | 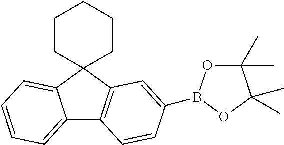 [SMILES: CC1(C)OB(c2ccc3c(c2)C2(CCCCC2)c2ccccc2-3)OC1(C)C] | 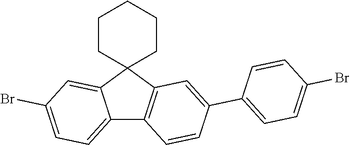 [SMILES: Brc1ccc(-c2ccc3c(c2)C2(CCCCC2)c2cc(Br)ccc2-3)cc1] | 48 |
| 4 | Mon-4 | 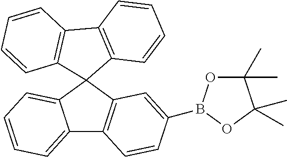 [SMILES: CC1(C)OB(c2ccc3c(c2)C2(c4ccccc4-c4ccccc42)c2ccccc2-3)OC1(C)C] | 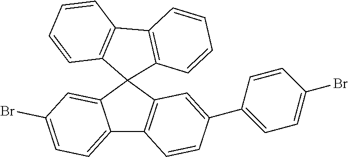 [SMILES: Brc1ccc(-c2ccc3c(c2)C2(c4ccccc4-c4ccccc42)c2cc(Br)ccc2-3)cc1] | 62 |
| 5 | Mon-5 | 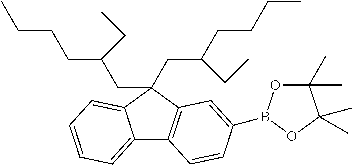 [SMILES: CCCCC(CC)CC1(CC(CC)CCCC)c2ccccc2-c2ccc(B3OC(C)(C)C(C)(C)O3)cc21] | 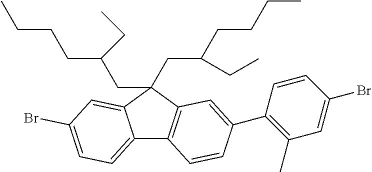 [SMILES: CCCCC(CC)CC1(CC(CC)CCCC)c2cc(Br)ccc2-c2ccc(-c3ccc(Br)cc3C)cc21] | 34 |
| 6 | Mon-16 | 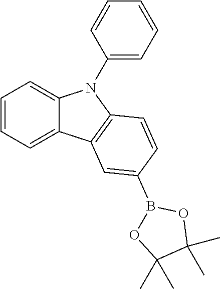 [SMILES: CC1(C)OB(c2ccc3c(c2)c2ccccc2n3-c2ccccc2)OC1(C)C] | 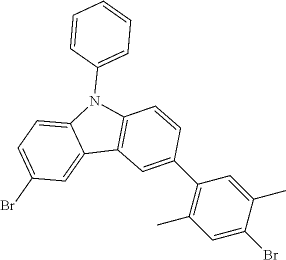 [SMILES: Cc1cc(-c2ccc3c(c2)c2cc(Br)ccc2n3-c2ccccc2)c(C)cc1Br] | 52 |

### Example 7

Synthesis of Monomer Mon-6

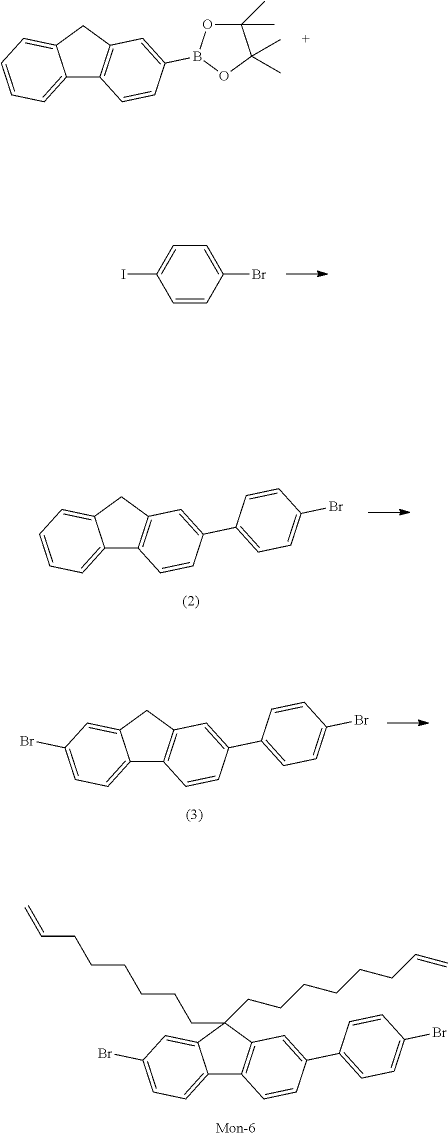

To an initial charge of 82.4 g (280 mmol) of 2-(9H-fluoren-2-yl)-4,4,5,5-tetramethyl[1,3,2]dioxaborolane and 90.5 g (310 mmol) of 1-bromo-4-iodobenzene in 600 ml of ethylene glycol dimethyl ether are then added 65.7 g (620 mmol) of Na₂CO₃ dissolved in 160 ml of H₂O. The mixture is saturated with argon, 10.2 g (8.8 mmol) of tetrakis(triphenylphosphine)palladium(0) are added and the mixture is stirred under reflux for 48 hours. Subsequently, the mixture is cooled down to room temperature and 500 ml of water and 600 ml of toluene are added. After phase separation, the organic phase is washed three times with 500 ml each time of water, dried over sodium sulfate and freed of the solvent on a rotary evaporator.

The remaining solids are subjected to extractive stirring in hot heptane and the suspension is filtered with suction. 50.3 g (157 mmol, 56% of theory) of a white solid (2) were obtained.

50.3 g (157 mmol) of solid (2) are dissolved together with 28.1 g (158 mmol) of N-bromosuccinimide in 1300 ml of DCM and heated to 40° C. Subsequently, one drop of 33% HBr solution in acetic acid is added and the mixture is stirred at 40° C. for 12 hours. After cooling to room temperature, the mixture is freed of the solvent on a rotary evaporator, subjected to extractive stirring in hot ethanol and filtered. Filtration through silica gel (solvent: toluene) is followed by concentration of the solution again. The solids are taken up again in hot toluene, precipitated with ethanol, subjected to extractive stirring overnight, filtered off with suction and washed with methanol. 53.3 g (133 mmol, 85% of theory) of a solid (3) were obtained.

9.5 g (23.5 mmol) of solid (3) are dissolved in 190 ml of dry DMSO. 13.8 g (144 mmol) of sodium t-butoxide are added to this solution at room temperature. The suspension is heated to 80° C., and 18.4 g (94 mmol) of 1-bromooct-8-ene are slowly added dropwise at this temperature. The mixture is stirred at 80° C. overnight. Subsequently, the mixture is cooled down to room temperature and quenched with 20 ml of toluene and 25 ml of water. After phase separation, the organic phase is washed three times with 500 ml each time of water, dried over sodium sulfate and freed of the solvent on a rotary evaporator. The solids are then eluted through a silica gel frit with heptane and the colorless eluate is concentrated on a rotary evaporator. Recrystallization from ethanol gave 6.5 g (10.4 mmol, 45% of theory) of Mon-6.

### Examples 8 and 9

Synthesis of Monomers Mon-7 and Mon-8

Analogously to example 7, the reactants shown in table 2 below are used to obtain the monomers Mon-7 and Mon-8 in the corresponding yields.

TABLE 2

| | Product | | | Yield |
|---|---|---|---|---|
| Example | name | Reactant | Product | (%) |
| 7 | Mon-6 | 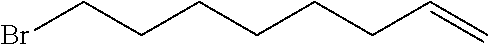 | 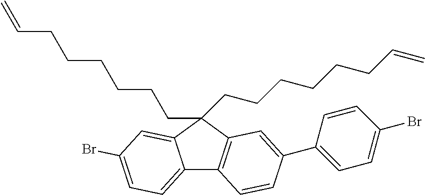 [SMILES: C=CCCCCCCC1(CCCCCCC=C)c2cc(Br)ccc2-c2ccc(-c3ccc(Br)cc3)cc21] | 45 |
| 8 | Mon-7 | 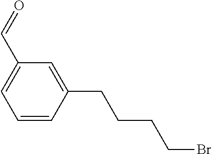 [SMILES: O=Cc1cccc(CCCCBr)c1] | 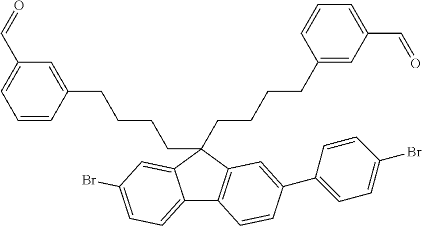 [SMILES: O=Cc1cccc(CCCCC2(CCCCc3cccc(C=O)c3)c3cc(Br)ccc3-c3ccc(-c4ccc(Br)cc4)cc32)c1] | 38 |
| 9 | Mon-8 | 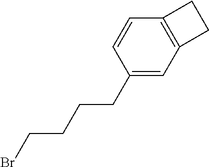 [SMILES: BrCCCCc1ccc2c(c1)CC2] | 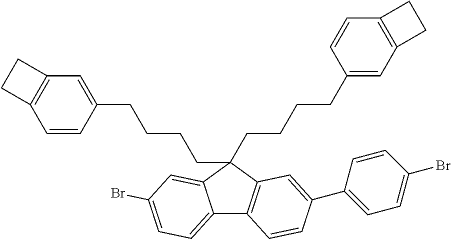 [SMILES: Brc1ccc(-c2ccc3c(c2)C(CCCCc2ccc4c(c2)CC4)(CCCCc2ccc4c(c2)CC4)c2cc(Br)ccc2-3)cc1] | 63 |

### Example 10

Synthesis of Monomer Mon-9

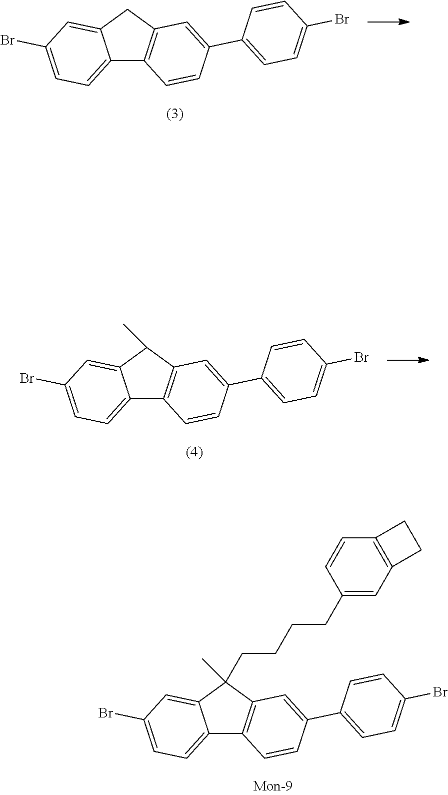 [SMILES: Brc1ccc(-c2ccc3c(c2)Cc2cc(Br)ccc2-3)cc1 ; CC1c2cc(Br)ccc2-c2ccc(-c3ccc(Br)cc3)cc21 ; CC1(CCCCc2ccc3c(c2)CC3)c2cc(Br)ccc2-c2ccc(-c3ccc(Br)cc3)cc21]

An initial charge of 20 g (50 mmol) of solid (3) in 250 ml of THF is cooled down to −78° C. 28.7 ml (57.5 mmol) of lithium diisopropylamide (2 M in THF) are slowly added dropwise, and the mixture is warmed to room temperature and stirred for a further 15 minutes. Subsequently, the mixture is cooled back down to −78° C. and 14.2 g (100 mmol) of methyl iodide are added dropwise; the reaction comes to room temperature overnight. The reaction is quenched cautiously with a small amount of acetic acid and then water and toluene are added. After phase separation, the organic phase is washed three times with 500 ml each time of water, dried over sodium sulfate and freed of the solvent on a rotary evaporator. The remaining solids are subjected to extractive stirring in hot heptane and the suspension is filtered with suction. 18.3 g (44 mmol, 88% of theory) of a solid (4) were obtained.

An initial charge of 18.3 g (44 mmol) of solid (4) in 200 ml of THF is cooled down to −78° C. 66 ml (132 mmol) of lithium diisopropylamide (2 M in THF) are slowly added dropwise, and the mixture is warmed to room temperature and stirred for a further 15 minutes. Subsequently, the mixture is cooled back down to −78° C. and 15.8 g (66 mmol) of 3-(4-bromobutyl)bicyclo[4.2.0]octa-1(6),2,4-triene are added dropwise. The reaction comes to room temperature overnight and is then quenched cautiously with a small amount of water and acetic acid, then toluene is added. After phase separation, the organic phase is washed three times with 500 ml each time of water, dried over sodium sulfate and freed of the solvent on a rotary evaporator. The solids are then eluted through a silica gel frit with heptane and the colorless eluate is concentrated on a rotary evaporator. Recrystallization from ethanol gave 13.3 g (23.3 mmol, 53% of theory) of Mon-9.

### Examples 11 to 13

Synthesis of Monomers Mon-10 to Mon-12

Analogously to example 10, the reactants shown in table 3 below are used to obtain the monomers Mon-10 to Mon-12 in the corresponding yields.

TABLE 3

| | Product | | | Yield |
|---|---|---|---|---|
| Example | name | Reactant | Product | (%) |
| 10 | Mon-9 | 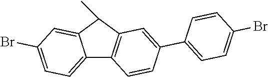 [SMILES: CC1c2cc(Br)ccc2-c2ccc(-c3ccc(Br)cc3)cc21] | 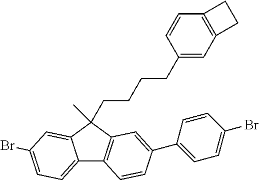 [SMILES: CC1(CCCCc2ccc3c(c2)CC3)c2cc(Br)ccc2-c2ccc(-c3ccc(Br)cc3)cc21] | 53 |
| 11 | Mon-10 | 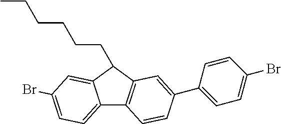 [SMILES: CCCCCCC1c2cc(Br)ccc2-c2ccc(-c3ccc(Br)cc3)cc21] | 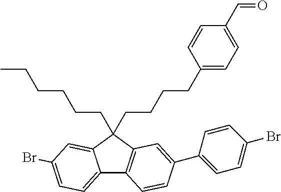 [SMILES: CCCCCCC1(CCCCc2ccc(C=O)cc2)c2cc(Br)ccc2-c2ccc(-c3ccc(Br)cc3)cc21] | 48 |
| 12 | Mon-11 | 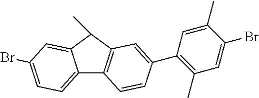 [SMILES: Cc1cc(-c2ccc3c(c2)C(C)c2cc(Br)ccc2-3)c(C)cc1Br] | 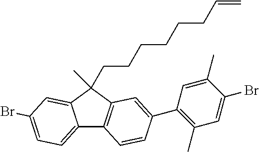 [SMILES: C=CCCCCCCC1(C)c2cc(Br)ccc2-c2ccc(-c3cc(C)c(Br)cc3C)cc21] | 65 |
| 13 | Mon-12 | 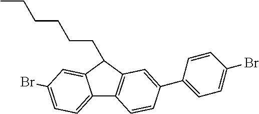 [SMILES: CCCCCCC1c2cc(Br)ccc2-c2ccc(-c3ccc(Br)cc3)cc21] | 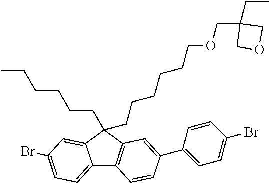 [SMILES: CCCCCCC1(CCCCCCOCC2(CC)COC2)c2cc(Br)ccc2-c2ccc(-c3ccc(Br)cc3)cc21] | 28 |

### Example 14

Synthesis of Monomer Mon-13

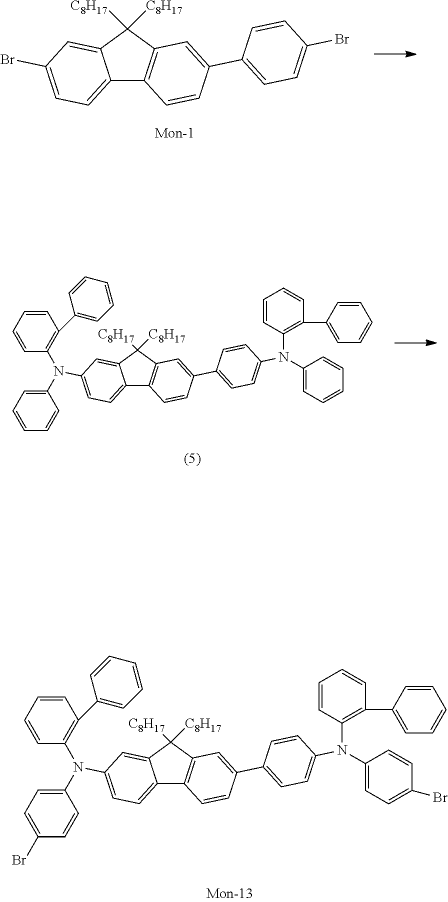

20 g (32 mmol) of monomer Mon-1, 23.6 g (96 mmol) of biphenyl-2-yl(phenyl)amine, 15.4 g (160 mmol) of sodium t-butoxide and 216 mg (0.96 mmol) of palladium acetate are dissolved in 400 ml of toluene. The mixture is saturated with argon at 45° C., then 1.92 ml (19.2 mmol) of tri-t-butylphosphine are added and the mixture is stirred under reflux for 12 hours. Subsequently, the reaction is cooled down to room temperature, water is added, and the organic phase is removed, washed three times with water, dried over sodium sulfate and freed of the solvent on a rotary evaporator. The remaining raw material is recrystallized repeatedly from a butanol/ethanol mixture. 19 g (19.8 mmol, 62% of theory) of solid (5) were obtained.

19 g (19.8 mmol) of solid (5) are initially charged in 1000 ml of THF. The solution is cooled down to −10° C. with an ice/salt bath. Subsequently, 6.9 g (38.6 mmol) of N-bromosuccinimide are added. The mixture is stirred at −10° C. for 1.5 hours, then the mixture comes to room temperature overnight. The mixture is then freed of the solvent on a rotary evaporator, subjected to extractive stirring in hot ethanol and filtered. The remaining solids are recrystallized repeatedly in i-propanol. 17 g (15 mmol, 76% of theory) of Mon-13 were obtained.

### Examples 15 and 16

Synthesis of Monomers Mon-14 and Mon-15

Analogously to example 14, the reactants shown in table 4 below are used to obtain the monomers Mon-14 and Mon-15 in the corresponding yields.

TABLE 4

| | Pro- | | | |
|---|---|---|---|---|
| Ex- | duct | | | Yield |
| ample | name | Reactant | Product | (%) |
| 14 | Mon- 13 | 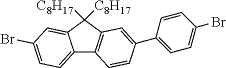 | 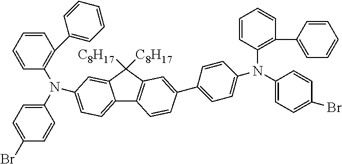 | 76 |
| 15 | Mon- 14 | 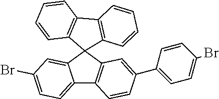 [SMILES: Brc1ccc(-c2ccc3c(c2)C2(c4ccccc4-c4ccccc42)c2cc(Br)ccc2-3)cc1] | 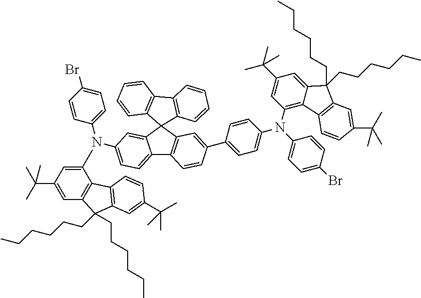 [SMILES: CCCCCCC1(CCCCCC)c2cc(C(C)(C)C)ccc2-c2c(N(c3ccc(Br)cc3)c3ccc(-c4ccc5c(c4)C4(c6ccccc6-c6ccccc64)c4cc(N(c6ccc(Br)cc6)c6cc(C(C)(C)C)cc7c6-c6ccc(C(C)(C)C)cc6C7(CCCCCC)CCCCCC)ccc4-5)cc3)cc(C(C)(C)C)cc21] | 58 |
| 16 | Mon- 15 | 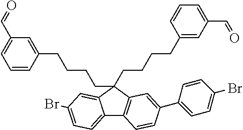 [SMILES: O=Cc1cccc(CCCCC2(CCCCc3cccc(C=O)c3)c3cc(Br)ccc3-c3ccc(-c4ccc(Br)cc4)cc32)c1] | 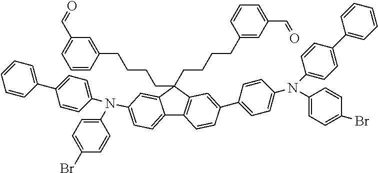 [SMILES: O=Cc1cccc(CCCCC2(CCCCc3cccc(C=O)c3)c3cc(-c4ccc(N(c5ccc(Br)cc5)c5ccc(-c6ccccc6)cc5)cc4)ccc3-c3ccc(N(c4ccc(Br)cc4)c4ccc(-c5ccccc5)cc4)cc32)c1] | 44 |

### Example 17

Synthesis of Monomer Mon-1-BE

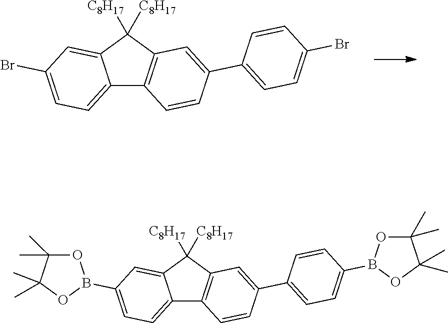

10 g (16 mmol) of monomer Mon-1 are initially charged together with 10.2 g (40 mmol) of bis(pinacolato)diboron, 5.2 g (53 mmol) of potassium acetate, 0.35 g (0.48 mmol) of Pd(dppf)Cl₂*CH₂Cl₂ in 200 ml of DMSO. The mixture is heated to 40° C. and saturated with argon for 20 minutes. Subsequently, the reaction is stirred at 80° C. overnight and cooled down to room temperature. After addition of 150 ml of water and 150 ml of ethyl acetate, the organic phase is removed, washed 3 times with water, dried over sodium sulfate and finally concentrated on a rotary evaporator. The remaining solids are repeatedly dissolved in hot heptane and precipitated again with ethanol. 8.3 g (11.5 mmol, 72% of theory) of monomer Mon-1-BE were obtained.

### Examples 18 to 20

Synthesis of Monomers Mon-6-BE, Mon-9-BE and Mon-13-BE

Analogously to example 17, the reactants shown in table 5 below are used to obtain the monomers Mon-6-BE, Mon-9-BE and Mon-13-BE in the corresponding yields.

TABLE 5

| Ex- | Product | | | Yield |
|---|---|---|---|---|
| ample | name | Reactant | Product | (%) |
| 17 | Mon-1- BE | 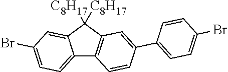 | 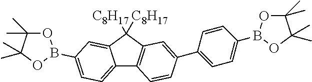 | 72 |
| 18 | Mon-6- BE | 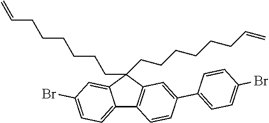 [SMILES: C=CCCCCCCC1(CCCCCCC=C)c2cc(Br)ccc2-c2ccc(-c3ccc(Br)cc3)cc21] | 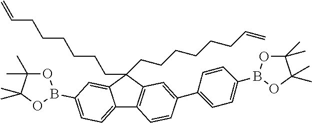 | 83 |
| 19 | Mon-9- BE | 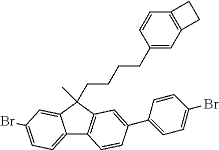 [SMILES: CC1(CCCCc2ccc3c(c2)CC3)c2cc(Br)ccc2-c2ccc(-c3ccc(Br)cc3)cc21] | 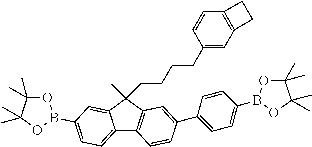 | 67 |
| 20 | Mon-13- BE | 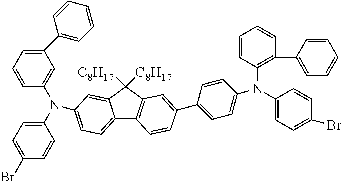 | 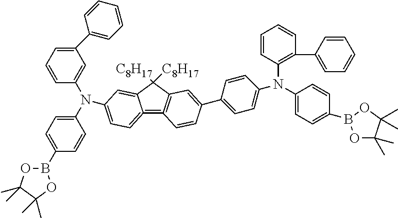 | 55 |

Further Monomers:

Further monomers for production of the polymers of the invention are already described in the prior art, are commercially available or are prepared according to a literature method, and are summarized in table 6 below:

TABLE 6

| | | Synthesis |
|---|---|---|
| Monomer | Structure | according to |
| Mon-101-BE | 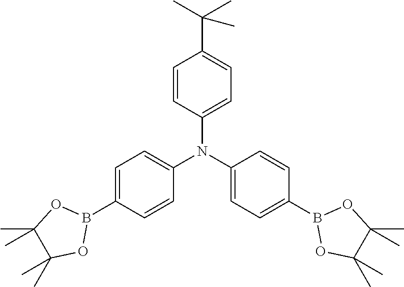 | WO 99/048160 A1 |
| Mon-102-BE | 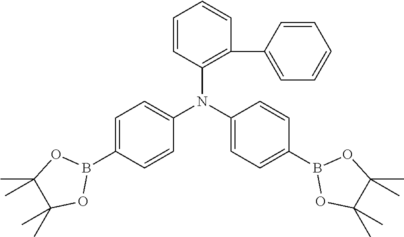 | WO 2013/156130 |
| Mon-102 | 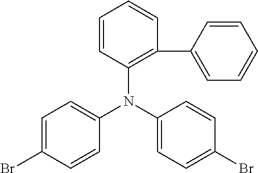 [SMILES: Brc1ccc(N(c2ccc(Br)cc2)c2ccccc2-c2ccccc2)cc1] | WO 2013/156130 |
| Mon-103 | 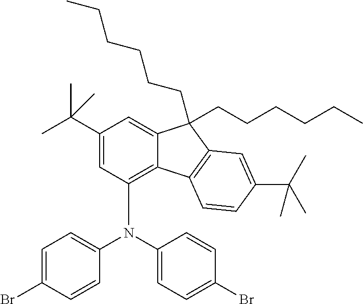 [SMILES: CCCCCCC1(CCCCCC)c2cc(C(C)(C)C)ccc2-c2c(N(c3ccc(Br)cc3)c3ccc(Br)cc3)cc(C(C)(C)C)cc21] | WO 2013/156130 |
| Mon-103-BE | 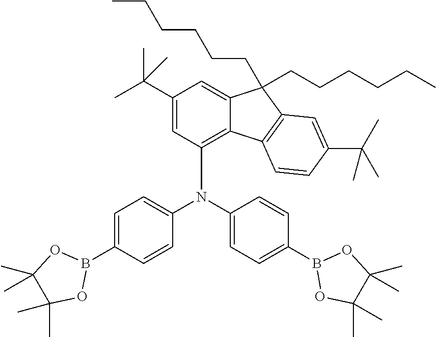 [SMILES: CCCCCCC1(CCCCCC)c2cc(C(C)(C)C)ccc2-c2c(N(c3ccc(B4OC(C)(C)C(C)(C)O4)cc3)c3ccc(B4OC(C)(C)C(C)(C)O4)cc3)cc(C(C)(C)C)cc21] | WO 2013/156130 |
| Mon-104 | 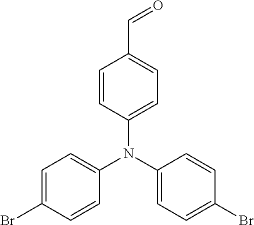 [SMILES: O=Cc1ccc(N(c2ccc(Br)cc2)c2ccc(Br)cc2)cc1] | WO 2010/097155 A1 |
| Mon-104-BE | 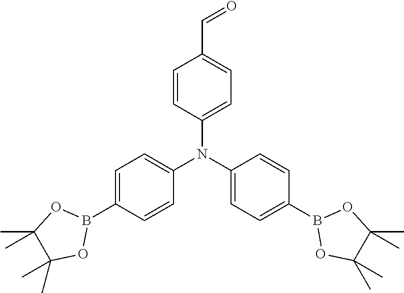 | WO 2010/097155 A1 |
| Mon-105 | 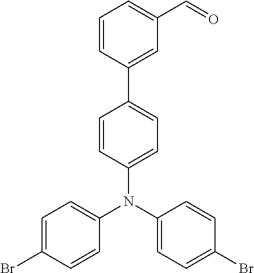 [SMILES: O=Cc1cccc(-c2ccc(N(c3ccc(Br)cc3)c3ccc(Br)cc3)cc2)c1] | analogous to: WO 2013/156130 |
| Mon-106-BE | 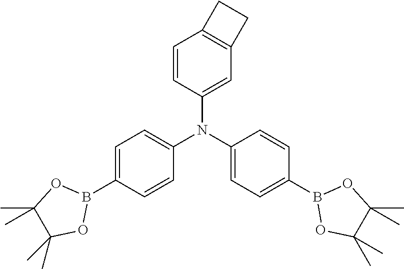 | WO 2009/102027 |
| Mon-107 | 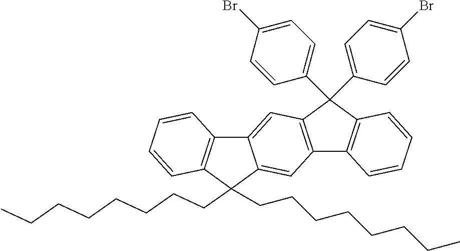 [SMILES: CCCCCCCCC1(CCCCCCCC)c2ccccc2-c2cc3c(cc21)-c1ccccc1C3(c1ccc(Br)cc1)c1ccc(Br)cc1] | WO 2010/136111 |
| Mon-107-BE | 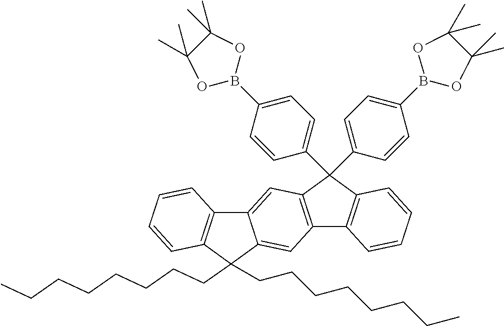 [SMILES: CCCCCCCCC1(CCCCCCCC)c2ccccc2-c2cc3c(cc21)-c1ccccc1C3(c1ccc(B2OC(C)(C)C(C)(C)O2)cc1)c1ccc(B2OC(C)(C)C(C)(C)O2)cc1] | WO 2010/136111 |
| Mon-108 | 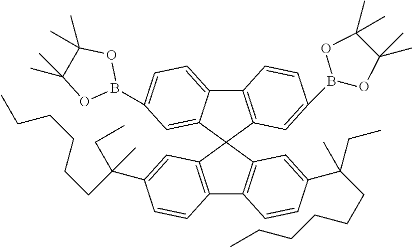 [SMILES: CCCCCCC(C)(CC)c1ccc2c(c1)C1(c3cc(B4OC(C)(C)C(C)(C)O4)ccc3-c3ccc(B4OC(C)(C)C(C)(C)O4)cc31)c1cc(C(C)(CC)CCCCCC)ccc1-2] | WO 2003/020790 |
| Mon-109-BE | 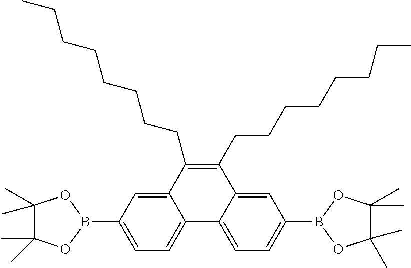 [SMILES: CCCCCCCCc1c(CCCCCCCC)c2cc(B3OC(C)(C)C(C)(C)O3)ccc2c2ccc(B3OC(C)(C)C(C)(C)O3)cc12] | WO 2005/104264 |
| Mon-110 | 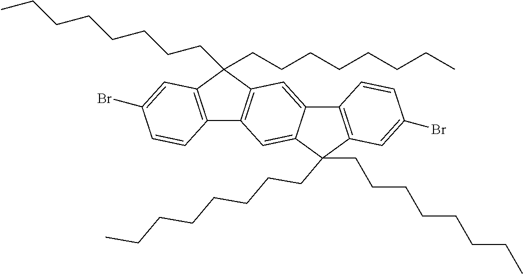 [SMILES: CCCCCCCCC1(CCCCCCCC)c2cc(Br)ccc2-c2cc3c(cc21)-c1ccc(Br)cc1C3(CCCCCCCC)CCCCCCCC] | Macromolecules 2000, 33, 2016-2020 |
| Mon-110-Be | 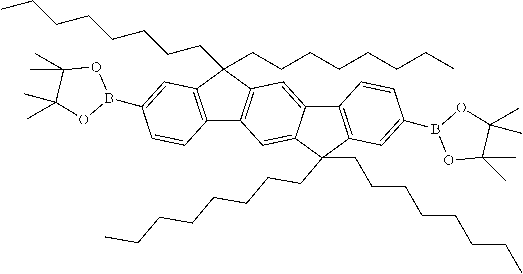 [SMILES: CCCCCCCCC1(CCCCCCCC)c2cc(B3OC(C)(C)C(C)(C)O3)ccc2-c2cc3c(cc21)-c1ccc(B2OC(C)(C)C(C)(C)O2)cc1C3(CCCCCCCC)CCCCCCCC] | Macromolecules 2000, 33, 2016-2020 |
| Mon-111 | 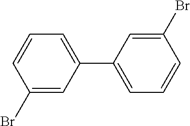 [SMILES: Brc1cccc(-c2cccc(Br)c2)c1] | CAS 16400-51-4 |
| Mon-112 | 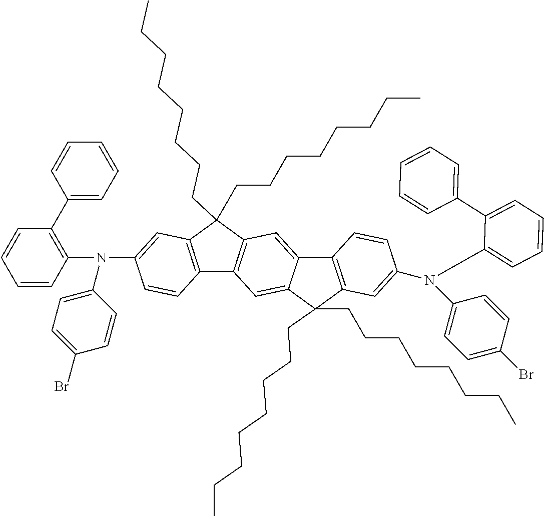 [SMILES: CCCCCCCCC1(CCCCCCCC)c2cc(N(c3ccc(Br)cc3)c3ccccc3-c3ccccc3)ccc2-c2cc3c(cc21)-c1ccc(N(c2ccc(Br)cc2)c2ccccc2-c2ccccc2)cc1C3(CCCCCCCC)CCCCCCCC] | WO 2013/156125 A1 |

Part B: Synthesis of the Polymers

### Examples 21 to 41

Preparation of comparative polymers V1, V2, V3 and V4 and of inventive polymers Po1 to Po17

The comparative polymers V1, V2, V3 and V4 and the inventive polymers Po1 to Po17 are prepared by SUZUKI coupling by the process described in WO 03/048225 from the monomers disclosed in Part A.

The polymers V1 to V4 and Po1 to Po17 prepared in this way contain the structural units, after elimination of the leaving groups, in the percentages reported in table 7 below (percent figures=mol %). In the case of the polymers which are prepared from monomers having aldehyde groups, the latter are converted to crosslinkable vinyl groups after the polymerization by WITTIG reaction by the process described in WO 2010/097155. The polymers listed correspondingly in Table 7 and used in Part C thus have crosslinkable vinyl groups rather than the aldehyde groups originally present.

The palladium and bromine contents of the polymers are determined by ICP-MS. The values determined are below 10 ppm.

The molecular weights M_{w} and the polydispersities D are determined by means of gel permeation chromatography (GPC) (model: Agilent HPLC System Series 1100, column: PL-RapidH from Polymer Laboratories; solvent: THF with 0.12% by volume of o-dichlorobenzene; detection: UV and refractive index; temperature: 40° C.). Calibration is effected with polystyrene standards.

| | | | | | | | | | | | | | | Molecular | |
|---|---|---|---|---|---|---|---|---|---|---|---|---|---|---|---|
| Exam- | Poly- | | | | | | | | | | | | | weight | Polydisp. |
| ple | mer | Inventive monomers | | | | | | Further monomers | | | | | | M_{w} (g/mol) | D |
| 21 | V1 | | | | | | | Mon-110 | 50% | Mon- | 50% | | | 145 000 | 2.5 |
| | | | | | | | | | | 101-BE | | | | | |
| 22 | V2 | | | | | | | Mon-110 | 50% | Mon- | 40% | Mon- | 10% | 125 000 | 2.9 |
| | | | | | | | | | | 101-BE | | 104-BE | | | |
| 23 | V3 | | | | | | | Mon- | 25% | Mon- | 25% | Mon-111 | 50% | 85 000 | 5.3 |
| | | | | | | | | 110-BE | | 102-BE | | | | | |
| 24 | V4 | | | | | | | Mon-112 | 50% | Mon- | 50% | | | 160 000 | 2.3 |
| | | | | | | | | | | 101-BE | | | | | |
| 25 | Po1 | Mon-1 | 50% | | | | | Mon- | 50% | | | | | 123 000 | 2.6 |
| | | | | | | | | 101-BE | | | | | | | |
| 26 | Po2 | Mon-4 | 50% | | | | | Mon- | 50% | | | | | 153 000 | 3.2 |
| | | | | | | | | 103-BE | | | | | | | |
| 27 | Po3 | Mon-1 | 50% | | | | | Mon- | 40% | | | Mon- | 10% | 98 000 | 3.5 |
| | | | | | | | | 101-BE | | | | 104-BE | | | |
| 28 | Po4 | Mon-3 | 50% | | | | | Mon- | 30% | | | Mon- | 20% | 180 000 | 2.8 |
| | | | | | | | | 102-BE | | | | 106-BE | | | |
| 29 | Po5 | Mon- | 50% | Mon-9 | 10% | | | Mon-103 | 40% | | | | | 135 000 | 3.2 |
| | | 1-BE | | | | | | | | | | | | | |
| 30 | Po6 | Mon-5 | 30% | Mon-6 | 10% | Mon-8 | 10% | Mon- | 50% | | | | | 155 000 | 2.9 |
| | | | | | | | | 103-BE | | | | | | | |
| 31 | Po7 | | | Mon-7 | 10% | | | Mon-101 | 40% | Mon- | 50% | | | 189 000 | 1.9 |
| | | | | | | | | | | 110-BE | | | | | |
| 32 | Po8 | | | Mon-10 | 10% | Mon-11 | 10% | Mon- | 30% | Mon- | 20% | Mon-102 | 30% | 220 000 | 2.7 |
| | | | | | | | | 109-BE | | 102-BE | | | | | |
| 33 | Po9 | Mon-4 | 50% | Mon- | 50% | | | | | | | | | 138 000 | 2.1 |
| | | | | 9-BE | | | | | | | | | | | |
| 34 | Po10 | Mon- | 50% | | | | | Mon-102 | 30% | Mon-105 | 20% | | | 114 000 | 2.5 |
| | | 13-BE | | | | | | | | | | | | | |
| 35 | Po11 | Mon-14 | 30% | Mon-15 | 20% | | | Mon- | 50% | | | | | 136 000 | 2.4 |
| | | | | | | | | 108-BE | | | | | | | |
| 36 | Po12 | Mon-2 | 30% | | | | | Mon- | 50% | Mon-105 | 20% | | | 163 000 | 2.6 |
| | | | | | | | | 103-BE | | | | | | | |
| 37 | Po13 | Mon- | 25% | | | | | Mon- | 25% | Mon-111 | 50% | | | 74 000 | 4.8 |
| | | 1-BE | | | | | | 102-BE | | | | | | | |
| 38 | Po14 | Mon-15 | 25% | Mon-3 | 25% | | | Mon- | 50% | | | | | 185 000 | 1.8 |
| | | | | | | | | 107-BE | | | | | | | |
| 39 | Po15 | Mon-13 | 20% | Mon-12 | 25% | | | Mon- | 50% | | | | | 155 000 | 3.1 |
| | | | | | | | | 107-BE | | | | | | | |
| 40 | Po16 | Mon-13 | 50% | | | | | Mon- | 50% | | | | | 195 000 | 2.7 |
| | | | | | | | | 101-BE | | | | | | | |
| 41 | Po17 | Mon-16 | 50% | | | | | Mon- | 50% | | | | | 68 000 | 3.2 |
| | | | | | | | | 103-BE | | | | | | | |

### Part C: Production of the OLEDs

### Examples 21 to 41

The comparative polymers and the inventive polymers are processed from solution.

Whether the crosslinkable variants of the polymers after crosslinking give rise to a completely insoluble layer is tested analogously to WO 2010/097155.

Table 8 lists the remaining layer thickness of the original 100 nm after the washing operation described in WO 2010/097155. If there is no decrease in the layer thickness, the polymer is insoluble and hence the crosslinking is sufficient.

TABLE 8
Check of the residual layer thickness of the original 100 nm
after the wash test

| | Residual layer thickness after wash test |
|---|---|
| | [in nm] |
| Polymer | Crosslinking at 220° C. for 30 minutes |
| V1 | 22.5 |
| V2 | 99 |
| Po3 | 99.5 |
| Po5 | 98 |
| Po10 | 98.5 |
| Po12 | 99 |

As can be inferred from Table 8, comparative polymer V1 which does not bear any crosslinking group hardly crosslinks at all on baking at 220° C. for 30 minutes. Comparative polymer V2 and inventive polymers Po3, Po5, Po10 and Po12 crosslink fully at 220° C.

There are already many descriptions of the production of solution-based OLEDs in the literature, for example in WO 2004/037887 and WO 2010/097155. The process is matched to the circumstances described hereinafter (variation in layer thickness, materials).

The inventive polymers are used in two different layer sequences:

Structure A is as follows:
substrate,
ITO (50 nm),
PEDOT:PSS (20 nm),
hole transport layer (HTL) (20 nm),
emission layer (EML) (60 nm),
hole blocker layer (HBL) (10 nm),
electron transport layer (ETL) (40 nm),
cathode.

Structure B is as follows:
substrate,
ITO (50 nm),
PEDOT:PSS (20 nm),
hole transport layer (HTL) (40 nm),
emission layer (EML) (30 nm),
electron transport layer (ETL) (20 nm),
cathode.

Substrates used are glass plates coated with structured ITO (indium tin oxide) of thickness 50 nm. These are coated with PEDOT:PSS. Spin-coating is effected under air from water. The layer is baked at 180° C. for 10 minutes. PEDOT:PSS is sourced from Heraeus Precious Metals GmbH & Co. KG, Germany. The hole transport layer and the emission layer are applied to these coated glass plates.

The hole transport layers used are the compounds of the invention and comparative compounds, each dissolved in toluene. The typical solids content of such solutions is about 5 g/l when, as here, the layer thicknesses of 20 nm or 40 nm which are typical of a device are to be achieved by means of spin-coating. The layers are spun on in an inert gas atmosphere, argon in the present case, and baked at 220° C. for 30 minutes in the case of the crosslinked polymers (structure A) and at 180° C. for 10 minutes in the case of the uncrosslinked polymers (structure B).

The emission layer is always composed of at least one matrix material (host material) and an emitting dopant (emitter). In addition, mixtures of a plurality of matrix materials and co-dopants may occur. Details given in such a form as H1 (92%):dopant (8%) mean here that the material H1 is present in the emission layer in a proportion by weight of 92% and the dopant in a proportion by weight of 8%. The mixture for the emission layer is dissolved in toluene for structure A. The typical solids content of such solutions is about 18 g/l when, as here, the layer thickness of 60 nm which is typical of a device is to be achieved by means of spin-coating. The layers are spun on in inert gas atmosphere, argon in the present case, and baked at 150° C. for 10 minutes.

In structure B, the emission layer is formed by thermal evaporation in a vacuum chamber. This layer may consist of more than one material, the materials being added to one another by co-evaporation in a particular proportion by volume.

Details given in such a form as H3:dopant (95%:5%) mean here that the H3 and dopant materials are present in the layer in a proportion by volume of 95%:5%.

The materials used in the present case are shown in table 9.

TABLE 9
Structural formulae of the materials used in the emission layer

| | |
|---|---|
| 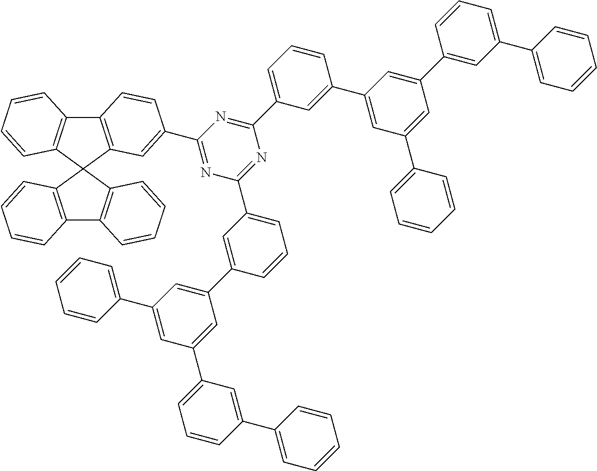 [SMILES: c1ccc(-c2cccc(-c3cc(-c4ccccc4)cc(-c4cccc(-c5nc(-c6cccc(-c7cc(-c8ccccc8)cc(-c8cccc(-c9ccccc9)c8)c7)c6)nc(-c6ccc7c(c6)C6(c8ccccc8-c8ccccc86)c6ccccc6-7)n5)c4)c3)c2)cc1] | H1 |
| 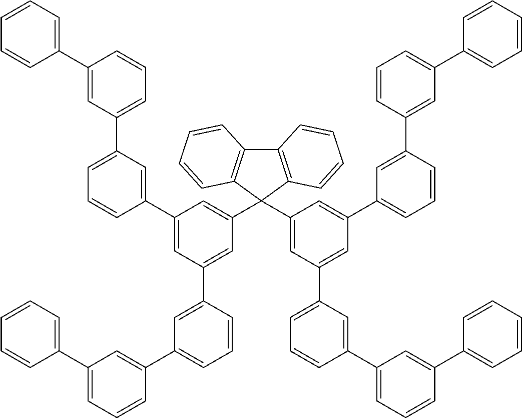 [SMILES: c1ccc(-c2cccc(-c3cccc(-c4cc(-c5cccc(-c6cccc(-c7ccccc7)c6)c5)cc(C5(c6cc(-c7cccc(-c8cccc(-c9ccccc9)c8)c7)cc(-c7cccc(-c8cccc(-c9ccccc9)c8)c7)c6)c6ccccc6-c6ccccc65)c4)c3)c2)cc1] | H2 |
| 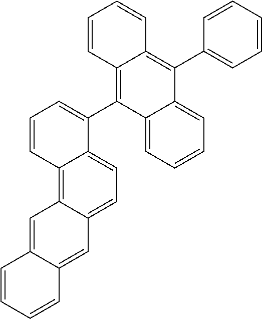 [SMILES: c1ccc(-c2c3ccccc3c(-c3cccc4c3ccc3cc5ccccc5cc34)c3ccccc23)cc1] | H3 |
| 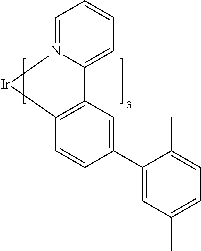 | TEG |
| 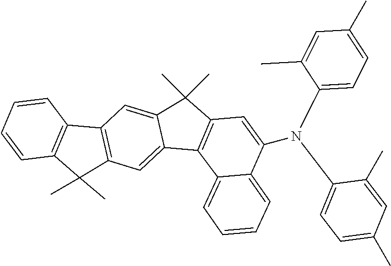 [SMILES: Cc1ccc(N(c2ccc(C)cc2C)c2cc3c(c4ccccc24)-c2cc4c(cc2C3(C)C)-c2ccccc2C4(C)C)c(C)c1] | SEB |

The materials for the hole blocker layer and electron transport layer are likewise applied by thermal vapor deposition in a vacuum chamber and are shown in Table 10. The hole blocker layer consists of ETM1. The electron transport layer consists of the two materials ETM1 and ETM2, which are added to one another by co-evaporation in a proportion by volume of 50% each.

TABLE 10
HBL and ETL materials used

| | |
|---|---|
| 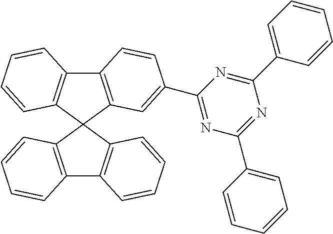 [SMILES: c1ccc(-c2nc(-c3ccccc3)nc(-c3ccc4c(c3)C3(c5ccccc5-c5ccccc53)c3ccccc3-4)n2)cc1] | ETM1 |
| 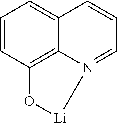 | ETM2 |

The cathode is formed by the thermal evaporation of an aluminum layer of thickness 100 nm.

The exact structure of the OLEDs can be found in Table 11.

TABLE 11
Structure of the OLEDs

| Example | HTL polymer | Structure | EML composition |
|---|---|---|---|
| 42 | V1 | B | H3 95%; SEB 5% |
| 43 | V2 | A | H1 30%; H2 55%; TEG 15% |
| 44 | V3 | B | H3 95%; SEB 5% |
| 45 | Po3 | A | H1 30%; H2 55%; TEG 15% |
| 46 | Po5 | A | H1 30%; H2 55%; TEG 15% |
| 47 | Po10 | A | H1 30%; H2 55%; TEG 15% |
| 48 | Po12 | A | H1 30%; H2 55%; TEG 15% |
| 49 | Po13 | B | H3 95%; SEB 5% |

The OLEDs are characterized in a standard manner. For this purpose, the electroluminescence spectra, current-voltage-luminance characteristics (IUL characteristics) assuming Lambertian radiation characteristics and the (operating) lifetime are determined. The IUL characteristics are used to determine parameters such as the operating voltage (in V) and the external quantum efficiency (in %) at a particular brightness. LD80 @ 1000 cd/m² is the lifetime until the OLED, given a starting brightness of 1000 cd/m², has dropped to 80% of the starting intensity, i.e. to 800 cd/m².

The properties of the different OLEDs are summarized in tables 12a and 12b. Examples 42 and 44 show comparative components; all the other examples show properties of inventive OLEDs.

Tables 12a and 12b:

Properties of the OLEDs

TABLE 12a

| | Efficiency at | Voltage at | LT80 at |
|---|---|---|---|
| | 1000 cd/m² | 1000 cd/m² | 10 000 cd/m² |
| Example | % EQE | [V] | [h] |
| 42 | 4.9 | 4.5 | 120 |
| 44 | 8.0 | 4.6 | 160 |
| 49 | 9.7 | 4.8 | 160 |

TABLE 12b

| | Efficiency at | Voltage at | LT80 at |
|---|---|---|---|
| | 1000 cd/m² | 1000 cd/m² | 1000 cd/m² |
| Example | % EQE | [V] | [h] |
| 43 | 17.0 | 4.2 | 110 |
| 45 | 18.8 | 4.3 | 125 |
| 46 | 18.9 | 4.2 | 130 |
| 47 | 17.9 | 3.9 | 260 |
| 48 | 18.1 | 3.8 | 230 |

As shown in tables 12a and 12b, the polymers of the invention, when used as hole transport layer in OLEDs, show improvements over the prior art. By virtue of their higher triplet level and the larger bandgap, the efficiencies in particular of the green- and blue-emitting OLEDs produced are improved.

The fact that the polymers of the invention have a higher triplet level than their direct comparative polymers is shown by quantum-mechanical calculations using some selected polymers. The results are shown in table 13.

TABLE 13
Comparison of the calculated T1 level

| Polymer | V1 | Po1 | Po2 | V2 | Po3 | V3 | Po13 | V4 | Po16 |
|---|---|---|---|---|---|---|---|---|---|
| T1 (eV) | 2.31 | 2.43 | 2.49 | 2.31 | 2.45 | 2.38 | 2.52 | 2.31 | 2.45 |

1-18. (canceled)

19. A polymer comprising at least one structural unit of formula (I): 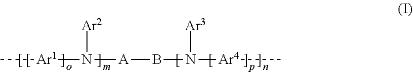
wherein
A is a polycyclic aromatic or heteroaromatic ring system having 10 to 60 aromatic or heteroaromatic ring atoms and which is optionally substituted by one or more R radicals;
B is a mono- or polycyclic, aromatic or heteroaromatic ring system having 5 to 10 aromatic or heteroaromatic ring atoms and which is optionally substituted by one or more R radicals;
wherein the number of aromatic or heteroaromatic ring atoms in A is greater than the number of aromatic or heteroaromatic ring atoms in B;
Ar¹, Ar², Ar³, and Ar⁴
are the same or different in each instance and are a mono- or polycyclic, aromatic or heteroaromatic ring system having 5 to 60 aromatic ring atoms and which is optionally substituted by one or more R radicals;
n, m, o, and p
are the same or different and are each 0 or 1;
R is the same or different in each instance and is H, D, F, Cl, Br, I, N(R¹)₂, CN, NO₂, Si(R¹)₃, B(OR¹)₂, C(═O)R¹, P(═O)(R¹)₂, S(═O)R¹, S(═O)₂R¹, OSO₂R¹, a straight-chain alkyl, alkoxy, or thioalkoxy group having 1 to 40 carbon atoms or a branched or cyclic alkyl, alkoxy, or thioalkoxy group having 3 to 40 carbon atoms, each of which is optionally substituted by one or more R¹ radicals, wherein one or more nonadjacent CH₂ groups are optionally replaced by R¹C═CR¹, C≡C, Si(R¹)₂, C═O, C═S, C═NR¹, P(═O)(R¹), SO, SO₂, NR¹, O, S, or CONR¹ and wherein one or more hydrogen atoms are optionally replaced by D, F, Cl, Br, I, or CN, or a mono- or polycyclic, aromatic or heteroaromatic ring system having 5 to 60 aromatic ring atoms and which is optionally substituted in each case by one or more R¹ radicals, or an aryloxy or heteroaryloxy group having 5 to 60 aromatic ring atoms and which is optionally substituted by one or more R¹ radicals, or an aralkyl or heteroaralkyl group having 5 to 60 aromatic ring atoms and which is optionally substituted by one or more R¹ radicals, or a diarylamino group, diheteroarylamino group, or arylheteroarylamino group having 10 to 40 aromatic ring atoms and which is optionally substituted by one or more R¹ radicals, or a crosslinkable Q group; and wherein two or more R radicals together optionally define a mono- or polycyclic, aliphatic, aromatic, and/or benzofused ring system;
R¹ is the same or different in each instance and is H, D, F, or an aliphatic hydrocarbyl radical having 1 to 20 carbon atoms, an aromatic and/or a heteroaromatic hydrocarbyl radical having 5 to 20 carbon atoms, wherein one or more hydrogen atoms are optionally replaced by F; and wherein two or more R¹ substituents together optionally define a mono- or polycyclic, aliphatic, aromatic, or heteroaromatic ring system; and
the dotted lines denote bonds to adjacent structural units in the polymer.

20. The polymer of claim 19, wherein the at least one structural unit of formula (I) is a structural unit of formula (Ia):

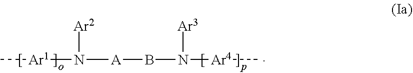

21. The polymer of claim 19, wherein the at least one structural unit of formula (I) is a structural unit of formula (Ib):
------A-B----- (Ib).

22. The polymer of claim 19, wherein the at least one structural unit of formula (I) is a structural unit of formula (Ic): 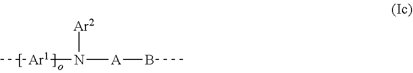
wherein o is 0 or 1.

23. The polymer of claim 19, wherein the at least one structural unit of formula (I) is a structural unit of formula (Id): 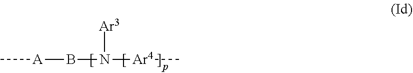
wherein p is 0 or 1.

24. The polymer of claim 19, wherein the polycyclic, aromatic or heteroaromatic ring system A is selected from the group consisting of units A1 through A8: 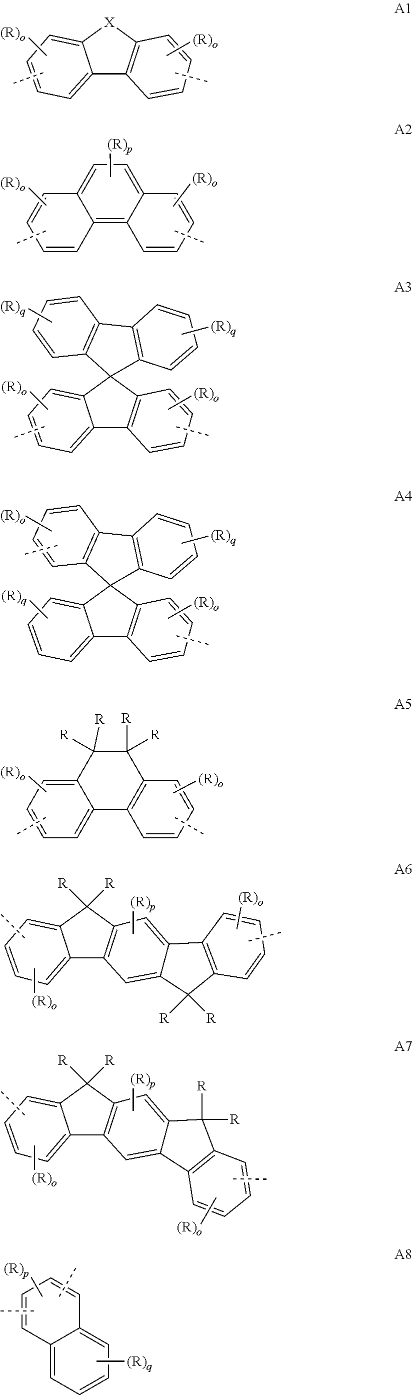
wherein
X is CR², NR, SiR², O, S, C═O, or P═O;
o is 0, 1, 2, or 3;
p is 0, 1, or 2; and
q is 0, 1, 2, 3, or 4.

25. The polymer of claim 19, wherein the the mono- or polycyclic, aromatic or heteroaromatic ring system B is selected from the group consisting of units B1 through B4: 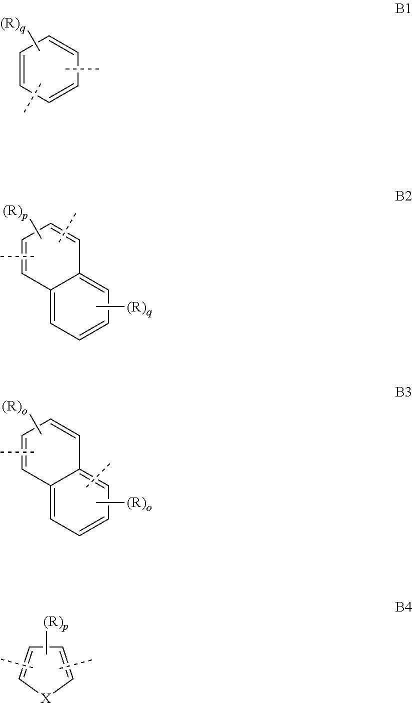
wherein
X is CR², NR, SiR², O, S, C═O, or P═O;
o is 0, 1, 2, or 3;
p is 0, 1, or 2; and
q is 0, 1, 2, 3, or 4.

26. The polymer of claim 19, wherein the mono- or polycyclic, aromatic or heteroaromatic ring systems Ar² and Ar³ are selected from the group consisting of units Ar1 through Ar10: 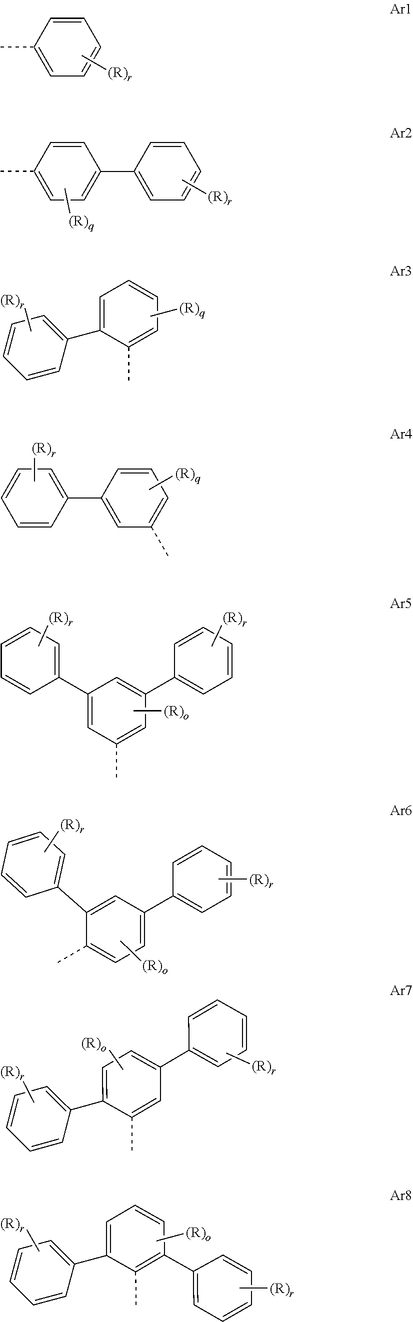 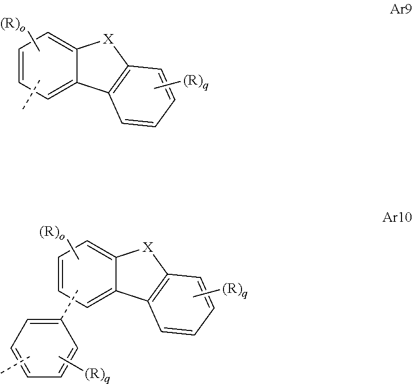
wherein
X is CR², NR, SiR², O, S, C═O, or P═O;
o is 0, 1, 2, or 3;
r is 0, 1, 2, 3, 4 or 5; and
q is 0, 1, 2, 3, or 4.

27. The polymer of claim 19, wherein the mono- or polycyclic, aromatic or heteroaromatic ring systems Ar¹ and Ar⁴ are selected from the group consisting of units Ar11 through Ar20: 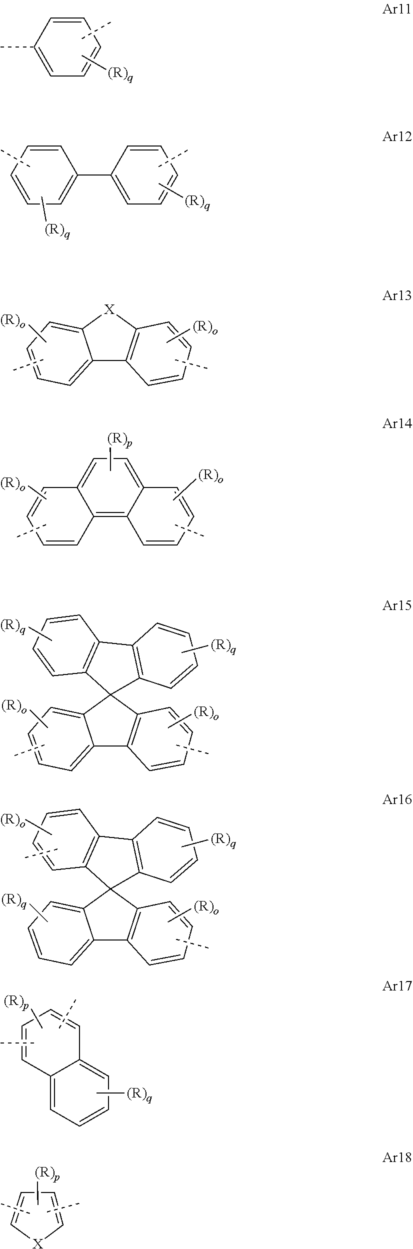
wherein
X is CR², NR, SiR², O, S, C═O, or P═O;
o is 0, 1, 2, or 3;
p is 0, 1, or 2; and
q is 0, 1, 2, 3, or 4.

28. The polymer of claim 19, wherein the proportion of structural units of formula (I) in the polymer is in the range of from 50 to 95 mol %, based on 100 mol % of all copolymerizable monomers present as structural units in the polymer.

29. The polymer of claim 19, wherein the polymer, in addition to the the structural units of formula (I), comprises further structural units different than the structural units of the formula (I).

30. The polymer of claim 19, wherein the polymer, in addition to the one or more structural units of the formula (I) and optionally further structural units, further comprises at least one structural unit comprising at least one crosslinkable Q group.

31. The polymer of claim 30, wherein the structural unit comprising the at least one crosslinkable group is selected from the group consisting of structural units of formulae (IIa) through (IIf): 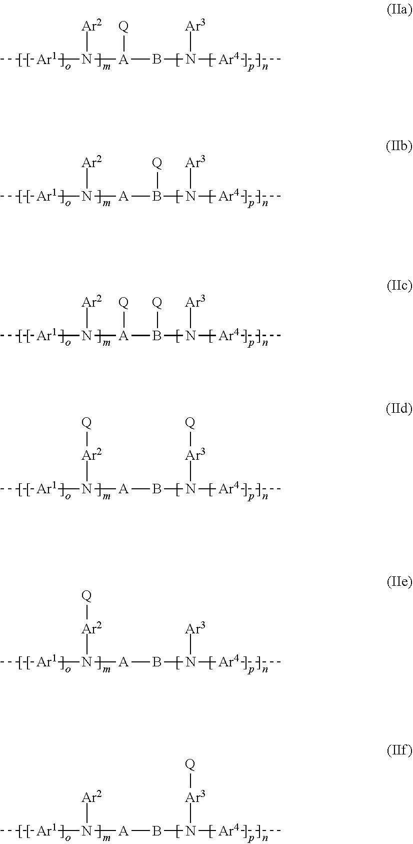
wherein Q is a crosslinkable group.

32. A process for preparing the polymer of claim 19, comprising the step of preparing the polymer by SUZUKI polymerization, YAMAMOTO polymerization, STILLE polymerization, or HARTWIG-BUCHWALD polymerization.

33. A polymer blend comprising one or more polymers of claim 19 and one or more further polymeric, oligomeric, dendritic, and/or low molecular weight substances.

34. An electronic or optoelectronic device comprising one or more active layers, wherein at least one of the one or more active layers comprises one or more polymers of claim 19.

35. The electronic or optoelectronic device of claim 34, wherein the electronic or optoelectronic device is selected from the group consisting of organic electroluminescent devices, organic light-emitting electrochemical cells, organic field-effect transistors, organic integrated circuits, organic thin-film transistors, organic solar cells, organic laser diodes, organic photovoltaic elements and devices, and organic photoreceptors.
